(19) United States
(12) Patent Application Publication
(10) Pub. No.: US 2026/0052690 A1
(43) Pub. Date: Feb. 19, 2026

(54) SEMICONDUCTOR MEMORY DEVICE

(71) Applicant: SK hynix Inc., Gyeonggi-do (KR)

(72) Inventors: Won Geun CHOI, Gyeonggi-do (KR); In Su PARK, Gyeonggi-do (KR); Jung Shik JANG, Gyeonggi-do (KR)

(21) Appl. No.: 19/367,832

(22) Filed: Oct. 24, 2025

Related U.S. Application Data
(63) Continuation of application No. 18/538,555, filed on Dec. 13, 2023.

(30) Foreign Application Priority Data
Feb. 23, 2023 (KR) 10-2023-0024515
Jul. 25, 2023 (KR) 10-2023-0096666
Jul. 25, 2023 (KR) 10-2023-0096737

(51) Int. Cl. H10B 43/27; H10B 41/10; H10B 41/27; H10B 43/10

(52) U.S. Cl. CPC H10B 43/27; H10B 41/10; H10B 41/27; H10B 43/10

(57) ABSTRACT

There are provided a semiconductor memory device and a manufacturing method of a semiconductor memory device. The semiconductor memory device includes a gate stack structure, a channel structure passing through the gate stack structure, and a memory layer between the channel structure and the gate stack structure. A channel layer or a channel pattern, which constitutes the channel structure, includes a structure having a corner or includes a filling type structure and a liner type structure.

### CROSS-REFERENCE TO RELATED APPLICATION

The present application is a continuation of U.S. patent Ser. No. 18/538,555 filed on Dec. 13, 2023, which claims priority under 35 U.S.C. § 119 (a) to Korean patent application number 10-2023-0024515 filed on Feb. 23, 2023, Korean patent application number 10-2023-0096666 filed on Jul. 25, 2023 and Korean patent application number 10-2023-0096737 filed on Jul. 25, 2023, the entire disclosures of which are incorporated by reference herein.

### BACKGROUND

### 1. Field of Invention

Embodiments of the present disclosure generally relate to an electronic device and a manufacturing method of an electronic device, and more particularly, to a semiconductor memory device and a manufacturing method of a semiconductor memory device.

### 2. Description of Related Art

Semiconductor memory devices are applied to electronic devices in various fields, including automobiles, medical appliances, data centers, and the like, in addition to small electronic devices. Accordingly, demand for semiconductor memory devices has increased.

A semiconductor memory device may include memory cells for storing data. In order to achieve the large capacity of semiconductor memory devices, the technical development of three-dimensional semiconductor memory devices including three-dimensionally arranged memory cells has been actively conducted.

### SUMMARY

In accordance with an embodiment of the present disclosure, a semiconductor memory device includes: a doped semiconductor structure including a first surface and a second surface facing opposite to each other; a gate stack structure formed over the first surface of the doped semiconductor structure, the gate stack structure including a plurality of conductive layers stacked spaced apart from each other in a direction intersecting the first surface; a channel layer including a first portion overlapping with a sidewall of the gate stack structure, a second portion extending to the inside of the doped semiconductor structure from the first portion, and a third portion extending toward the second surface of the doped semiconductor structure from the second portion; and a memory layer disposed between the first portion of the channel layer and the sidewall of the gate stack structure, wherein the second portion of the channel layer includes a first corner adjacent to the gate stack structure and a second corner between the second surface of the doped semiconductor structure and the first corner.

In accordance with another embodiment of the present disclosure, a semiconductor memory device includes: a doped semiconductor structure including a first surface and a second surface facing in a direction opposite to a direction in which the first surface faces; a gate stack structure overlapping with the first surface of the doped semiconductor structure, the gate stack structure including a plurality of conductive layers stacked spaced apart from each other in a direction intersecting the first surface; a channel hole passing through the gate stack structure to extend to the inside of the doped semiconductor structure; a channel structure disposed in the channel hole, the channel structure including a channel layer; and a memory layer between the channel layer and the gate stack structure, wherein the channel hole includes an end portion inside the doped semiconductor structure, a gate penetration portion passing through the gate stack structure, and a middle portion disposed inside the doped semiconductor structure between the end portion and the gate penetration portion, and wherein the middle portion in the channel hole includes a first corner adjacent to the gate stack structure and a second corner between the second surface of the doped semiconductor structure and the first corner.

In accordance with still another embodiment of the present disclosure, a method of manufacturing a semiconductor memory device includes: forming a preliminary semiconductor structure including a first surface and a second surface facing in a direction opposite to a direction in which the first surface faces; forming a sacrificial structure inside the preliminary semiconductor structure, the sacrificial structure including a first portion adjacent to the first surface and a second portion extending toward the second surface from the first portion, wherein the first portion has a width greater than a width of the second portion; forming a preliminary stack structure by alternately stacking a plurality of first material layers and a plurality of second material layers on the first surface of the preliminary semiconductor structure; forming a hole passing through the preliminary stack structure such that the sacrificial structure is opened by the hole, wherein a width of an exposed portion of the sacrificial structure is narrower than the width of the first portion of the sacrificial structure; removing the sacrificial structure through the hole; forming a memory layer along a surface of a channel hole defined as a region in which the sacrificial structure is removed and the hole are connected to each other; and forming a channel structure including a channel layer on the memory layer.

In accordance with still another embodiment of the present disclosure, a semiconductor memory device includes: a gate stack structure including a plurality of conductive layers and a plurality of interlayer insulating layers, which are alternately disposed in a stacking direction, wherein the plurality of conductive layers include a first conductive layer, a second conductive layer, and a third conductive layer, which are disposed spaced apart from each other in the stacking direction; a channel hole passing through the gate stack structure, the channel hole including a first portion passing through the second conductive layer, a second portion extending to pass through the first conductive layer from the first portion, and a third portion extending to pass through the third conductive layer from the first portion; a channel layer including a filling channel portion inside the second portion of the channel hole, a first liner channel portion inside the first portion of the channel hole, and a second liner channel portion inside the third portion of the channel hole; and a memory layer between the channel layer and the gate stack structure, wherein the first portion of the channel hole protrudes laterally toward the gate stack structure as compared with the second portion of the channel hole and the third portion of the channel hole.

In accordance with still another embodiment of the present disclosure, a semiconductor memory device includes: a gate stack structure including a plurality of conductive layers and a plurality of interlayer insulating layers, which are alternately disposed in a stacking direction, wherein the plurality of conductive layers include a first conductive layer and a second conductive layer which are disposed spaced apart from each other in the stacking direction, and the plurality of interlayer insulating layers include a pad interlayer insulating layer between the first conductive layer and the second conductive layer; a channel hole passing through the gate stack structure, the channel hole including a first portion inside the pad interlayer insulating layer, a second portion extending to pass through the first conductive layer from the first portion, and a third portion extending to pass through the second conductive layer from the first portion; a filling channel pattern inside the second portion of the channel hole; a liner channel pattern including a connection portion inside the first portion of the channel hole and a vertical portion extending to the inside of the third portion of the channel hole from the connection portion; a gate insulating layer between the filling channel pattern and the first conductive layer; and a memory layer between the liner channel pattern and the gate stack structure, wherein the first portion of the channel hole protrudes laterally toward the gate stack structure as compared with the second portion of the channel hole and the third portion of the channel hole.

In accordance with still another embodiment of the present disclosure, a method of manufacturing a semiconductor memory device includes: forming a preliminary stack structure with a channel hole, wherein the preliminary stack structure includes a lower stack structure including a first material layer and a second material layer on the first material layer, a third material layer on the lower stack structure, and a plurality of fourth material layers and a plurality of fifth material layers which are alternately stacked on the third material layer, wherein the channel hole includes a first opening inside the third material layer, a second opening extending to pass through the lower stack structure from the first opening, and a third opening extending to pass through the plurality of fourth material layers and the plurality of fifth material layers from the first opening, and wherein the first opening protrudes laterally as compared with the second opening and the third opening; forming a filling channel pattern filling the second opening of the channel hole; forming a memory layer extending along a sidewall of the first opening of the channel hole and a sidewall of the third opening of the channel hole; forming a liner channel pattern contacting the filling channel pattern, the liner channel pattern extending along an inner wall of the memory layer; removing the second material layer and the plurality of fifth material layers; forming a gate insulating layer to surround an outer wall of the filling channel pattern; and forming a plurality of conductive layers in regions in which the second material layer and the plurality of fifth material layers are removed.

### BRIEF DESCRIPTION OF THE DRAWINGS

Various embodiments of the present disclosure will now be described more fully hereinafter with reference to the accompanying drawings; however, the embodiments may be embodied in different forms and should not be construed as being limited to the embodiments set forth herein. Rather, these embodiments are provided so that this disclosure will be enabling to those skilled in the art.

In the drawing figures, dimensions may be exaggerated for clarity of illustration. It will be understood that when an element is referred to as being “between” two elements, it may be the only element between the two elements, or one or more intervening elements may also be present. Like reference numerals refer to like elements throughout.

FIGS. 1A and 1B are views illustrating semiconductor memory devices in accordance with embodiments of the present disclosure.

FIGS. 2A and 2B are views illustrating an arrangement and a sub-cell array structure of a semiconductor memory device in accordance with an embodiment of the present disclosure.

FIGS. 3A and 3B are views illustrating an arrangement and a sub-cell array structure of a semiconductor memory device in accordance with an embodiment of the present disclosure.

FIG. 4 is a plan view illustrating a gate stack structure of a semiconductor memory device in accordance with an embodiment of the present disclosure.

FIG. 5 is a sectional view of a semiconductor memory device in accordance with an embodiment of the present disclosure.

FIGS. 6A, 6B, and 6C are plan views illustrating a cell plug in accordance with an embodiment of the present disclosure.

FIGS. 7A, 7B, and 7C are plan views illustrating a cell plug in accordance with an embodiment of the present disclosure.

FIG. 8 is a sectional view of a semiconductor memory device in accordance with an embodiment of the present disclosure.

FIGS. 9A and 9B are sectional views of semiconductor memory devices in accordance with embodiments of the present disclosure.

FIGS. 10A to 10I, 11, and 12 are sectional views illustrating a manufacturing method of a semiconductor memory device in accordance with an embodiment of the present disclosure.

FIGS. 13A to 13C, 14, and 15A to 15C are sectional views illustrating a manufacturing method of a semiconductor memory device in accordance with an embodiment of the present disclosure.

FIGS. 16A and 16B are plan views illustrating a gate stack structure of a semiconductor memory device in accordance with an embodiment of the present disclosure.

FIGS. 17 and 18 are sectional views of semiconductor memory devices in accordance with embodiments of the present disclosure.

FIGS. 19A, 19B, and 19C are plan views illustrating a cell plug in accordance with an embodiment of the present disclosure.

FIGS. 20A, 20B, and 20C are plan views illustrating a cell plug in accordance with an embodiment of the present disclosure.

FIG. 21 is a sectional view of a semiconductor memory device in accordance with an embodiment of the present disclosure.

FIGS. 22A to 22J are sectional views illustrating a manufacturing method of a semiconductor memory device in accordance with an embodiment of the present disclosure.

FIGS. 23A to 23H are sectional views illustrating a manufacturing method of a semiconductor memory device in accordance with an embodiment of the present disclosure.

FIGS. 24A and 24B are plan views illustrating a gate stack structure of a semiconductor memory device in accordance with an embodiment of the present disclosure.

FIGS. 25 and 26 are sectional views of semiconductor memory devices in accordance with embodiments of the present disclosure.

FIGS. 27A, 27B, and 27C are plan views illustrating a cell plug in accordance with an embodiment of the present disclosure.

FIGS. 28A, 28B, and 28C are plan views illustrating a cell plug in accordance with an embodiment of the present disclosure.

FIG. 29 is a sectional view illustrating a semiconductor memory device in accordance with embodiments of the present disclosure.

FIGS. 30A to 30L are sectional views illustrating a manufacturing method of a semiconductor memory device in accordance with an embodiment of the present disclosure.

FIG. 31 is a block diagram illustrating an electronic system including a semiconductor memory device in accordance with embodiments of the present disclosure.

### DETAILED DESCRIPTION

The specific structural and functional descriptions disclosed herein are merely illustrative for the purpose of describing embodiments according to the concept of the present disclosure. The embodiments according to the concept of the present disclosure can be modified in various forms and replaced with other equivalent embodiments. Thus, the present disclosure should not be construed as limited to the embodiments set forth herein.

It will be understood that, although the terms “first,” “second,” etc. may be used herein to describe various elements, these elements should not be limited by these terms. These terms are only used to distinguish one element from another element, and the order or number of components is not limited by the terms.

Embodiments provide a semiconductor memory device and a manufacturing method of a semiconductor memory device, which can improve the stability and operational reliability of manufacturing processes.

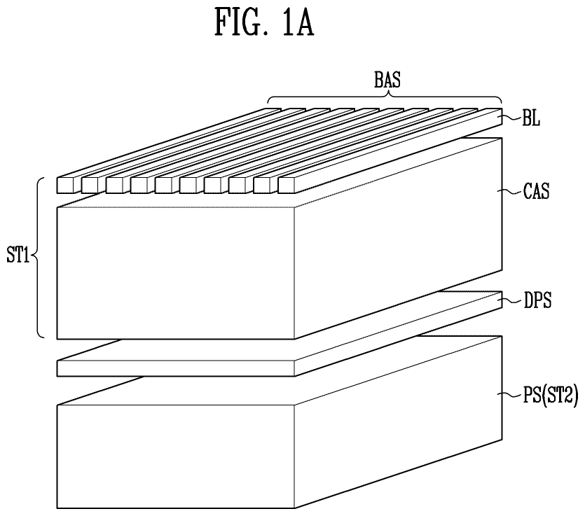

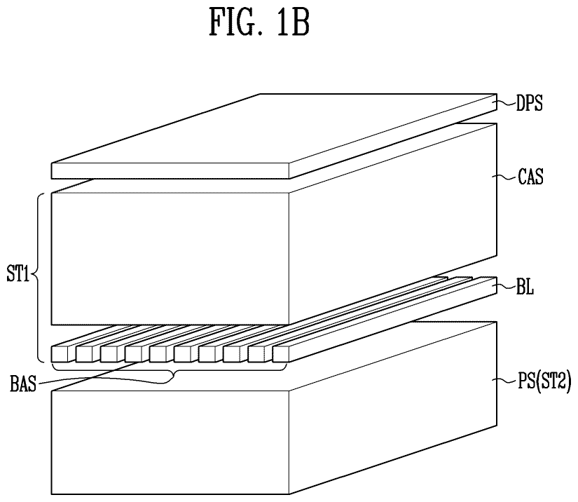

FIGS. 1A and 1B are views illustrating semiconductor memory devices in accordance with embodiments of the present disclosure.

Referring to FIGS. 1A and 1B, each of the semiconductor memory devices may include a first structure ST1, a second structure ST2, and a doped semiconductor structure DSP. The first structure ST1 may include a cell array structure CAS and a bit line array structure BAS, and the second structure ST2 may include a peripheral circuit structure PS.

The bit line array structure BAS may include a plurality of bit lines BL.

The cell array structure CAS may be disposed between the bit line array structure BAS and the doped semiconductor structure DPS. The cell array structure CAS may include a memory block. The memory block may include a plurality of memory cell strings electrically connected to the bit line array structure BAS and the doped semiconductor structure DPS. Each memory cell string may include a channel region disposed between a bit line BL corresponding thereto and the doped semiconductor structure DPS. In an embodiment, the channel region may be formed with a channel layer extending toward a bit line BL corresponding thereto from the doped semiconductor structure DPS. In another embodiment, the channel region may be formed with a filling channel pattern and a liner pattern, which are connected to each other. Each memory cell string may include a plurality of memory cells stacked along the channel layer or the liner pattern.

The peripheral circuit structure PS may be configured to perform a program operation for storing data in a memory cell, a read operation for outputting data stored in the memory cell, and an erase operation for erasing data stored in the memory cell. In an embodiment, the peripheral circuit structure PS may include an input/output circuit, a control circuit, a voltage generating circuit, a row decoder, a column decoder, a page buffer, and the like. More specifically, the peripheral circuit structure PS may include a plurality of transistors, a capacitor, a resistor, and the like.

The peripheral circuit structure PS may include a region overlapping with the doped semiconductor structure DPS, the cell array structure CAS, and the bit line array structure BAS. The terms overlap, or overlapping are used herein to mean two structures are positioned or stacked over or below each other and share a common space in the stacking direction. Moreover “overlap’ or “overlapping” as used herein means a complete overlap or partial overlap unless further specified. Complete overlap or complete overlapping means that the two structures are entirely covering each other or sharing the same space entirely, with no part of either structure remaining separate from the other. Partial overlap or partial overlapping means that only a portion of one structure or object is overlapping with another.

The peripheral circuit structure PS may be adjacent to the doped semiconductor structure DPS as shown in FIG. 1A or be adjacent to the bit line array structure BAS as shown in FIG. 1B.

The cell array structure CAS may be connected to the peripheral circuit structure PS via a plurality of select lines, a plurality of word lines, the bit line array structure BAS, and the doped semiconductor structure DPS. Although not shown in the drawings, each of the first structure ST1 and the second structure ST2 may include at least one of a plurality of interconnections, a plurality of contacts, and a plurality of conductive bonding pads, which are used for electrical connection.

The cell array structure CAS may include a three-dimensional cell array structure including three-dimensionally arranged memory cells.

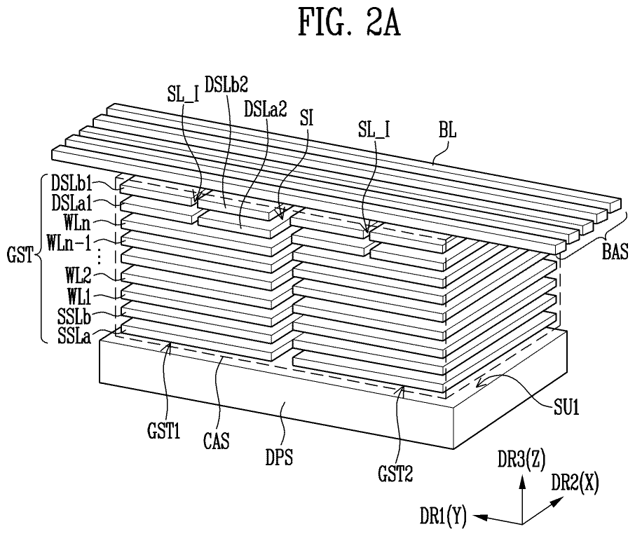

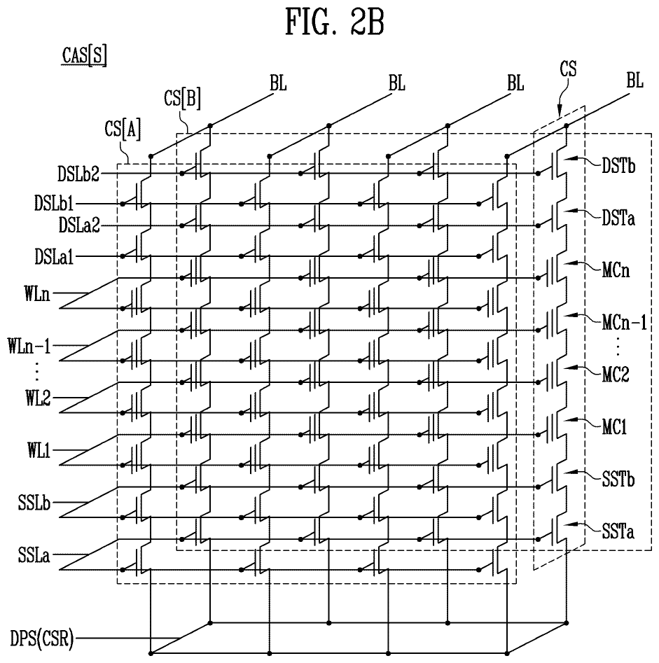

FIGS. 2A and 2B are views illustrating an arrangement and a sub-cell array structure of a semiconductor memory device in accordance with an embodiment of the present disclosure.

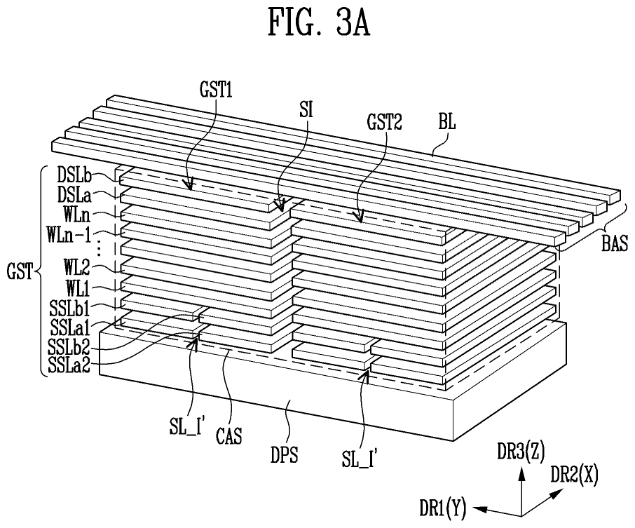

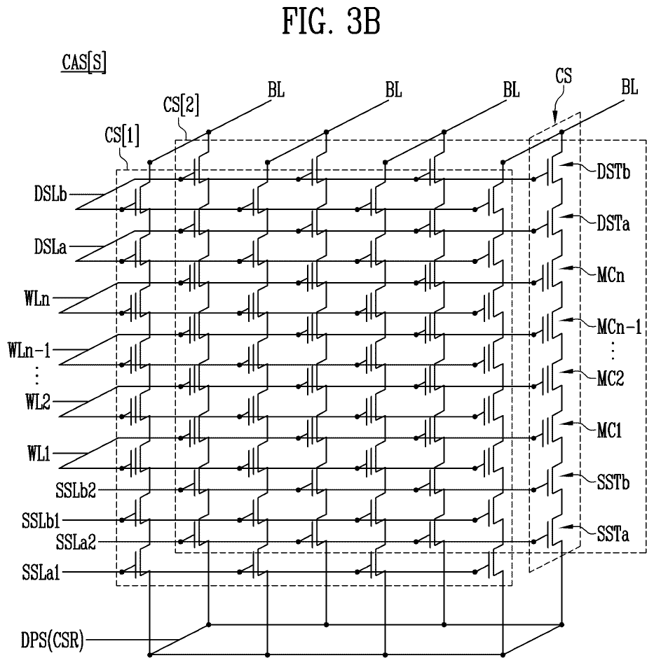

FIGS. 3A and 3B are views illustrating an arrangement and a sub-cell array structure of a semiconductor memory device in accordance with an embodiment of the present disclosure.

FIGS. 2A and 3A illustrate arrangements of a doped semiconductor structure DPS, a cell array structure CAS, and a bit line array structure BAS of a three-dimensional semiconductor memory device in accordance with embodiments of the present disclosure. The doped semiconductor structure DPS, the cell array structure CAS, and the bit line array structure BAS, which are shown in each of FIGS. 2A and 3A, may be applied to the semiconductor memory device shown in FIG. 1A or 1B.

Referring to FIGS. 2A and 3A, the cell array structure CAS may include a plurality of gate stack structures GST partitioned by a slit SI. In an embodiment, the plurality of gate stack structures GST may include a first gate stack structure GST1 and a second gate stack structure GST2, which are adjacent to each other with the slit SI interposed therebetween.

Each gate stack structure GST may be disposed between the bit line array structure BAS and the doped semiconductor structure DPS. The cell array structure CAS may include a sub-cell array structure controlled by each gate stack structure GST. The sub-cell array structure may constitute a memory block or constitute a portion of the memory block.

The doped semiconductor structure DPS may include a doped region including at least one of a common source region and a well region. For example, the doped semiconductor structure DPS may include at least one of an n-type impurity and a p-type impurity. The doped semiconductor structure DPS may include at least one of a first conductivity type doped region including the n-type impurity as a majority carrier and a second conductivity type doped region including the p-type impurity as a majority carrier. The first conductivity type doped region may include the common source region, and the second conductivity type doped region may include the well region.

A plurality of bit lines BL of the bit line array structure BAS may extend in one direction. In the embodiment illustrated in FIGS. 2A and 3A, the plurality of bit lines BL may extend in a first direction DR1 and may be spaced apart from each other at a regular interval along a second direction DR2. For example, the plurality of bit lines BL may include a first bit line and a second bit line, which extend in the first direction DR1, and the first bit line and the second bit line may be spaced apart from each other in the second direction DR2.

The doped semiconductor structure DPS may include a first surface SU1 facing the gate stack structure GST. The gate stack structure GST may be disposed between the first surface SU1 of the doped semiconductor structure DPS and the bit line array structure BAS. The gate stack structure GST may include a source select line SSLa, SSLb, SSLa1, SSLb1, SSLa2 or SSLb2, a plurality of word lines WL1 to WLn, where n is a natural number of 2 or more, and a drain select line DSLa1, DSLb1, DSLa2, DSLb2, DSLa or DSLb, which are stacked spaced apart from each other in a third direction DR3 as a stacking direction.

The first direction DR1, the second direction DR2, and the third direction DR3, which are described above, may be defined as directions intersecting one another. In an embodiment, the first direction DR1 may correspond to an X-axis direction, the second direction DR2 may correspond to a Y-axis direction, and the third direction DR3 may correspond to a Z-axis direction. The DR1, DR2 and DR3 directions may be orthogonal directions in one embodiment.

Referring to FIG. 2A, at least one source select line may be disposed between the doped semiconductor structure DPS and the plurality of word lines WL1 to WLn. In an embodiment, a first source select line SSLa and a second source select line SSLb may be stacked spaced apart from each other in the third direction DR3 between the doped semiconductor structure DPS and the plurality of word lines WL1 to WLn.

Drain select lines constituting two or more groups may be disposed between the plurality of word lines WL1 to WLn and the doped semiconductor structure DPS. Drain select lines of groups adjacent to each other may be isolated from each other by a select line isolation structure SL_I. In an embodiment, the gate stack structure GST may include a drain select line DSLa1 or DSLb1 of a first group and a drain select line DSLa2 or DSLb2 of a second group, and the select line isolation structure SL_I may isolate the first and second groups from each other. The drain select line of each of the first and second groups may be disposed between the plurality of word lines WL1 to WLn and the bit line array structure BAS. Each of the first and second groups may include at least one drain select line disposed between the plurality of word lines WL1 to WLn and the bit line array structure BAS. In an embodiment, the first group may include a first drain select line DSLa1 and a second drain select line DSLb1, which are stacked spaced apart from each other in the third direction DR3 between the plurality of word lines WL1 to WLn and the bit line array structure BAS, and the second group may include a third drain select line DSLa2 and a fourth drain select line DSLb2, which are stacked spaced apart from each other in the third direction DR3 between the plurality of word lines WL1 to WLn and the bit line array structure BAS. Each of the plurality of word lines WL1 to WLn may extend to overlap with the select line isolation structure SL_I.

Referring to FIG. 3A, source select lines constituting two or more groups may be disposed between the doped semiconductor structure DSP and the plurality of word lines WL1 to WLn. Source select lines of groups adjacent to each other may be isolated from each other by a select line isolation structure SL_I′. In an embodiment, the gate stack structure GST may include a source select line SSLa1 or SSLb1 of a first group and a source select line SSLa2 or SSLb2 of a second group, and the select line isolation structure SL_I′ may isolate the first group and second group from each other. The source select line of each of the first and second groups may be disposed between the doped semiconductor structure DPS and the plurality of word lines WL1 to WLn. Each of the first and second groups may include at least one source select line disposed between the doped semiconductor structure DPS and the plurality of word lines WL1 to WLn. In an embodiment, the first group may include a first source select line SSLa1 and a second source select line SSLb1, which are stacked spaced apart from each other in the third direction DR3 between the doped semiconductor structure DPS and the plurality of word lines WL1 to WLn, and the second group may include a third source select line SSLa2 and a fourth source select line SSLb2, which are stacked spaced apart from each other in the third direction DR3 between the doped semiconductor structure DPS and the plurality of word lines WL1 to WLn. Each of the plurality of word lines WL1 to WLn may extend to overlap with the select line isolation structure SL_I′.

At least one drain select line may be disposed between the plurality of word lines WL1 to WLn and the bit line array structure BAS. In an embodiment, a first drain select line DSLa and a second drain select line DSLb may be stacked spaced apart from each other in the third direction DR3 between the plurality of word lines WL1 to WLn and the bit line array structure BAS.

FIG. 2B is a circuit diagram of a sub-cell array structure CAS[S] of the semiconductor memory device shown in FIG. 2A, and FIG. 3B is a circuit diagram of a sub-cell array structure CAS[S] of the semiconductor memory device shown in FIG. 3A.

Referring to FIGS. 2B and 3B, the sub-cell array structure CAS[S] may include a plurality of memory cell strings CS. The plurality of memory cell strings CS may be connected in parallel to a common source region CSR of the doped semiconductor structure DPS. The common source region CSR may include an n-type impurity. Each memory cell string CS may be connected to a bit line corresponding thereto among the plurality of bit lines BL. The common source region CSR may be connected to a plurality of channel layers of the plurality of memory cell strings CS, or be connected to a plurality of filling channel patterns of the plurality of memory cell strings CS. A plurality of bit lines BL may be connected to the plurality of channel layers of the plurality of memory cell strings CS, or be connected to a plurality of liner channel patterns of the plurality of cell strings CS.

Each memory cell string CS may include a first source select transistor SSTa, a second source select transistor SSTb, a plurality of memory cells MC1 to MCn, where n is a natural number of 2 or more, a first drain select transistor DSTa, and a second drain select transistor DSTb, which are connected in series. The plurality of memory cells MC1 to MCn may be connected in series between the second source select transistor SSTb and the first drain select transistor DSTa. The first source select transistor SSTa and the second source select transistor SSTb may be connected in series between the common source region CSR and the plurality of memory cells MC1 to MCn. The first drain select transistor DSTa and the second drain select transistor DSTb may be connected in series between a bit line BL corresponding thereto and the plurality of memory cells MC1 to MCn.

Each source select line SSLa, SSLb, SSLa1, SSLb1, SSLa2 or SSLb2 may be used as a gate electrode of a source select transistor corresponding thereto among the first and second source select transistors SSTa and SSTb. The plurality word lines WL1 to WLn may be used as a plurality of gate electrodes of the plurality of memory cells MC1 to MCn. Each drain select line DSLa1, DSLb1, DSLa2, DSLb2, DSLa or DSLb may be used as a gate electrode of a drain select transistor corresponding thereto among the first and second drain select transistors DSTa and DSTb.

The plurality of cell strings CS may be disposed on a plurality of columns and a plurality of rows. To improve the degree of integration of the semiconductor memory device, the number of rows controlled by each of the word lines WL1 to WLn may be increased. Specifically, memory cell strings CS arranged on two or more rows may be commonly controlled through each of the word lines WL1 to WLn. Memory cell strings of different rows, which are commonly controlled through each of the word lines WL1 to WLn may be connected to the same bit line. In an embodiment, the sub-cell array structure CAS[S] may include a first memory cell string CS[A] of a first row and a second memory cell string CS[B] of a second row, which are commonly controlled by each of the word lines WL1 to WLn. The first memory cell string CS[A] and the second memory cell string CS[B] may be connected to the same bit line BL.

Referring to FIG. 2B, the first memory cell string CS[A] and the second memory cell string CS[B] may be commonly connected to the first source select line SSLa or the second source select line SSLb and be individually connected to the drain select line DSLa1 or DSLb1 of the first group and the drain select line DSLa2 or DSLb2 of the second group, which are isolated from each other.

In accordance with the embodiment shown in FIG. 2B, the first memory cell string CS[A] may be selected by selecting one of the plurality of bit lines BL and the drain select lines (e.g., DSLa1 and DSL1b) of the first group. Similarly, the second memory cell string CS[B] may be selected by selecting one of the plurality of bit lines BL and the drain select lines (e.g., DSLa2 and DSLb2) of the second group.

Referring to FIG. 3B, the first memory cell string CS[A] and the second memory cell string CS[B] may be commonly connected to the first drain select line DSLa or the second drain select line DSLb and be individually connected to the source select line SSLa1 or SSLb1 of the first group and the source select line SSLa2 or SSLb2 of the second group, which are isolated from each other.

In accordance with the embodiment shown in FIG. 3B, the first memory cell string CS[A] may be selected by selecting one of the plurality of bit lines BL and the source select lines (e.g., SSLa1 and SSL1b) of the first group. Similarly, the second memory cell string CS[B] may be selected by selecting one of the plurality of bit lines BL and the source select lines (e.g., SSLa2 and SSLb2) of the second group.

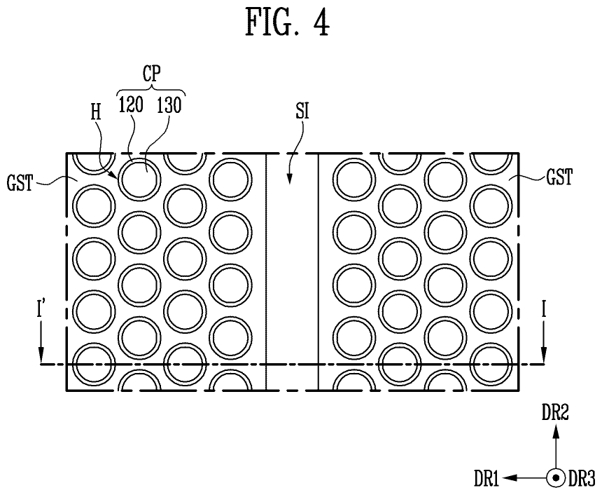

FIG. 4 is a plan view illustrating a gate stack structure of a semiconductor memory device in accordance with an embodiment of the present disclosure. FIG. 4 illustrates a portion of the gate stack structure GST between the slit SI and the select line isolation structure SL_I, which are shown in FIG. 2A.

Referring to FIG. 4, the semiconductor memory device may include a gate stack structure GST partitioned by a slit SI and a plurality of cell plugs CP surrounded by the gate stack structure GST. The memory cell string CS described with reference to FIG. 2B or 3B may be defined along each cell plug CP.

The gate stack structure GST may include a plurality of layers. The plurality of layers of the gate stack structure GST may extend in the first direction DR1 and the second direction DR2 and be stacked in the third direction DR3. The gate stack structure GST may include a plurality of channel holes H extending in the third direction DR3. The plurality of cell plugs CP may be disposed in the plurality of channel holes H. Each cell plug CP may include a memory layer 120 and a channel structure 130, which are disposed in the channel hole H. The memory layer 120 may be interposed between the channel structure 130 and the gate stack structure GST.

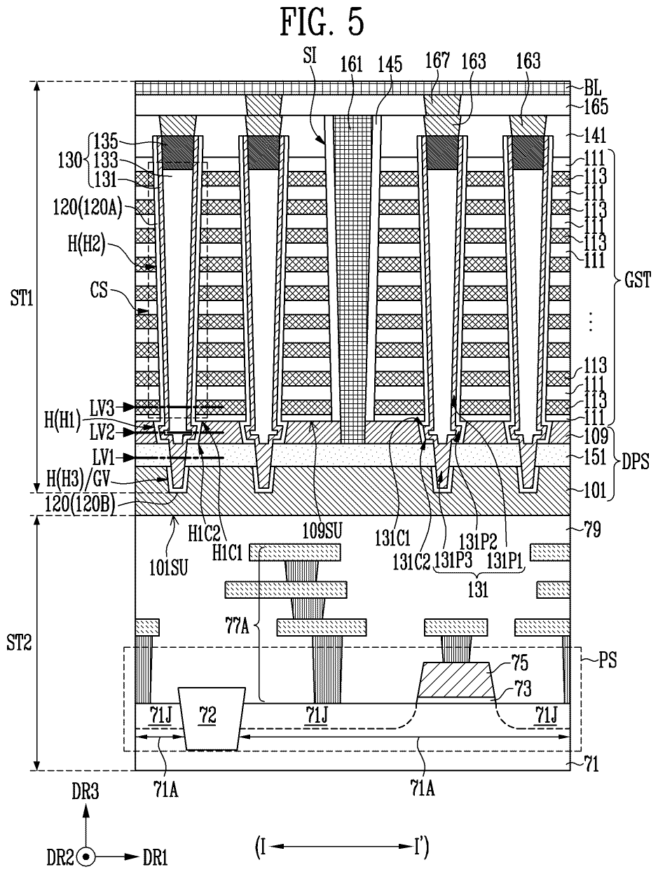

FIG. 5 is a sectional view of a semiconductor memory device in accordance with an embodiment of the present disclosure. FIG. 5 illustrates a sectional view of the semiconductor memory device taken along line I-I′ shown in FIG. 4.

Referring to FIG. 5, the semiconductor memory device may include a first structure ST1, a doped semiconductor structure DPS, and a second structure ST2. The first structure ST1 may include a bit line BL, a gate stack structure, and the cell plug CP described with reference to FIG. 4.

The doped semiconductor structure DPS may include a first surface 109SU and a second surface 101SU facing in a direction opposite to a direction in which the first surface 109SU faces. The doped semiconductor structure DPS may extend in the first direction DR1 and the second direction DR2, and the first surface 109SU may face in the third direction DR3. The third direction DR3 may be a direction in which an axis intersecting the first surface 109SU faces.

The doped semiconductor structure DPS may include first, second and third semiconductors layer 101, 109, and 151. The first semiconductor layer 101 may constitute the second surface 101SU of the doped semiconductor structure DPS. The second semiconductor layer 109 may constitute the first surface 109SU of the doped semiconductor structure DPS. The third semiconductor layer 151 may be disposed between the first semiconductor layer 101 and the second semiconductor layer 109. Each of the first, second, and third semiconductor layers, 101, 109, and 151 may include a doped region including at least one of a common source region and a well region. For example, each of the first, second, and third semiconductor layers, 101, 109, and 151 may include at least one of an n-type impurity and a p-type impurity. In an embodiment, each of the first, second, and third semiconductor layers, 101, 109, and 151 may include a first conductivity type doped region including the n-type impurity as a majority carrier. In another embodiment, each of the second and third semiconductor layers 109 and 151 may include the first conductivity type doped region including the n-type impurity as the majority carrier, and the first semiconductor layer 101 may include a second conductivity type doped region including the p-type impurity as a majority carrier. The first conductivity type doped region may include the common source region, and the second conductivity type doped region may include the well region. However, embodiments of the present disclosure are not limited thereto, and the doped region of each of the first, second, and third semiconductor layers, 101, 109, and 151 may vary. Each of the first, second, and third semiconductor layers, 101, 109, and 151 may include a semiconductor material such as silicon.

The gate stack structure GST may be positioned over or on the first surface 109SU of the doped semiconductor structure DPS. The gate stack structure GST may overlap with the first surface 109SU of the doped semiconductor structure DPS. The gate stack structure GST may include a plurality of conductive layers 113. The plurality of conductive layers 113 may be stacked on the first surface 109SU of the doped semiconductor structure DPS spaced apart from each other in the third direction DR3. The gate stack structure GST may further include a plurality of interlayer insulating layers 111. The plurality of conductive layers 113 and the plurality of interlayer insulating layers 111 may be alternately disposed one by one in the third direction DR3. The plurality of conductive layers 113 may include the source select lines (e.g., SSLa and SSLb), the plurality of word lines WL1 to WLn, and the drain select lines (e.g., DSLa1 and DSLb1), which are shown in FIGS. 2A and 3B. The plurality of conductive layers 113 may include at least one of a doped semiconductor layer, a metal layer, and a conductive metal nitride layer. The doped semiconductor layer may include a doped silicon layer. The metal layer may include tungsten, copper, molybdenum, and the like. The conductive metal nitride layer may include titanium nitride, tantalum nitride, and the like. The plurality of interlayer insulating layers 111 may include an insulating material such as a silicon oxide layer or a silicon oxynitride layer.

A sidewall insulating layer 145 may be formed on a sidewall of a slit SI. The plurality of conductive layers 113 may be covered by the sidewall insulating layer 145. A conductive contact structure 161 may be disposed in a central region of the slit SI. The conductive contact structure 161 may include at least one of a doped semiconductor layer, a metal layer, and a conductive metal nitride layer. The conductive contact structure 161 may be connected to the doped semiconductor structure DPS. In an embodiment, the conductive contact structure 161 may be in contact with the third semiconductor layer 151 and extend inside the slit SI while passing through the second semiconductor layer 109. However, embodiments of the present disclosure are not limited thereto. In another embodiment, the slit SI may be completely filled with an insulating material. In still another embodiment, the slit SI may be filled with different types of materials including an insulating material, a semiconductor material, a metal, and the like. The semiconductor material may include an amorphous semiconductor layer or a polycrystalline semiconductor layer, and include silicon (Si), germanium (Ge), or any mixture thereof. Unlike the conductive contact structure 161, the semiconductor material or metal in the slit SI may be insulated from the doped semiconductor structure DPS.

A channel structure 130 and a memory layer 120 of the cell plug may be disposed in a channel hole H. The channel hole H may pass through the gate stack structure GST and extend to the inside of the doped semiconductor structure DPS. The channel hole H may include a middle portion H1, a gate penetration portion H2, and an end portion H3. The middle portion H1 and the end portion H3 may be portions of the channel hole H disposed inside the doped semiconductor structure DPS. The gate penetration portion H2 may be a portion of the channel hole H penetrating the gate stack structure GST. The end portion H3 may be a portion of the channel hole H disposed inside the first semiconductor layer 101 of the doped semiconductor structure DPS, and the middle portion H1 may be a portion of the channel hole H penetrating the second semiconductor layer 109 of the doped semiconductor structure DPS between the gate penetration portion H2 and the end portion H3. The end portion H3 of the channel hole H may extend to the inside of the third semiconductor layer 151 to be connected to the middle portion H1.

The middle portion H1 of the channel hole H may have a first corner H1C1 and a second corner H1C2. The first corner H1C1 may be adjacent to the gate stack structure GST. The second corner H1C2 may be defined between the second surface 101SU of the doped semiconductor structure DPS and the first corner H1C1. A width of the middle portion H1 at a boundary between the gate stack structure GST and the doped semiconductor structure DSP is formed wider than a width of the gate penetration portion H2, thus the first corner H1C1 may be defined. A width of the middle portion H1 at a boundary between the second semiconductor layer 109 and the third semiconductor layer 151 is formed wider than a width of the end portion H3, thus second corner H1C2 may be defined.

According to the above-described structure of the channel hole H, the middle portion H1 of the channel hole H may define a concave portion at a sidewall of the doped semiconductor structure DPS and a convex portion at a sidewall of the channel hole H. The middle portion H1 of the channel hole H may extend in the second direction DR2 and the third direction DR3 to overlap with the gate stack structure GST.

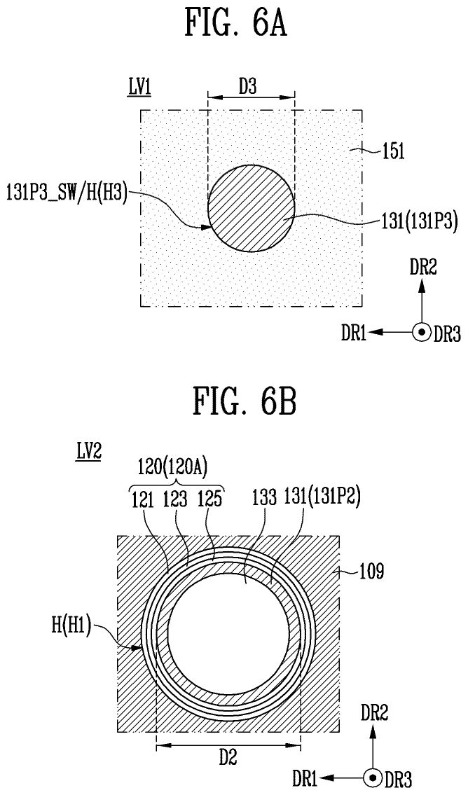

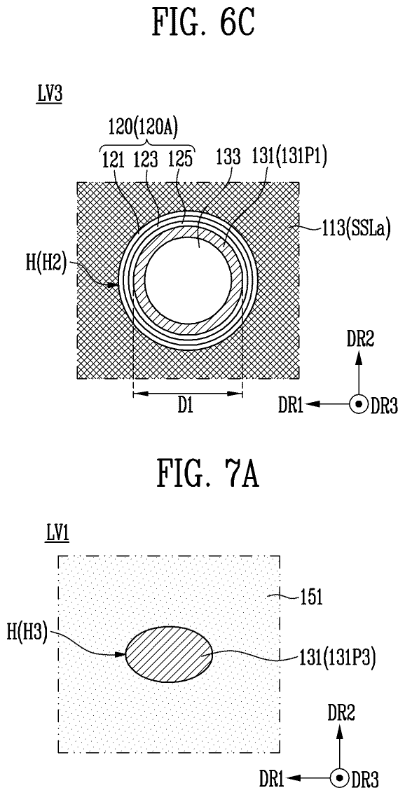

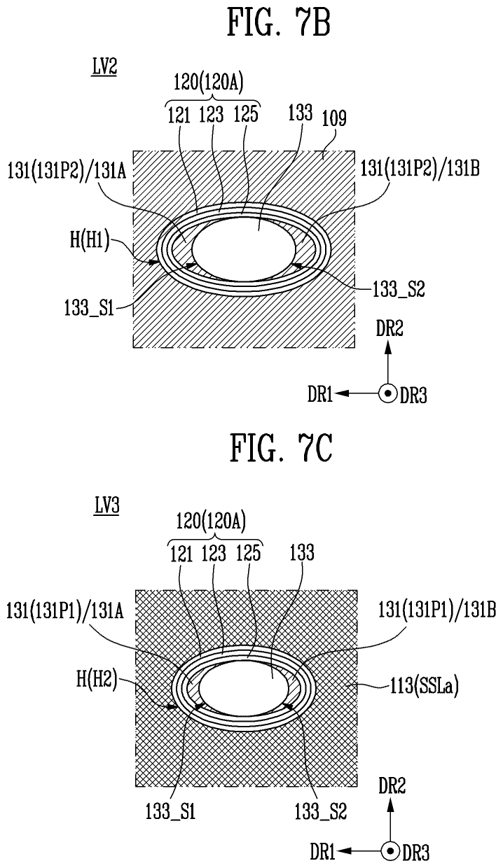

The channel structure 130 of the cell plug CP may include a channel layer 131. The channel layer 131 may include a semiconductor material to be used as a channel region of a memory cell string CS. In an embodiment, the channel layer 131 may include silicon (Si), germanium (Ge), or any mixture thereof. The memory layer 120 of the cell plug may include a blocking insulating layer 121, a data storage layer 123, and a tunnel insulating layer 125, like a memory layer 120 shown in FIGS. 6B and 6C or a memory layer 120 shown in FIGS. 7B and 7C.

The memory layer 120 may extend along the sidewall of the channel hole H and be divided into a first interposition layer 120A and a second interposition layer 120B by the third semiconductor layer 151 of the doped semiconductor structure DPS. The memory layer 120 configured with the first interposition layer 120A may be disposed between the channel layer 131 and the gate stack structure GST. The memory layer 120 configured with the second interposition layer 120B may be disposed between the channel layer 131 and the first semiconductor layer 101.

The channel layer 131 may include a first portion 131P1, a second portion 131P2, and a third portion 131P3. The first portion 131P1 may overlap with a sidewall of the gate stack structure GST defined along the gate penetration portion H2 of the channel hole H. The second portion 131P2 is a portion extending to the inside of the doped semiconductor structure DPS from the first portion 131P1, and may be a portion disposed in the middle portion H1 of the channel hole H. The third portion 131P3 is a portion extending toward the second surface 101SU of the doped semiconductor structure DPS from the second portion 131P2, and may be a portion disposed in the end portion H3 of the channel hole H. Similarly to the middle portion H1 of the channel hole H, the second portion 131P2 of the channel layer 131 may include a first corner 131C1 and a second corner 131C2. The first corner 131C1 of the second portion 131P2 in the channel layer 131 may be adjacent to the gate stack structure GST. The second corner 131C2 of the second portion 131P2 in the channel layer 131 may be disposed between the first corner 131C1 and the second surface 101SU of the doped semiconductor structure DPS.

The memory layer 120 configured with the first interposition layer 120A may be disposed between the first portion 131P1 of the channel layer 131 and the gate stack structure GST and extend to cover the first corner 131C1 in the channel layer 131. The memory layer 120 configured with the first interposition layer 120A may extend to cover the second corner 131C2 in the channel layer 131. For example, the memory layer 120 configured with the first interposition layer 120A may extend between the second semiconductor layer 109 of the doped semiconductor structure DPS and the second portion 131P2 of the channel layer 131. The memory layer 120 configured with the second interposition layer 120B may be disposed between the third portion 131P3 of the channel layer 131 and the first semiconductor layer 101.

The channel structure 130 may further include a core insulating layer 133 and a doped capping layer 135. The core insulating layer 133 may be disposed in a central region of the gate penetration portion H2 in the channel hole H, and extend to a central region of the middle portion H1 in the channel hole H. The first portion 131P1 of the channel layer 131 may protrude in the third direction DR3 as compared with the core insulating layer 133. The doped capping layer 135 may be disposed on the core insulating layer 133. The first portion 131P1 in the channel layer 131 may surround a sidewall of the core insulating layer 133. The doped capping layer 135 may be formed of a semiconductor layer including at least one of an n-type impurity and a p-type impurity. In an embodiment, the doped capping layer 135 may include the n-type impurity as a majority carrier. A portion of the channel layer 131 adjacent to the doped capping layer 135 may be doped with the same impurity as the doped capping layer 135.

The third portion 131P3 of the channel layer 131 may be formed in a pillar shape filling a central region of the end portion H3 in the channel hole H. The core insulating layer 133 may include an end portion facing the first surface 109SU of the doped semiconductor structure DPS. The third portion 131P3 may cover the end portion of the core insulating layer 133. An end of the third portion 131P3 and the second interposition layer 120B may be inserted into a groove GV included in the first semiconductor layer 101. The groove GV may constitute the end portion H3 of the channel hole H.

The third semiconductor layer 151 may be in contact with the third portion 131P3 of the channel layer 131. Accordingly, the conductive contact structure 161 and the channel layer 131 may be electrically connected to each other via the third semiconductor layer 151.

The channel structure 130 may include a portion protruding in the third direction DR3 as compared with the gate stack structure GST. The protruding portion of the channel structure 130 may be covered by a first insulating layer 141. The slit SI may extend to pass through the first insulating layer 141. The bit line BL may be spaced apart from the channel structure 130 with the first insulating layer 141 interposed therebetween. The bit line BL may be disposed directly on the first insulating layer 141 or overlap with the first insulating layer 141 with at least one insulating layer interposed therebetween. In an embodiment, a second insulating layer 165 may be disposed between the bit line BL and the first insulating layer 141. Hereinafter, the structure of the semiconductor memory device is described based on an embodiment in which the first insulating layer 141 and the second insulating layer 165 are disposed between the bit line BL and the channel structure 130, but embodiments of the present disclosure are not limited thereto.

The bit line BL may be electrically connected to a channel layer 131 of a channel structure corresponding thereto via at least one bit line contact. In an embodiment, the bit line BL may be electrically connected to the channel layer 131 corresponding thereto via a first bit line contact 163 and a second bit line contact 167. The first bit line contact 163 may be in contact with the doped capping layer 135 of the channel structure 130 while passing through the first insulating layer 141. The second bit line contact 167 may be connected to the first bit line contact 163 and the bit line BL while passing through the second insulating layer 165.

The second structure ST2 may include a semiconductor substrate 71, a peripheral circuit structure PS, an insulating structure 79, and a plurality of interconnections 77A. The peripheral circuit structure PS may correspond to the peripheral circuit structure described with reference to FIGS. 1A and 1B.

The semiconductor substrate 71 may include an active region 71A partitioned by an isolation layer 72. The peripheral circuit structure PS may include a transistor. The transistor may include a gate insulating layer 73, a gate electrode 75, and source/drain junctions 71J. The gate insulating layer 73 and the gate electrode 75 may be stacked on the active region 71A of the semiconductor substrate 71. The source/drain junctions 71J may be formed in the active region 71A at both sides of the gate electrode 75.

The plurality of interconnections 77A may include sub-interconnections individually connected to the gate electrode 75 and the source/drain junctions 71J. The semiconductor substrate 71 and the peripheral circuit structure PS may be covered by the insulating structure 79, and the plurality of interconnections 77A may be disposed inside the insulating structure 79.

The above-described second structure ST2 may be disposed adjacent to a side of the doped semiconductor structure DPS. A process of forming the doped semiconductor structure DPS and the first structure ST1, which is shown in FIG. 5, may be performed on the second structure ST2 after the second structure ST2 is formed.

FIGS. 6A, 6B, and 6C are plan views illustrating a cell plug in accordance with an embodiment of the present disclosure. FIG. 6A illustrates a cross-section of the cell plug at a first level LV1 shown in FIG. 5, FIG. 6B illustrates a cross-section of the cell plug at a second level LV2 shown in FIG. 5, and FIG. 6C illustrates a cross-section of the cell plug at a third level LV3 shown in FIG. 5.

Referring to FIGS. 5 and 6A to 6C, the first level LV1 may be a level at which the third semiconductor layer 151 is disposed, the second level LV2 may be a level at which the second semiconductor layer 109 is disposed, and the third level LV3 may be a level at which a lowermost conductive layer adjacent to the doped semiconductor structure DPS among the plurality of conductive layers 113 is disposed. In an embodiment, the third level LV3 may be a level at which the first source select line SSLa is disposed.

Referring to FIGS. 6A to 6C, the channel hole H may include a circular cross-sectional structure. A cross-section of the channel layer 131 may have a shape corresponding to the channel hole H. In an embodiment, the third portion 131P3 in the channel layer 131 may include a circular cross-sectional structure, and each of the first portion 131P1 and the second portion 131P2 in the channel layer 131 may include a ring-shaped cross-sectional structure.

Each of the first portion 131P1 and the second portion 131P2 in the channel layer 131 may surround a sidewall of the core insulating layer 133. The third portion 131P3 in the channel layer 131 may have a sidewall 131P3_SW in contact with the third semiconductor layer 151.

The first portion 131P1 may have a first external diameter D1 at the third level LV3, and an external diameter of the second portion 131P2 may be greater than each of the first external diameter D1 and an external diameter of the third portion 131P3. In an embodiment, the second portion 131P2 may have a second external diameter D2 at the second level LV2, and the third portion 131P3 may have a third external diameter D3 at the first level LV1. The second external diameter D2 may be greater than each of the first external diameter D1 and the third external diameter D3.

The third semiconductor layer 151 may surround the sidewall 131P3_SW of the third portion 131P3. The second semiconductor layer 109 may surround the second portion 131P2 with the memory layer 120 configured with the first interposition layer 120A, which is interposed therebetween. Each conductive layer 113 may surround the first portion 131P1 with the memory layer 120 configured with the first interposition layer 120A, which is interposed therebetween.

The memory layer 120 may include a blocking insulating layer 121, a data storage layer 123, and a tunnel insulating layer 125. Each of the blocking insulating layer 121, the data storage layer 123, and the tunnel insulating layer 125 may extend along an inner wall of the channel hole H. The blocking insulating layer 121 may be disposed between the inner wall of the channel hole H and the data storage layer 123, and the data storage layer 123 may be disposed between the blocking insulating layer 121 and the tunnel insulating layer 125.

The blocking insulating layer 121 may include an insulating material capable of blocking movement of charges. The tunnel insulating layer 125 may include an insulating material through which charges can tunnel. The blocking insulating layer 121 may include an insulating layer having a high dielectric constant as compared with the tunnel insulating layer 125. The data storage layer 123 may be formed of a material layer capable of storing data changed using Fowler-Nordheim tunneling. In an embodiment, the data storage layer 123 may be formed of an insulating layer including a charge trap insulating layer, a floating gate layer, or a conductive nano dot. The charge trap insulating layer may include a silicon nitride layer. However, embodiments of the present disclosure are not limited thereto, and the data storage layer 123 may be formed of a material layer capable of storing information, based on another operation principle instead of the Fowler-Nordheim tunneling. In an embodiment, the data storage layer 123 may include a phase change material layer, a ferroelectric layer, and the like.

FIGS. 7A, 7B, and 7C are plan views illustrating a cell plug in accordance with an embodiment of the present disclosure. FIG. 7A illustrates a cross-section of the cell plug at the first level LV1 shown in FIG. 5, FIG. 7B illustrates a cross-section of the cell plug at the second level LV2 shown in FIG. 5, and FIG. 7C illustrates a cross-section of the cell plug at the third level LV3 shown in FIG. 5.

Referring to FIGS. 7A to 7C, the channel hole H may include an elliptical cross-sectional structure. A cross-section of the channel layer 131 may include a shape corresponding to a cross-section of the channel hole H. In an embodiment, each of the first portion 131P1 and a second portion 131P2 in the channel layer 131 may include a crescent-moon-shaped cross-sectional structure, and the third portion 131P3 in the channel layer 131 may include an elliptical cross-sectional structure. Hereinafter, overlapping descriptions of components identical to those shown in FIGS. 6A to 6C may be simplified or omitted.

The core insulating layer 133 may include a first sidewall 133_S1 and a second sidewall 133_S2. Each of the first sidewall 133_S1 and the second sidewall 133_S2 may extend to the middle portion H1 from the gate penetration portion H2 of the channel hole H. Each of the first portion 131P1 and the second portion 131P2 in the channel layer 131 may be isolated into a first pattern 131A and a second pattern 131B. The first pattern 131A may extend along the first sidewall 133_S1 of the core insulating layer 133, and the second pattern 131B may extend along the second sidewall 133_S2 of the core insulating layer 133. The core insulating layer 133 between the first pattern 131A and the second pattern 131B may be in contact with the memory layer configured with the first interposition layer 120A. The third portion 131P3 in the channel layer 131 may include a connection portion connecting the first pattern 131A and the second pattern 131B to each other.

The third semiconductor layer 151 may be electrically connected to the first pattern 131A and the second pattern 131B of the channel layer 131 via the third portion 131P3 of the channel layer 131 in contact therewith. The entire inner wall of the third semiconductor layer 151 along the third portion 131P3 of the channel layer 131 may form a common surface. To form such a structure, a portion of the memory layer 120 surrounding the third portion 131P3 of the channel layer 131 may be removed in a process of forming the semiconductor memory device. The third portion 131P3 of the channel layer 131 may serve as an etch stop layer, and thus a phenomenon in which the core insulating layer 133 is exposed may be reduced or prevented.

The memory layer 120 may include a blocking insulating layer 121, a data storage layer 123, and a tunnel insulating layer 125 as described with reference to FIGS. 6A to 6C.

A maximum width of the middle portion H1 in the channel hole H may be greater than a maximum width of the end portion H3 in the channel hole H. The maximum width of the middle portion H1 in the channel hole H may be greater than a maximum width of the gate penetration portion H2 at the third level LV3 at which the lowermost conductive layer 113 used as the first source select line SSLa is disposed. Accordingly, the channel hole H may have a convex sidewall protruding toward the second semiconductor layer 109 at the second level LV2 at which the second semiconductor layer 109 is disposed.

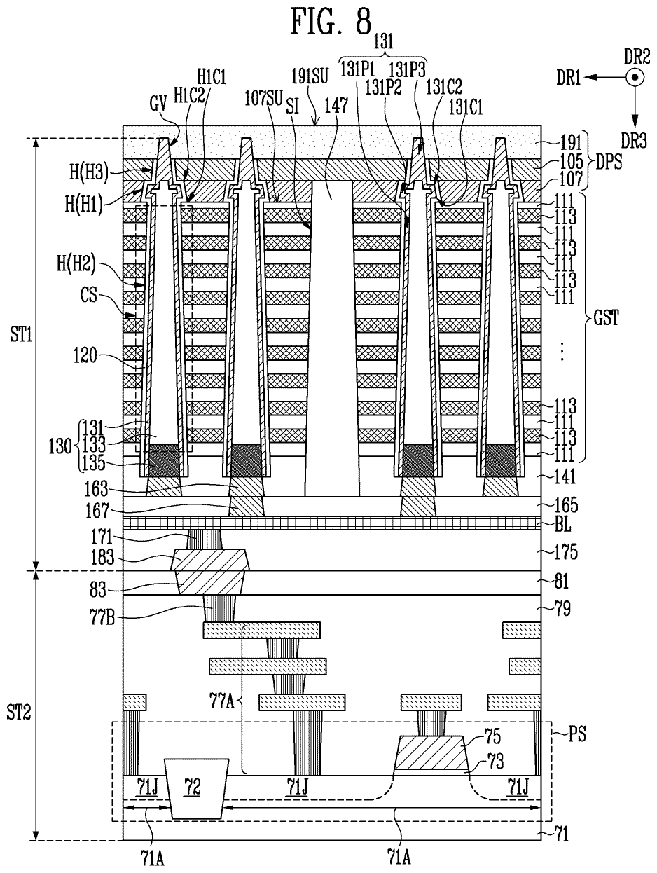

FIG. 8 is a sectional view of a semiconductor memory device in accordance with an embodiment of the present disclosure. Hereinafter, overlapping descriptions of components identical to those shown in FIG. 5 may be simplified or omitted.

Referring to FIG. 8, the semiconductor memory device may include a first structure ST1, a second structure ST2, and a doped semiconductor structure DPS.

As described with reference to FIG. 5, the doped semiconductor structure DPS may extend in the first direction DR1 and the second direction DR2, and include a first surface 107SU facing in the third direction DR3 and a second surface 191SU facing in a direction opposite to the direction in which the first surface 107SU faces. The doped semiconductor structure DPS may include a first semiconductor layer 105, a second semiconductor layer 107, and a third semiconductor layer 191. The first semiconductor layer 105 may be disposed between the second semiconductor layer 107 and the third semiconductor layer 191. The second semiconductor layer 107 may constitute the first surface 107SU and be disposed between the first semiconductor layer 105 and a gate stack structure GST. The third semiconductor layer 191 may constitute the second surface 191SU. Each of the first semiconductor layer 105, the second semiconductor layer 107, and the third semiconductor layer 191 may include a doped region including at least one of a common source region and a well region. For example, each of the first semiconductor layer 105, the second semiconductor layer 107, and the third semiconductor layer 191 may include at least one of an n-type impurity and a p-type impurity. In an embodiment, each of the first semiconductor layer 105 and the second semiconductor layer 107 may include a first conductivity type doped region including the n-type impurity as a majority carrier, and the third semiconductor layer 191 may include the first conductivity type doped region including the n-type impurity as the majority carrier and a second conductivity type doped region including the p-type impurity as a majority carrier. However, embodiments of the present disclosure are not limited thereto, and the doped region of each of the first semiconductor layer 105, the second semiconductor layer 107, and the third semiconductor layer 191 may vary. Each of the first semiconductor layer 105, the second semiconductor layer 107, and the third semiconductor layer 191 may include a semiconductor material such as silicon.

The first structure ST1 may include the gate stack structure GST, the cell plug CP shown in FIG. 4, a bit line BL, a first contact 171, and a first conductive bonding pad 183.

The gate stack structure GST may be disposed between the doped semiconductor structure DPS and the bit line BL. As described with reference to FIG. 5, the gate stack structure GST may include a plurality of conductive layers 113 and a plurality of interlayer insulating layers 111. The plurality of conductive layers 113 may be stacked spaced apart from each other in the third direction DR3 on the first surface 107SU of the doped semiconductor structure DPS.

In an embodiment, a slit SI may be filled with a sidewall insulating layer 145 and a conductive contact structure 161 as shown in FIG. 5. In another embodiment, the slit SI may be filled with an insulating material 147 as shown in FIG. 8. Although not shown in the drawing, in still another embodiment, the slit SI may be filled with different types of materials including an insulating material, a semiconductor material, a metal, and the like. The semiconductor material may include an amorphous semiconductor layer or a polycrystalline semiconductor layer, and include silicon (Si), germanium (Ge), or any mixture thereof.

As described with reference to FIG. 4, the gate stack structure GST may include a channel hole H.

Referring to FIG. 8, the channel hole H may include a gate penetration portion H2 penetrating the gate stack structure GST, a middle portion H1 penetrating the second semiconductor layer 107, and an end portion H3 penetrating the first semiconductor layer 105. The third semiconductor layer 191 may include a groove overlapping with the end portion H3 of the channel hole H. A cross-sectional structure of each of the channel hole H and the groove GV may have a circular shape as shown in FIGS. 6A to 6C, or have an elliptical shape as shown in FIGS. 7A to 7C. However, embodiments of the present disclosure are not limited thereto, and the cross-sectional structure of each of the channel hole H and the groove GV may be implemented in various shapes such as a polygonal shape and a semicircular shape. As described with reference to FIG. 5, a first corner H1C1 and a second corner H1C2 may be defined at the middle portion H1 of the channel hole H.

A memory layer 120 and a channel structure 130 of the cell plug may be disposed in the channel hole H. As described with reference to FIG. 5, the channel structure 130 of the cell plug may include a channel layer 131 provided as a channel region of a memory cell string CS, and further include a core insulating layer 133 and a doped capping layer 135.

The memory layer 120 of the cell plug may include a blocking insulating layer 121, a data storage layer 123, and a tunnel insulating layer 125 as described with reference to FIGS. 6B and 6C.

The channel layer 131 may include a first portion 131P1 disposed inside the gate penetrating portion H2 of the channel hole H, a second portion 131P2 extending to the inside of the middle portion H1 of the channel hole H from the first portion 131P1, and a third portion 131P3 extending to the inside of the end portion H3 of the channel hole H and the groove GV of the third semiconductor layer 191 from the second portion 131P2. As described with reference to FIG. 5, the second portion 131P2 of the channel layer 131 may include a first corner 131C1 and a second corner 131C2, and a sidewall of the second portion 131P2 may be surrounded by the second semiconductor layer 107. The third portion 131P3 of the channel layer 131 may include a sidewall surrounded by the first semiconductor layer 105 and an end in contact with the third semiconductor layer 191. Cross-sectional structures of the first portion 131P1, the second portion 131P2, and the third portion 131P3 may be the same as the cross-sectional structures shown in FIGS. 6A to 6C or be the same as the cross-sectional structures shown in FIGS. 7A to 7C. However, embodiments of the present disclosure are not limited thereto, and the cross-sectional structures of the first portion 131P1, the second portion 131P2, and the third portion 131P3 may have various shapes such as a semicircular shape and a polygonal shape according to the cross-sectional structure of each of the channel hole H and the groove GV.

The memory layer 120 may be disposed between the gate stack structure GST and the first portion 131P1 of the channel layer 131 and extend between the doped semiconductor structure DPS and the channel layer 131 to cover the first corner 131C1 and the second corner 131C2 of the channel layer 131. In an embodiment, the memory layer 120 may extend between the second semiconductor layer 107 and the channel layer 131 and extend between the first semiconductor layer 105 and the channel layer 131.

As described with reference to FIG. 5, the bit line BL may be electrically connected to the channel layer 131 of the channel structure 130 through a first bit line contact 163 penetrating a first insulating layer 141 and a second bit line contact 167 penetrating a second insulating layer 165. The bit line BL may be disposed between the gate stack structure GST and a third insulating layer 175. The third insulating layer 175 may include a single-layer insulating layer or multi-layer insulating layers each having at least two layers. The first contact 171 and the first conductive bonding pad 183 may be disposed in the third insulating layer 175. The first conductive bonding pad 183 may be electrically connected to the bit line BL via the first contact 171.

The second structure ST2 may include a semiconductor substrate 71, a peripheral circuit structure PS, an insulating structure 79, and a plurality of interconnections 77A as described with reference to FIG. 5. The second structure ST2 may further include a second contact 77B and a second conductive bonding pad 83.

As described with reference to FIG. 5, the semiconductor substrate 71 may include an active region 71A partitioned by an isolation layer 72. As described with reference to FIG. 5, the peripheral circuit structure PS may include a transistor including a gate insulating layer 73, a gate electrode 75, and source/drain junctions 71J. As described with reference to FIG. 5, the semiconductor substrate 71 and the peripheral circuit structure PS may be covered by the insulating structure 79, and the plurality of interconnections 77A may be disposed inside the insulating structure 79. A fourth insulating layer 81 may be disposed between the insulating structure 79 and the third insulating layer 175. The second contact 77B may be in contact with a sub-interconnection corresponding thereto among the plurality of interconnections 77A and extend to contact the second conductive bonding pad 83. The second conductive bonding pad 83 may be disposed in the fourth insulating layer 81. The second conductive bonding pad 83 may be in contact with the first conductive bonding pad 183.

The memory cell string CS of the first structure ST1 and the peripheral circuit structure PS of the second structure ST2 may be electrically connected to each other via the first conductive bonding pad 183 and the second conductive bonding pad 83. In an embodiment, the first conductive bonding pad 183 may be connected to the memory cell string CS via the first contact 171, the bit line BL, and the first and second bit line contacts 163 and 167, and the second conductive bonding pad 83 may be connected to the junction 71J constituting the transistor of a page buffer circuit via the second contact 77B and the interconnection 77A. When the first conductive bonding pad 183 and the second conductive bonding pad 83 in accordance with this embodiment are in contact with each other, the memory cell string CS may be electrically connected to the peripheral circuit structure PS via the bit line BL, the first contact 171, the first conductive bonding pad 183, the second conductive bonding pad 83, and the interconnection 77A.

The first structure ST1 and the second structure ST2, which are described above, may be provided through individual processes. A bonding process is performed such that the first conductive bonding pad 183 and the second conductive bonding pad 83 are in contact with each other. Thus, the first structure ST1 and the second structure ST2 may be structurally connected to each other. The doped semiconductor structure DPS may be provided after the bonding process.

The first conductive bonding pad 183 and the second conductive bonding pad 83 may include copper, a copper alloy, or the same kind of metal. The first conductive bonding pad 183 and the second conductive bonding pad 83 may further include a barrier layer such as a metal nitride layer.

Referring to FIGS. 5 and 8, the channel layer 131 may include the first corner 131C1 and the second corner 131C2 inside the doped semiconductor structure DPS. An etching material used in a process of removing a portion of the memory layer 120 to expose a portion of the channel layer 131 has difficulty in being introduced between the gate stack structure GST and the channel layer 131 by the first corner 131C1 and the second corner 131C2 of the channel layer 131. Accordingly, in accordance with the embodiment of the present disclosure, a phenomenon in which the memory layer 120 is lost between the gate stack structure GST and the channel layer 131 may be reduced, and a leakage current caused by the loss of the memory layer 120 may be reduced.

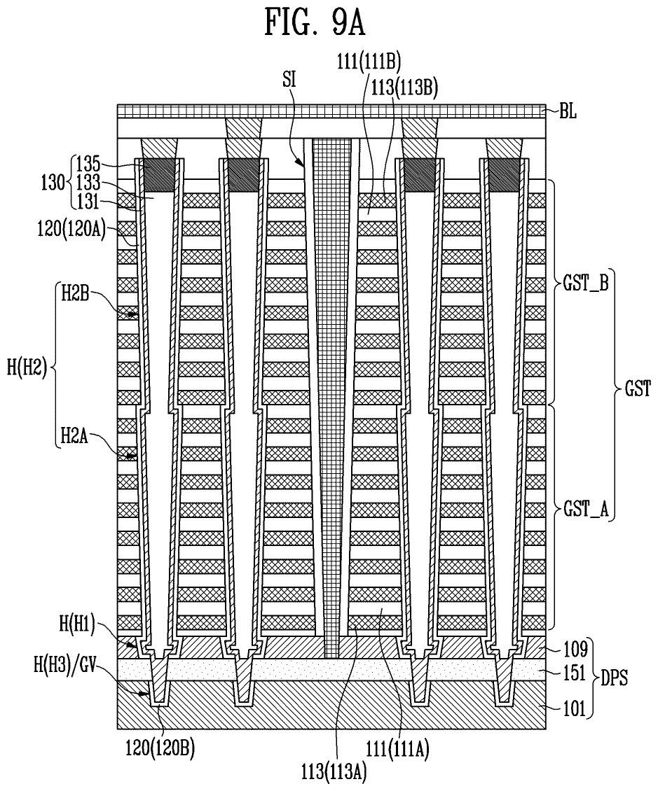

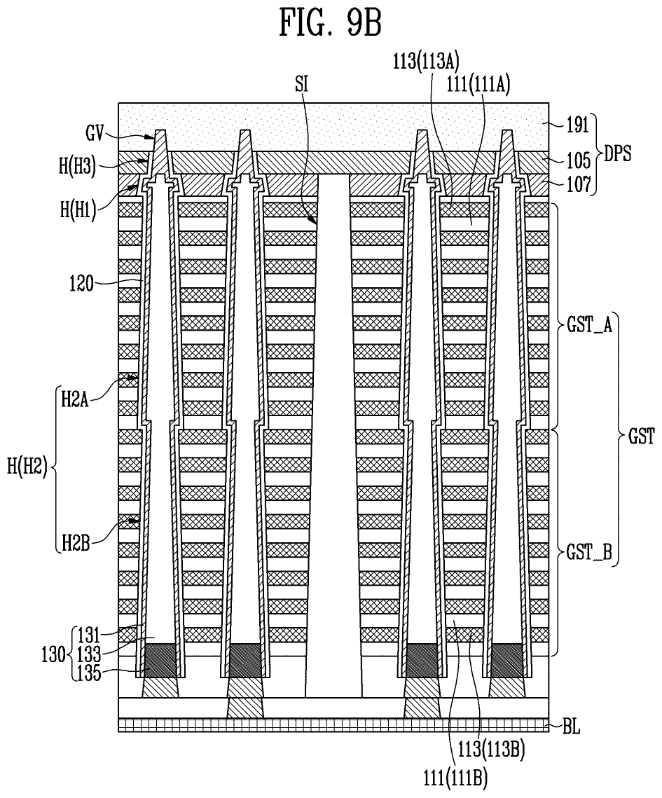

FIGS. 9A and 9B are sectional views of semiconductor memory devices in accordance with embodiments of the present disclosure. FIGS. 9A and 9B illustrate first structures in accordance with embodiments of the present disclosure. A structure shown in FIG. 9A may substitute for the first structure ST1 shown in FIG. 5, and a structure shown in FIG. 9B may substitute for the first structure ST1 shown in FIG. 8. Hereinafter, overlapping descriptions of components identical to those shown in FIGS. 5 and 8 may be simplified or omitted.

Referring to FIGS. 9A and 9B, a gate stack structure GST of each of the semiconductor memory devices may be divided into two or more sub-stack structures stacked between a doped semiconductor structure DPS and a bit line BL. In an embodiment, the gate stack structure GST may be divided into a first sub-gate stack structure GST_A adjacent to the doped semiconductor structure DPS and a second sub-gate stack structure GST_B between the first sub-gate stack structure GST_A and the bit line BL. Hereinafter, the embodiments of the present disclosure are described based on the gate stack structure GST configured with two sub-stack structures including the first sub-gate stack structure GST_A and the second sub-gate stack structure GST_B, but the embodiments of the present disclosure are not limited thereto. For example, the gate stack structure GST may be configured with three or more sub-stack structures.

A plurality of conductive layers 113A and 113B of the gate stack structure GST may be divided into a plurality of first conductive layers 113A of the first sub-gate stack structure GST_A and a plurality of second conductive layers 113B of the second sub-gate stack structure GST_B. A plurality of interlayer insulating layers 111 of the gate stack structure GST may be divided into a plurality of first interlayer insulating layers 111A of the first sub-gate stack structure GST_A and a plurality of second interlayer insulating layers 111B of the second sub-gate stack structure GST_B. A slit SI may extend to partition the first sub-gate stack structure GST_A and the second sub-gate stack structure GST_B, and be filled with various materials as described with reference to FIGS. 5 and 8.

A gate penetration portion H2 of a channel hole H may be formed in a connection structure of penetration portions respectively passing through the sub-gate stack structures of the gate stack structure GST. Due to a width difference between the penetration portions at an interface between the sub-gate stack structures, a corner of the gate penetration portion H2 may be defined while being adjacent to the interface between the sub-gate stack structures. In an embodiment, the gate penetration portion H2 of the channel hole H may be formed in a connection structure between a first penetration portion H2A penetrating the first sub-gate stack structure GST_A and a second penetration portion H2B passing through the second sub-gate stack structure GST_B. A width of the first penetration portion H2A and a width of the second penetration portion H2B may be different from each other at a level at which an interface between the first sub-gate stack structure GST_A and the second sub-gate stack structure GST_B is disposed. According to this structure, a corner may be defined at a sidewall of the gate penetration portion H2. The corner may be formed at the level at which the interface between the first sub-gate stack structure GST_A and the second sub-gate stack structure GST_B is disposed.

A middle portion H1 and an end portion H3 of the channel hole H may be disposed inside the doped semiconductor structure DPS as described with reference to FIGS. 5 and 8.

In an embodiment, referring to FIG. 9A, the doped semiconductor structure DPS may include first, second, and third semiconductor layers 101, 109, and 151 as described with reference to FIG. 5. The end portion H3 of the channel hole H may be a portion of the channel hole H disposed inside the first semiconductor layer 101 of the doped semiconductor structure DPS, and the middle portion H1 of the channel hole H may be a portion of the channel hole H passing through the second semiconductor layer 109 of the doped semiconductor structure DPS between the gate penetration portion H2 and the end portion H3. The end portion H3 of the channel hole H may extend to the inside of the third semiconductor layer 151 to be connected to the middle portion H1. The first semiconductor layer 101 may include a groove GV configured with the end portion H3 of the channel hole H.

In another embodiment, referring to FIG. 9B, the doped semiconductor structure DPS may include a first semiconductor layer 105, a second semiconductor layer 107, and a third semiconductor layer 191 as described with reference to FIG. 8. An end portion H3 of a channel hole H may be a portion of the channel hole disposed inside the first semiconductor layer 105 of the doped semiconductor structure DPS, and a middle portion H1 of the channel hole H may be a portion of the channel hole H disposed inside the second semiconductor layer 107. The third semiconductor layer 191 may include a groove GV overlapping with the end portion H3 of the channel hole H.

Referring to FIGS. 9A and 9B, a memory layer 120 and a channel structure 130 may be disposed inside the channel hole H having the above-described structure. The channel structure 130 may include a channel layer 131, a core insulating layer 133, and a doped capping layer 135. The doped capping layer 135 may be electrically connected to the bit line BL. Each of the channel layer 131 and the memory layer 120 may include a corner portion corresponding to the corner formed at the sidewall of the gate penetration portion H2.

Referring to FIG. 9A, the memory layer 120 may be divided into a first interposition layer 120A and the second interposition layer 120B by the third semiconductor layer 151 of the doped semiconductor structure DPS as described with reference to FIG. 5. The third semiconductor layer 151 may be in contact with a sidewall of the channel layer 131.

Referring to FIG. 9B, the channel layer 131 may extend to the inside of the groove GV of the third semiconductor layer 191 as described with reference to FIG. 8. The third semiconductor layer 191 may be in contact with the channel layer 131.

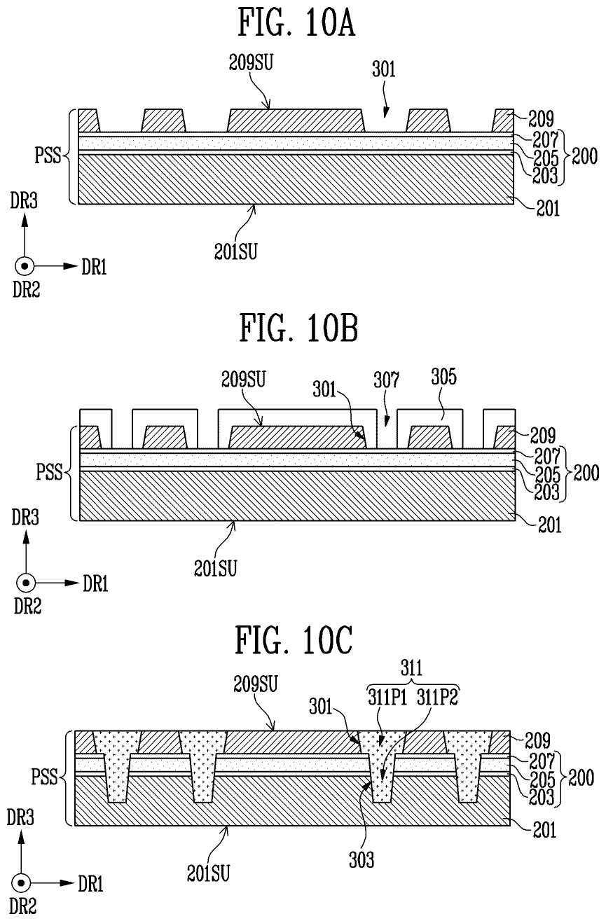

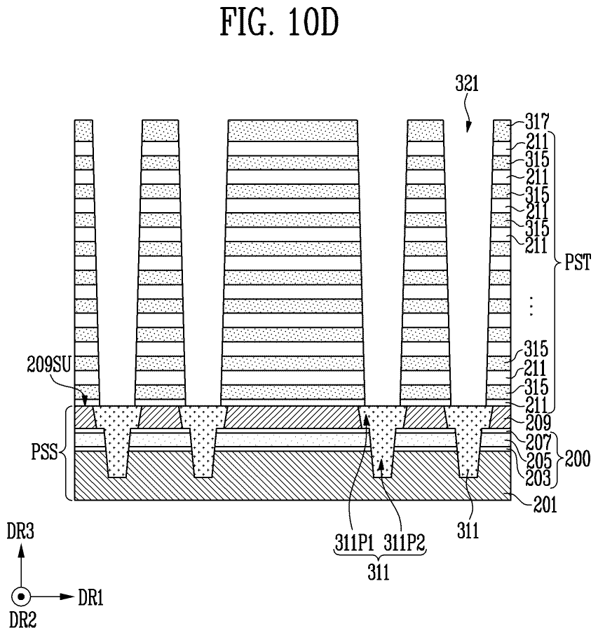

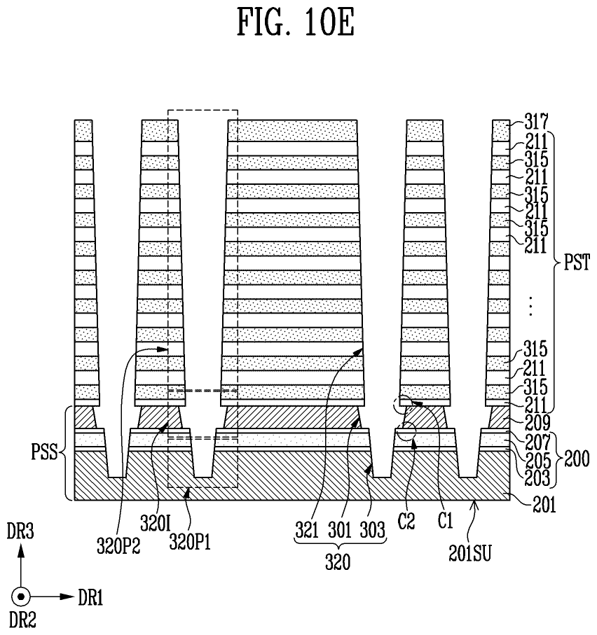

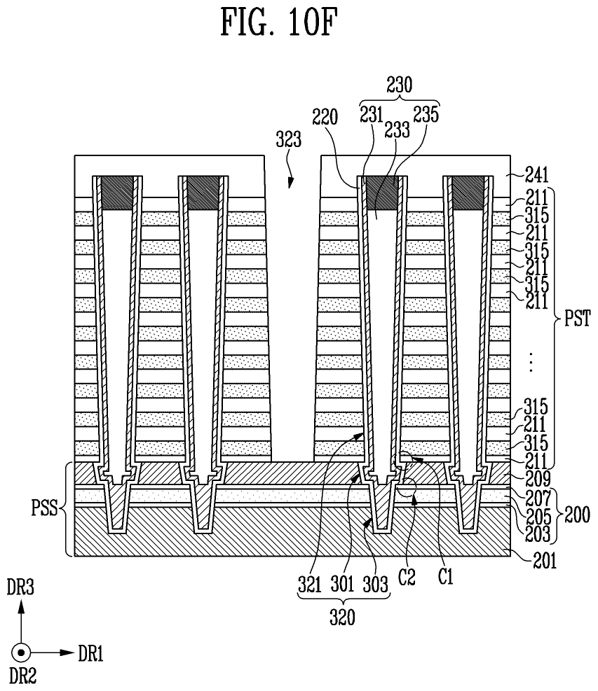

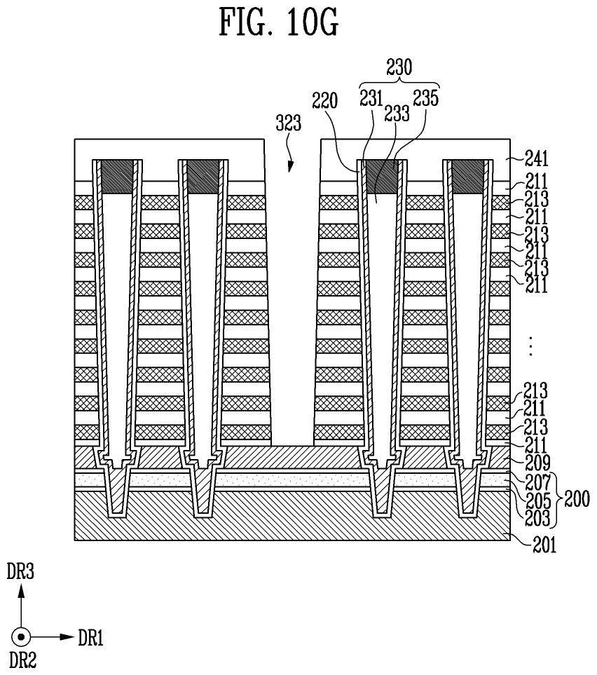

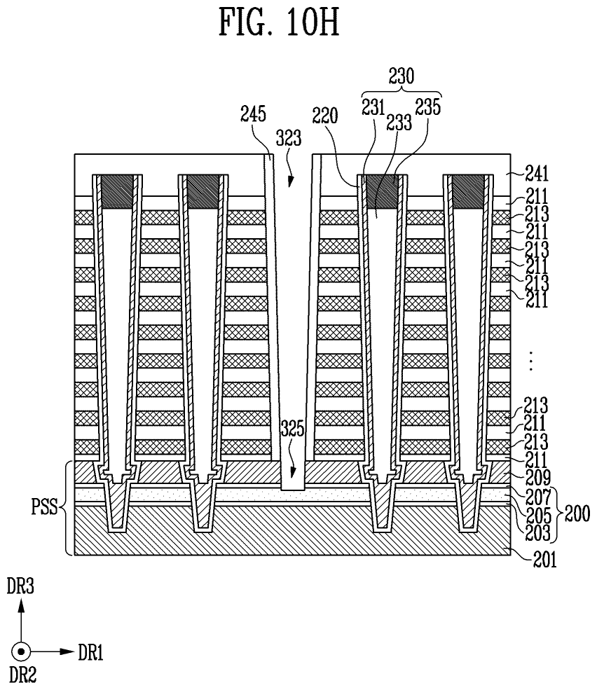

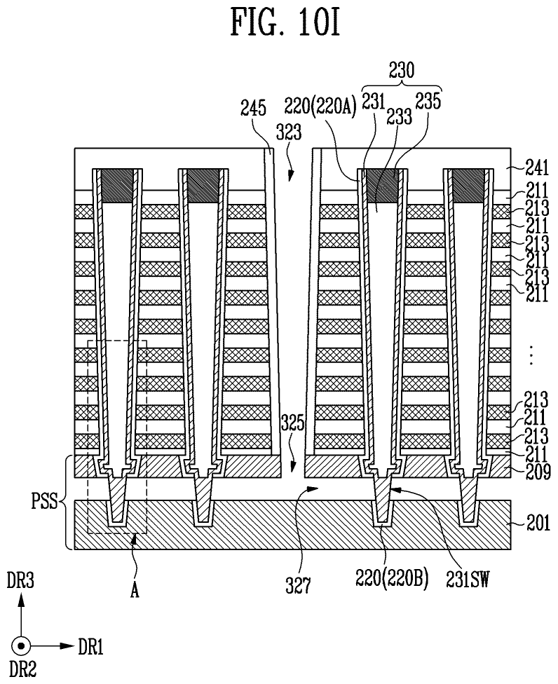

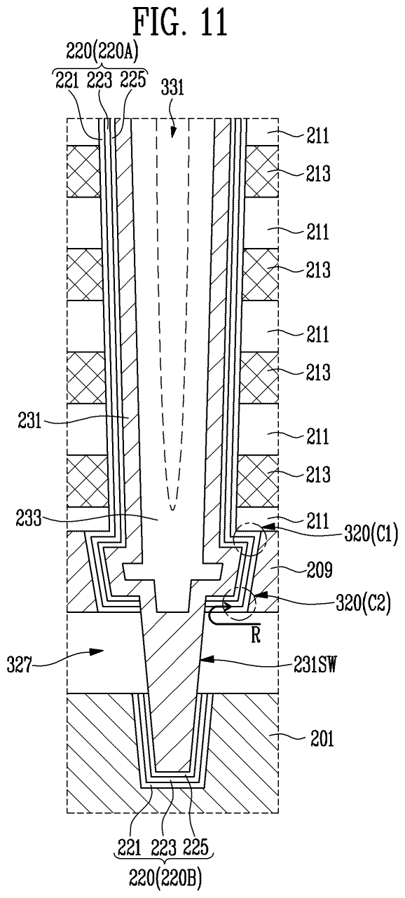

FIGS. 10A to 101, 11, and 12 are sectional views illustrating a manufacturing method of a semiconductor memory device in accordance with an embodiment of the present disclosure.

FIGS. 10A to 10I are sectional views illustrating process operations of a manufacturing method of a semiconductor memory device taken along the line I-I′ shown in FIG. 4.

Referring to FIG. 10A, a preliminary semiconductor structure PSS may be formed. The preliminary semiconductor structure PSS may include a first surface 209SU and a second surface 201SU, which extend in the first direction DR1 and the second direction DR2. The second surface 201SU may face in a direction opposite to a direction in which the first surface 209SU faces. Hereinafter, the third direction DR3 may be a direction in which an axis intersecting the first surface 209SU faces and be defined as the direction in which the first surface 209SU faces.

In an embodiment, the preliminary semiconductor structure PSS may include a first semiconductor layer 201, a sacrificial stack structure 200, and a second semiconductor layer 209.

The first semiconductor layer 201 may be formed on a lower structure including the second structure ST2 shown in FIG. 5. The second surface 201SU of the preliminary semiconductor structure PSS may be configured with the first semiconductor layer 201. The first semiconductor layer 201 may include at least one of an n-type impurity and a p-type impurity. In an embodiment, the first semiconductor layer 201 may include a doped silicon layer.

The sacrificial stack structure 200 may be formed on the first semiconductor layer 201. The sacrificial stack structure 200 may include at least one material layer having an etch selectivity with respect to the first semiconductor layer 201. In an embodiment, the sacrificial stack structure 200 may be formed in a single-layer structure including a sacrificial layer 205. In another embodiment, the sacrificial stack structure 200 may be formed in a multi-layer structure including a first protective layer 203, the sacrificial layer 205 on the first protective layer 203, and a second protective layer 207 on the sacrificial layer 205. The sacrificial layer 205 may include a material having an etch selectivity with respect to the first semiconductor layer 201. In an embodiment, the sacrificial layer 205 may include a nitride layer or an undoped silicon layer. Each of the first protective layer 203 and the second protective layer 207 may include at least one of an oxide layer and a nitride layer by considering an etch selectivity thereof. In an embodiment, each of the first protective layer 203 and the second protective layer 207 may be formed as a single layer formed with an oxide layer or be formed as a double layer or a triple layer, which is formed with a combination of an oxide layer and a nitride layer. The first protective layer 203 and the second protective layer 207 may be formed in the same structure or be formed in different structures. In an embodiment, the first protective layer 203 may be formed in a double-layer structure of an oxide layer and a nitride layer, and the second protective layer 207 may be formed in a single-layer structure of an oxide layer.

The second semiconductor layer 209 may be formed on the sacrificial stack structure 200. The first surface 209SU of the preliminary semiconductor structure PSS may be configured with the second semiconductor layer 209. The second semiconductor layer 209 may include at least one of an n-type impurity and a p-type impurity. The second semiconductor layer 209 may include a material layer having an etch selectivity with respect to the sacrificial stack structure 200. In an embodiment, the second semiconductor layer 209 may include doped silicon.

Subsequently, a first opening 301 may be formed. The first opening 301 may pass through the first surface 209SU of the preliminary semiconductor structure PSS and extend to the inside of the preliminary semiconductor structure PSS. Although not shown in the drawing, a mask layer may be formed on the preliminary semiconductor structure PSS before the first opening 301 is formed. In an embodiment, the mask layer may include an oxide layer.

The first opening 301 may pass through the second semiconductor layer 209 of the preliminary semiconductor structure PSS.

Referring to FIG. 10B, a spacer layer 305 may be formed to cover a sidewall of the first opening 301 and the first surface 209SU of the preliminary semiconductor structure PSS. When the mask layer (not shown) described with reference to FIG. 10A remains on the second semiconductor layer 209, the spacer layer 305 may extend to cover a sidewall of the mask layer. The spacer layer 305 may include a penetration hole 307 exposing a central region of the first opening 301. The spacer layer 305 may include a material having an etch selectivity with respect to the first semiconductor layer 201, the second semiconductor layer 209, and the sacrificial layer 205. In an embodiment, the spacer layer 305 may include an oxide layer. In another embodiment, the spacer layer 305 may include a carbon layer, a carbon doping layer, a high dielectric layer doped with a metal, a metal oxide layer, and the like. For example, the spacer layer 305 may be formed of an aluminum oxide (Al₂O₃) or a silicon carbon nitride (SiCN).

Referring to FIG. 10C, a portion of the sacrificial stack structure 200 and a portion of the first semiconductor layer 201, which are exposed through the penetration hole 307 shown in FIG. 10B, may be etched through an etching process using the spacer layer 305 shown in FIG. 10B as an etch barrier. Accordingly, a second opening 303 may be formed. The second opening 303 may be formed with a width narrower than a width of the first opening 301. The second opening 303 may extend to the inside of the first semiconductor layer 201 while passing through the sacrificial stack structure 200. The first and second openings 301 and 303 may each be slightly tapered having a larger cross-section at a higher level thereof and a lower cross-section at a lower level thereof.

After the second opening 303 is formed, the spacer layer 305 shown in FIG. 10B may be removed. After that, a sacrificial structure 311 may be formed to fill the first opening 301 and the second opening 303. The sacrificial structure 311 may include a material having an etch selectivity with respect to the preliminary semiconductor structure PSS. In an embodiment, the sacrificial structure 311 may include a metal such as tungsten. The sacrificial structure 311 may further include a barrier layer. The barrier layer may be formed along an interface between the metal and the preliminary semiconductor structure PSS. The barrier layer may include a metal nitride layer such as a titanium nitride layer.

According to the processes described with reference to FIGS. 10A to 10C, the sacrificial structure 311 may include a first portion 311P1 filling the first opening 301 and a second portion 311P2 filling the second opening 303. The first portion 311P1 may be adjacent to the first surface 209SU of the preliminary semiconductor structure PSS and pass through the second semiconductor layer 209. The second portion 311P2 may extend toward the second surface 201SU of the preliminary semiconductor structure PSS from the first portion 311P1 and extend to the inside of the first semiconductor layer 201 while passing through the sacrificial stack structure 200. The first portion 311P1 may be formed with a width greater than the width of the second portion 311P2. In an embodiment, the sacrificial structure 311 may have a T-shaped longitudinal sectional structure.

Referring to FIG. 10D, a plurality of first material layers 211 and a plurality of second material layers 315 may be alternately stacked one by one on the first surface 209SU of the preliminary semiconductor structure PSS. Accordingly, a preliminary stack structure PST may be formed. The preliminary stack structure PST may extend to cover the first surface 209SU of the preliminary semiconductor structure PSS and the sacrificial structure 311.

The plurality of second material layers 315 may be formed of a material having an etch selectivity with respect to the plurality of first material layers 211. In an embodiment, the plurality of first material layers 211 may include an insulating material such as a silicon oxide layer or a silicon oxynitride layer, and the plurality of second material layers 315 may include a sacrificial insulating material such as a silicon nitride layer. The sacrificial insulating material may be replaced with a conductive material including at least one of a doped semiconductor layer, a metal layer, and a conductive metal nitride layer in a subsequent process. In another embodiment, the plurality of first material layers 211 may include a sacrificial material such as an undoped silicon layer, and the plurality of second material layers 315 may include a conductive material such as a doped silicon layer. The sacrificial material may be replaced with an insulating material including a silicon oxide layer, a silicon oxynitride layer, and the like in a subsequent process.

Unlike as described above, the plurality of first material layers 211 may be formed of an insulating material, and the plurality of second material layers 315 may be formed of a conductive material. In an embodiment, the plurality of first material layers 211 may include a silicon oxide layer, a silicon oxynitride layer, and the like, and the plurality of second material layers 315 may include at least one of a doped semiconductor layer, a metal layer, and a conductive metal nitride layer.

Subsequently, a mask layer 317 may be formed on the preliminary stack structure PST. After that, the mask layer 317, the plurality of first material layers 211, and the plurality of second material layers 315 may be etched, thereby forming a hole 321 passing through the mask layer 317 and the preliminary stack structure PST. The hole 321 may expose the sacrificial structure 311. The hole 321 may be formed to expose the sacrificial structure 311 and may have a width narrower than the width of the first portion 311P1.

Referring to FIG. 10E, the sacrificial structure 311 shown in FIG. 10D may be removed through the hole 321. Accordingly, the first opening 301 and the second opening 303 may be opened. The first opening 301, the second opening 303, and the hole 321 may be connected to each other such that a channel hole 320 is defined. The channel hole 320 may include a first corner region C1 and a second corner region C2. The first corner region C1 may be adjacent to the preliminary stack structure PST, and the second corner region C2 may be defined between the second surface 201SU of the preliminary semiconductor structure PSS and the first corner region C1. A width of the first opening 301 is formed wider than the width of the hole 321 at a boundary between the preliminary stack structure PST and the preliminary semiconductor structure PSS, thus the first corner region C1 may be defined. A width of the first opening 301 is formed wider than the width of the second opening 303 at a boundary between the second semiconductor layer 209 and the sacrificial stack structure 200, thus the second corner region C2 may be defined.

According to the above-described processes, the channel hole 320 may include an interposition portion 320I having a cross (+) shaped longitudinal sectional structure. The interposition portion 320I may be configured with the first opening 301, a lower portion of the hole 321 adjacent to the first opening 301, and an upper portion of the second opening 303 adjacent to the first opening 301. The lower portion of the second opening 303 extending toward the second surface 201SU of the preliminary semiconductor structure PSS from the interposition portion 320I may be defined as a first portion 320P1 of the channel hole 320. An upper portion of the hole 321 extending to pass through the preliminary stack structure PST and the mask layer 317 from the interposition portion 320I may be defined as a second portion 320P2 of the channel hole 320.

The process for forming the channel hole is not limited to the above-described process. In an embodiment, to form the channel hole H shown in FIG. 9A, the hole 321 shown in FIG. 10D may be filled with a sacrificial material, and then a plurality of upper first material layers and a plurality of upper second material layers may be alternately stacked on the preliminary stack structure PST. The upper first material layer may be formed of the same material as the first material layer 211, and the upper second material layer may be formed of the same material as the second material layer 315. Subsequently, an upper hole may be formed to open the sacrificial material in the hole 321 while passing through the plurality of upper first material layers and the plurality of upper second material layers. After that, the sacrificial material in the hole 321 and the sacrificial structure 311 shown in FIG. 10D may be removed through the upper hole, thereby forming the channel hole H shown in FIG. 9A.

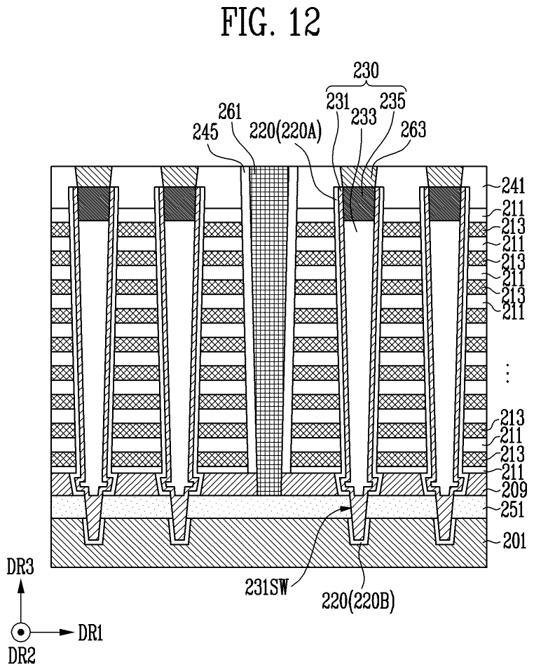

Referring to FIG. 10F, a memory layer 220 may be formed along a surface of the channel hole 320. The memory layer 220 may include a blocking insulating layer 221, a data storage layer 223, and a tunnel insulating layer 225, which are shown in FIG. 11. The blocking insulating layer 221, the data storage layer 223, and the tunnel insulating layer 225, which are shown in FIG. 11, may be configured identically to the blocking insulating layer 121, the data storage layer 123, and the tunnel insulating layer 125, which are shown in FIGS. 6B and 6C. The memory layer 220 may be formed in a bent shape along an inner wall of the channel hole 320 to have a first corner and a second corner, which respectively correspond to the first corner region C1 and the second corner region C2 of the channel hole 320.

Subsequently, a channel structure 230 including a channel layer 231 may be formed on the memory layer 220. The channel layer 231 may include silicon (Si), germanium (Ge), or any mixture thereof. The channel layer 231 may be formed in a bent shape along the inner wall of the channel hole 320 to have a first corner and a second corner, which respectively correspond to the first corner region C1 and the second corner region C2 of the channel hole 320. The channel layer 231 may include a pillar type structure filling a central region of the second opening 303. A structure of a portion of the channel layer 231 disposed in a central region of the first opening 301 and a central region of the hole 321 may vary. In an embodiment, the channel layer 231 may include a hollow type structure opening the central region of the first opening 301 and the central region of the hole 321 in the channel hole 320. In another embodiment, the channel layer 231 may be divided into a first pattern extending along one side of the first opening 301 and one side of the hole 321 and a second pattern extending along the other side of the first opening 301 and the other side of the hole 321. Each of the first pattern and the second pattern may have the crescent-shaped cross-sectional structure described with reference to FIGS. 7B and 7C.

The channel structure 230 may further include a core insulating layer 233 and a doped capping layer 235. The doped capping layer 235 may be formed of a semiconductor layer including at least one of an n-type impurity and a p-type impurity. In an embodiment, the doped capping layer 235 may include the n-type impurity as a majority carrier. In an embodiment, the core insulating layer 233 and the doped capping layer 235 may be disposed in the central region of the first opening 301 and the central region of the hole 321, which are opened by the channel layer 231 having the hollow type structure. In another embodiment, the core insulating layer 233 and the doped capping layer 235 may be disposed in the first opening 301 and the hole 321 between the first pattern and the second pattern of the channel layer 231.

After the channel structure 230 is formed, the mask layer 317 shown in FIG. 10E may be removed. Subsequently, a first insulating layer 241 may be formed to cover the channel structure 230 and the preliminary stack structure PST.

After that, a slit 323 may be formed to pass through the first insulating layer 241 and the preliminary stack structure PST. A subsequent process continued after the above-described processes may vary according to properties of the plurality of first material layers 211 and the plurality of second material layers 315. Hereinafter, the subsequent process will be described based on an embodiment in which the plurality of first material layers 211 include an insulating material and the plurality of second material layers 315 include a sacrificial insulating material having an etch selectivity with respect to the insulating material.

Referring to FIG. 10G, the plurality of second material layers 315 shown in FIG. 10F may be replaced with a plurality of conductive layers 213 through the slit 323. Accordingly, a gate stack structure may be formed. The gate stack structure may include the plurality of first material layers 211 and the plurality of conductive layers 213 and may be partitioned by the slit 323.

Referring to FIG. 10H, a spacer insulating layer 245 may be formed on a sidewall of the slit 323. The spacer insulating layer 245 may be formed to expose the bottom of the slit 323.

Subsequently, the second semiconductor layer 209 may be etched through the slit 323, thereby forming a slit extension portion 325. The slit extension portion 325 may pass through the second semiconductor layer 309, and pass through the second protective layer 207 of the sacrificial stack structure 200. The sacrificial layer 205 of the sacrificial stack structure 200 may be exposed through the slit extension portion 325.

Referring to FIG. 10I, the sacrificial layer 205 of the sacrificial stack structure 200 shown in FIG. 10H may be removed through the slit extension portion 325. Accordingly, a portion of the memory layer 220 shown in FIG. 10H may be exposed between the first semiconductor layer 201 and the second semiconductor layer 209. After that, the exposed portion of the memory layer 220 may be removed through the slit extension portion 325. The first protective layer 203 and the second protective layer 207 of the sacrificial stack structure 200 shown in FIG. 10H may be removed.

Through the above-described process, a third opening 327 may be defined. The first semiconductor layer 201 and the second semiconductor layer 209 may be exposed by the third opening 327. A sidewall 231SW of the channel layer 231 may be exposed between the first semiconductor layer 201 and the second semiconductor layer 209 through the third opening 327. The memory layer 220 may be isolated into a first interposition layer 220A and a second interposition layer 220B by the third opening 327.

FIG. 11 is an enlarged sectional view of region A shown in FIG. 10I.

Referring to FIG. 11, as a portion of the memory layer 220 between the first semiconductor layer 201 and the second semiconductor layer 209 is removed to form the third opening 327, the sidewall 231SW of the channel layer 231 may be exposed. When an etching process for removing the portion of the memory layer 220 is performed, an etching material may be introduced through a path “R.” The etching material may have difficulty infiltrating at a level at which the gate stack structure including the conductive layers 213 is disposed due to the first corner and the second corner of the channel layer 231, which are defined in the first corner region C1 and the second corner region C2 of the channel hole 320. Accordingly, a phenomenon in which the memory layer 220 configured with the first interposition layer 220A is lost between each of the conductive layers 213 and the channel layer 231 may be reduced, and a phenomenon in which the conductive layers 213 are exposed due to the loss of the memory layer 220 in a process of forming the third opening 327 may be reduced. In addition, a position change of a bottom surface of the first interposition layer 220A may be reduced. Accordingly, the uniformity of a structure of the first interposition layer 220A may be improved, and thus operational characteristics of the semiconductor memory device may be improved.

In accordance with an embodiment of the present disclosure, an end portion of the channel layer 231 adjacent to the third opening 327 may be formed in a pillar shape filling a central region of an end of the channel hole 320. Accordingly, a punching phenomenon at the end portion of the channel layer 231 due to influence of the etching process for forming the third opening 327 may be reduced. Thus, although a void 331 is formed inside the core insulating layer 233, the void 331 may be blocked by the end portion of the channel layer 231. As a result, although a third semiconductor layer 251 is formed as shown in FIG. 12 in a subsequent process, a phenomenon in which the third semiconductor layer 251 infiltrates into the void 331 may be reduced.

FIG. 12 is a sectional view illustrating an embodiment of a subsequent process continued after the process shown in FIG. 10I.

Referring to FIG. 12, the third opening 327 shown in FIG. 10I may be filled with the third semiconductor layer 251. The third semiconductor layer 251 may be in contact with the sidewall 231SW of the channel layer 231 between the first semiconductor layer 201 and the second semiconductor layer 209.

The third semiconductor layer 251 may include at least one of an n-type impurity and a p-type impurity. In an embodiment, the third semiconductor layer 251 may include the n-type impurity as a majority carrier and be a silicon layer.

After that, the inside of the slit extension portion 325 and the slit 323, which are shown in FIG. 10I, may be filled with an insulating material or a conductive material. In an embodiment, the conductive material may be formed inside the slit extension portion 325 and the slit 323, which are shown in FIG. 10I, thereby providing a conductive contact structure 261. The conductive contact structure 261 may be formed of various conductive materials. Subsequently, a subsequent process such as a process of forming a first bit line contact 263 may be performed, thereby providing the semiconductor memory device shown in FIG. 5.

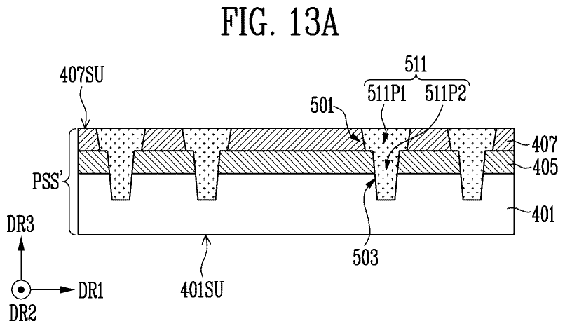

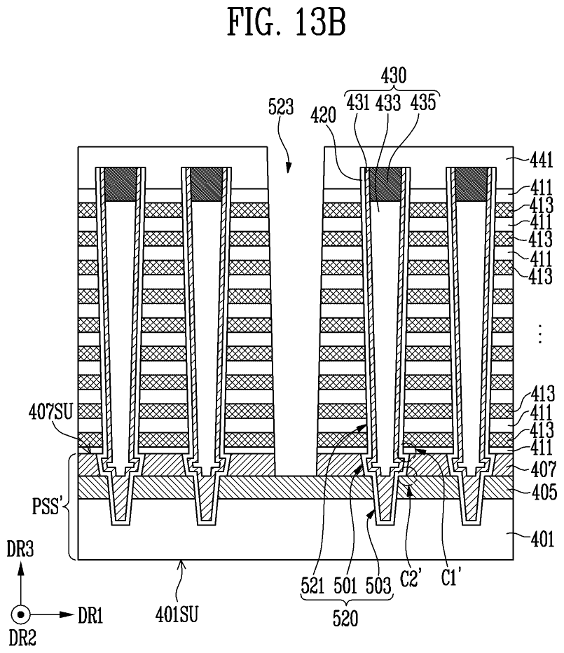

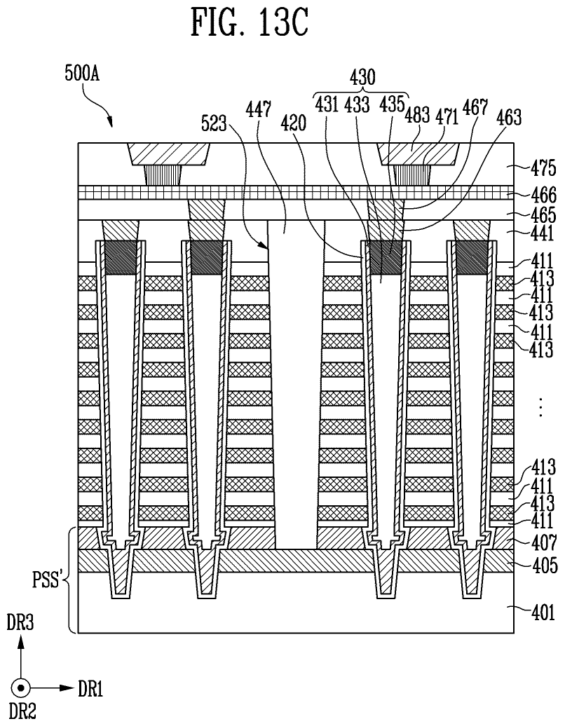

FIGS. 13A to 13C, 14, and 15A to 15C are sectional views illustrating a manufacturing method of a semiconductor memory device in accordance with an embodiment of the present disclosure.

FIGS. 13A to 13C are sectional views illustrating process operations of a manufacturing method of a semiconductor memory device taken along the line I-I′ shown in FIG. 4 and illustrate processes of forming a first structure.

Referring to FIG. 13A, a preliminary semiconductor structure PSS' may be formed. The preliminary semiconductor structure PSS' may include a first surface 407SU and a second surface 401SU, which extend in the first direction DR1 and the second direction DR2. The second surface 401SU may face in a direction opposite to a direction in which the first surface 407SU faces. Hereinafter, the third direction DR3 may be a direction in which an axis intersecting the first surface 407SU faces and be defined as the direction in which the first surface 407SU faces.

In an embodiment, the preliminary semiconductor structure PSS' may include a substrate 401, a first semiconductor layer 405, and a second semiconductor layer 407.

The second surface 401SU of the preliminary semiconductor structure PSS' may be configured with the substrate 401. The first semiconductor layer 405 may be disposed on the substrate 401. The first semiconductor layer 405 may include at least one of an n-type impurity and a p-type impurity. In an embodiment, the first semiconductor layer 405 may include a doped silicon layer. The second semiconductor layer 407 may be formed on the first semiconductor layer 405. The first surface 407SU of the preliminary semiconductor structure PSS' may be configured with the second semiconductor layer 407. The second semiconductor layer 407 may include at least one of an n-type impurity and a p-type impurity. In an embodiment, the second semiconductor layer 407 may include a doped silicon layer.

Subsequently, a first opening 501 and a second opening 503 may be formed. The first opening 501 may pass through the first surface 407SU of the preliminary semiconductor structure PSS' and extends to the inside of the preliminary semiconductor structure PSS′. The second opening 503 may extend to the inside of the preliminary semiconductor structure PSS' toward the second surface 401SU of the preliminary semiconductor structure PSS' from the first opening 501. In an embodiment, the first opening 501 may pass through the second semiconductor layer 407, and the second opening 503 may pass through the first semiconductor layer 405 and extend to the inside of the substrate 401.

The first opening 501 and the second opening 503 may be formed using the processes described with reference to FIGS. 10A to 10C. The first opening 501 may be formed with a width wider than the width of the second opening 503.

The first opening 501 and the second opening 503 may be filled with a sacrificial structure 511. The sacrificial structure 511 may have a T-shape longitudinal sectional structure due to a width difference between the first opening 501 and the second opening 503. The sacrificial structure 511 may include a material having an etch selectivity with respect to the preliminary semiconductor structure PSS' as described with reference to FIG. 10C.

The sacrificial structure 511 may include a first portion 511P1 filling the first opening 501 and a second portion 511P2 filling the second opening 503. The first portion 511P1 may be adjacent to the first surface 407SU of the preliminary semiconductor structure PSS' and pass through the second semiconductor layer 407. The second portion 411P2 may extend toward the second surface 401SU of the preliminary semiconductor structure PSS' from the first portion 411P1, and extend to the inside of the substrate 401 while passing through the first semiconductor layer 405.

Referring to FIG. 13B, the processes described with reference to FIGS. 10D to 10G may be performed. Accordingly, a gate stack structure including a plurality of interlayer insulating layers 411 and a plurality of conductive layers 413 may be formed on the first surface 407SU of the preliminary semiconductor structure PSS′. A hole 521 may pass through the plurality of interlayer insulating layers 411 and the plurality of conductive layers 413. The hole 521 may be connected to the first opening 501 and the second opening 503. A connection structure between the hole 521, the first opening 501, and the second opening 503 may define a channel hole 520. The channel hole 520 may be filled with a memory layer 420 and a channel structure 430. The channel structure 430 may include a channel layer 431, a core insulating layer 433, and a doped capping layer 435. The channel structure 430 and the gate stack structure including the plurality of interlayer insulating layers 411 and the plurality of conductive layers 413 may be covered by a first insulating layer 441. A slit 523 may pass through the first insulating layer 441. An alternate stacked structure of the plurality of interlayer insulating layers 411 and the plurality of conductive layers 413 may be partitioned by the slit 523. The slit 523 may extend to pass through the second semiconductor layer 407. However, embodiments of the present disclosure are not limited thereto, and a depth of the slit 523 may be variously controlled at a level between the first surface 407SU and the second surface 401SU.

As described with reference to FIG. 10E, the channel hole 520 may include a first corner region C1′ and a second corner region C2′. As described with reference to FIG. 10F, each of the memory layer 420 and the channel layer 431 may be formed in a bent shape along an inner wall of the channel hole 520 to have a first corner and a second corner, which respectively correspond to the first corner region C1′ and the second corner region C2′ of the channel hole 520.

Referring to FIG. 13C, the slit 523 may be filled with an insulating material 447 or be filled with the spacer insulating layer 245 and the conductive contact structure 261, which are shown in FIG. 12. Subsequently, a first bit line contact 463 may be formed to contact the channel structure 430 while passing through the first insulating layer 441.

After that, a second insulating layer 465 may be formed to cover the first bit line contact 463 and the first insulating layer 441. Subsequently, a second bit line contact 467 and a bit line 466 may be formed. The second bit line contact 467 may be in contact with the first bit line contact 463 while passing through the second insulating layer 465, and a bit line 466 may be in contact with the second bit line contact 467.

Subsequently, a third insulating layer 475 may be formed on the bit line 466. A first contact 471 and a first conductive bonding pad 483 may be buried inside the third insulating layer 475.

A first structure 500A may be formed through the processes described with reference to FIGS. 13A to 13C.

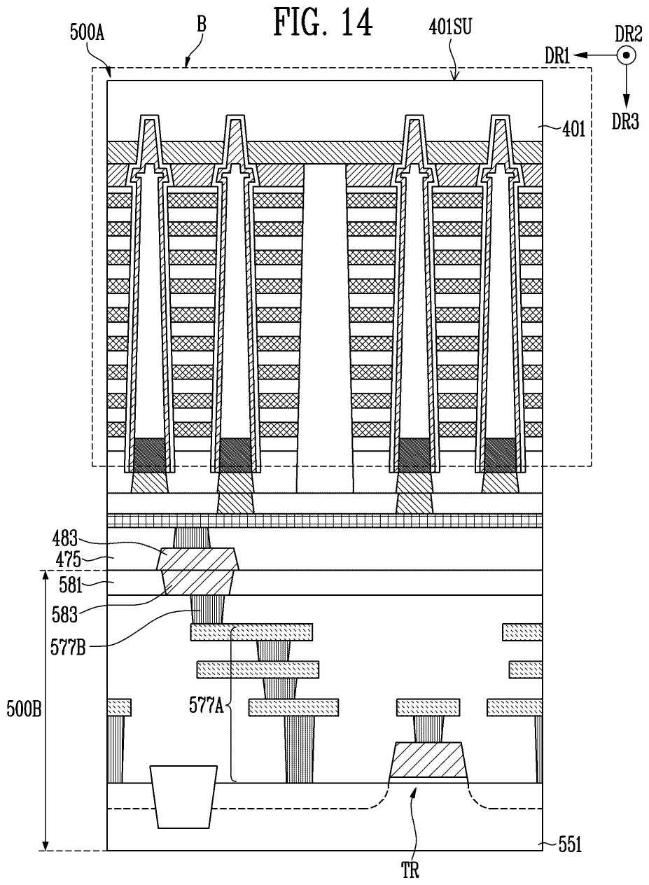

FIG. 14 is a sectional view illustrating a bonding process between the first structure 500A and a second structure 500B.

Referring to FIG. 14, the second structure 500B may be formed separately from the first structure 500A.

The second structure 500B may include a semiconductor substrate 551, a transistor TR constituting a peripheral circuit structure, a plurality of interconnections 577A, a second contact 577B, and a second conductive bonding pad 583 as described with reference to FIG. 8. The second conductive bonding pad 583 may be formed in a fourth insulating layer 581.

The first structure 500A and the second structure 500B may be aligned such that the first conductive bonding pad 483 of the first structure 500A and the second conductive bonding pad 583 of the second structure 500B face each other. After that, a bonding process may be performed such that the first conductive bonding pad 483 and the second conductive bonding pad 583 are in contact with each other. The third insulating layer 475 and the fourth insulating layer 581 may be in contact with each other.

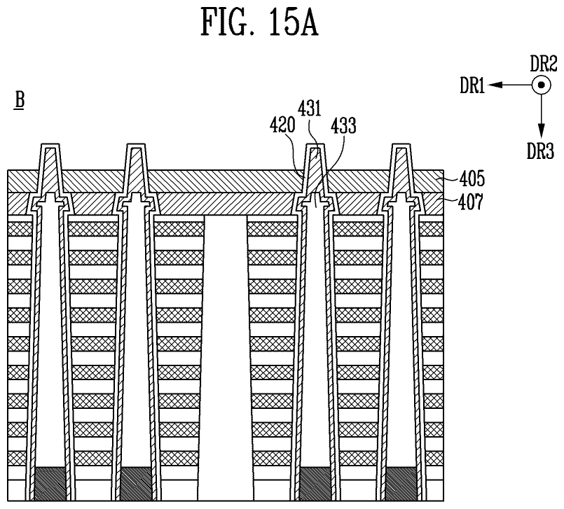

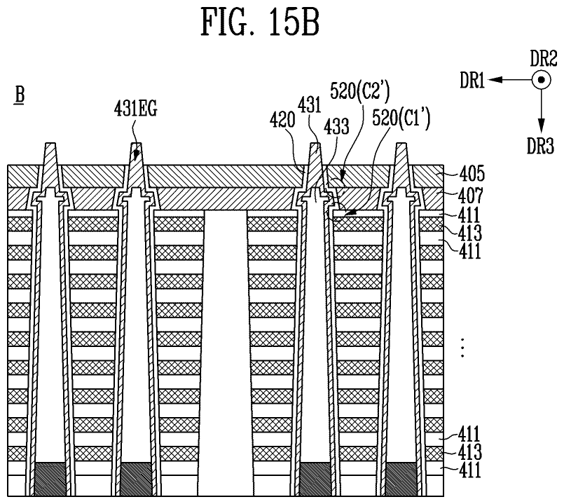

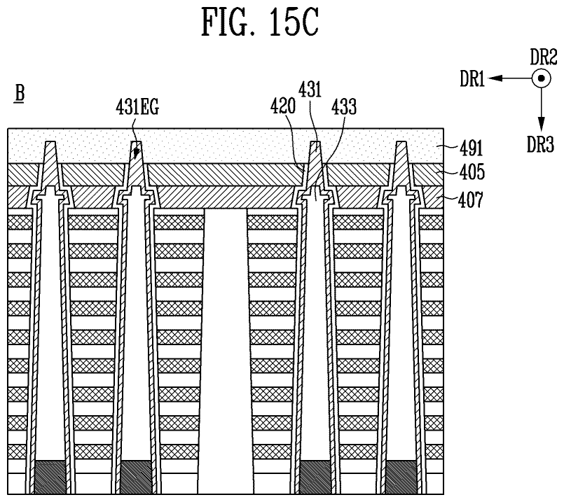

FIGS. 15A to 15C are sectional views illustrating subsequent processes continued after the bonding process shown in FIG. 14 and illustrate subsequent processes of region B shown in FIG. 14.

Referring to FIG. 15A, the substrate 401 of the preliminary semiconductor structure PSS' may be removed from the second surface 401SU. Accordingly, the first semiconductor layer 405 and the memory layer 420 may be exposed.

Referring to FIG. 15B, an exposed portion of the memory layer 420 shown in FIG. 15A may be removed through an etching process. Accordingly, an end 431EG of the channel layer 431 may be exposed.

While the memory layer 420 is etched to expose the end 431EG of the channel layer 431, an etching material may be blocked by the first corner and the second corner of the channel layer 431 which are formed in the first corner region C1′ and the second corner region C2′ of the channel hole 520. Accordingly, a phenomenon in which the memory layer 420 between the channel layer 431 and the conductive layers 413 is lost may be reduced.

In accordance with an embodiment of the present disclosure, the end 431EG of the channel layer 431 is not formed in a hollow shape but may be formed in a pillar shape filling a central region of the end 431EG. Accordingly, as described with reference to FIG. 11, although a void is formed inside the core insulating layer 433, the void may be blocked through the end 431EG of the channel layer 431.

Referring to FIG. 15C, a third semiconductor layer 491 in contact with the end 431EG of the channel layer 431 may be formed. The third semiconductor layer 491 may include at least one of an n-type impurity and a p-type impurity. The third semiconductor layer 491 may include a semiconductor material such as silicon. Because the core insulating layer 433 is blocked by the end 431EG of the channel layer 431, a failure in which the third semiconductor layer 491 extends to the inside of the core insulating layer 433 may be reduced or prevented.

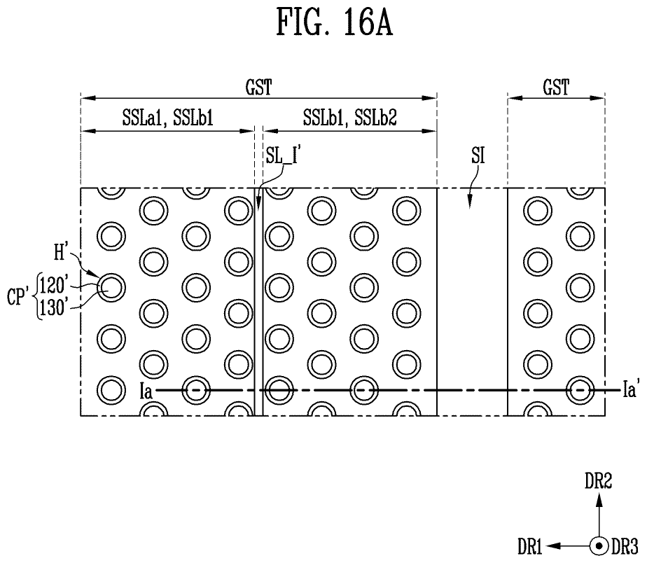

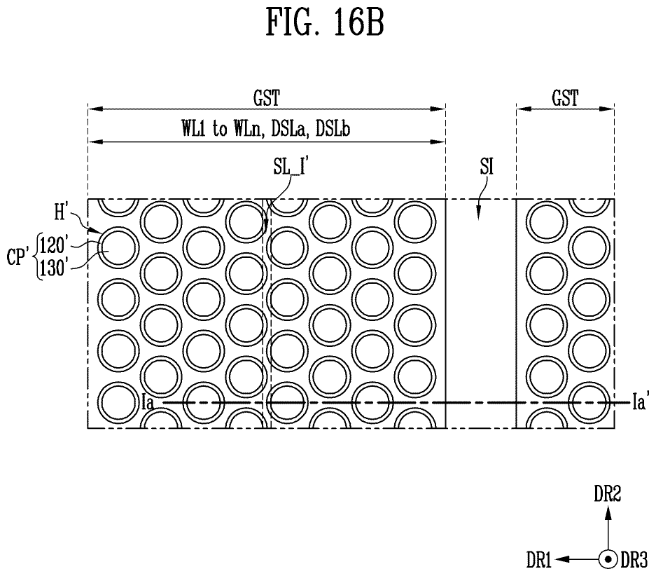

FIGS. 16A and 16B are plan views illustrating a gate stack structure of a semiconductor memory device in accordance with an embodiment of the present disclosure. For convenience of description, FIGS. 16A and 16B representatively illustrate a gate stack structure which may be applied to the semiconductor memory device shown in FIGS. 3A and 3B. Specifically, FIG. 16A illustrates a layout of the source select lines SSLa1 and SSLb1 of the first group and the source select lines SSLa2 and SSLb2 of the second group, which are shown in FIGS. 3A and 3B, and FIG. 16B illustrates a layout of the plurality of word lines WL1 to WLn and the drain select lines DSLa and DSLb, which are shown in FIGS. 3A and 3B.

Referring to FIGS. 16A and 16B, the semiconductor memory device may include a gate stack structure GST partitioned by a slit SI and a plurality of cell plugs CP′ surrounded by the gate stack structure GST. The memory cell string CS described with reference to FIG. 3B may be defined along each cell plug CP′.

The gate stack structure GST may include a plurality of conductive layers used as the source select lines SSLa1 and SSLb1 of the first group, the source select lines SSLa2 and SSLb2 of the second group, the plurality of word lines WL1 to WLn, and the drain select line DSLa and DSLb. The plurality of conductive layers may extend in the first direction DR1 and the second direction DR2, and be stacked spaced apart from each other in the third direction DR3. As shown in FIG. 16A, some of the plurality of conductive layers may be isolated into the source select lines SSLa1 and SSLb1 of the first group and the source select lines SSLa2 and SSLb2 of the second group by a select line isolation structure SL_I′. As shown in FIG. 16B, others of the plurality of conductive layers may form the plurality of word lines WL1 to WLn and the drain select lines DSLa and DSLb. The plurality of word lines WL1 to WLn and the drain select lines DSLa and DSLb may overlap with the select line isolation structure SL_I′ and continuously extend to overlap with the source select lines SSLa1 and SSLb1 of the first group and the source select lines SSLa2 and SSLb2 of the second group.

The gate stack structure GST may include a plurality of channel holes H′ extending in the third direction DR3. The plurality of cell plugs CP′ may be disposed in the plurality of channel holes H′. An external diameter in each of each cell plug CP′ and each channel hole H′ may be changed according to a position of each of the cell plug CP′ and the channel hole H′ in the third direction DR3. In an embodiment, an external diameter of each of the cell plug CP′ and the channel hole H′ at a first level at which a source select line (e.g., SSLb1) of the first group and a source select line (e.g., SSLb2) of the second group are disposed may be formed narrower than an external diameter of each of the cell plug CP′ and the channel hole H′ at a second level at which a first word line WL1 is disposed. Accordingly, an arrangement space of the select line isolation structure SL_I′ may be secure between the source select line (e.g., SSLb1) of the first group and the source select line (e.g., SSLb2) of the second group.

The cell plug CP′ may include a memory layer 120′ and a channel structure 130′, which are disposed in the channel hole H′. The memory layer 120′ may be interposed between the channel structure 130′ and the gate stack structure GST.

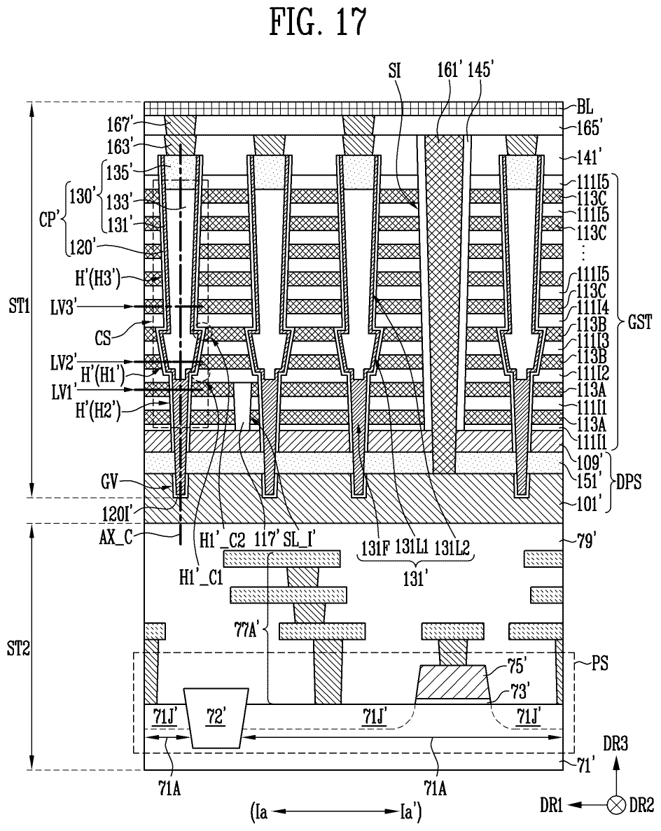

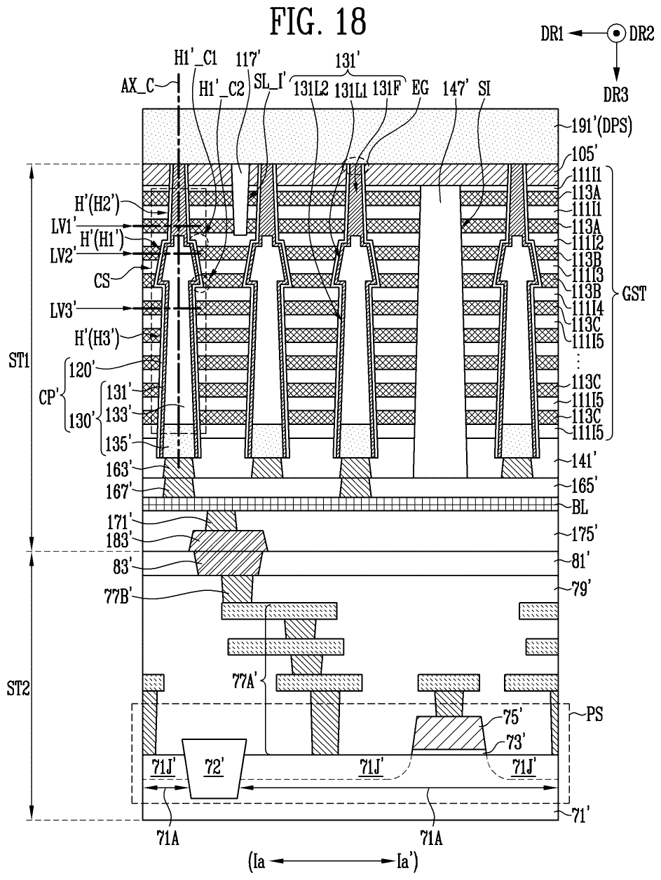

FIGS. 17 and 18 are sectional views of semiconductor memory devices in accordance with embodiments of the present disclosure. The sectional view shown in each of FIGS. 17 and 18 may correspond to a sectional view of the semiconductor memory device taken along line Ia-Ia′ shown in each of FIGS. 16A and 16B.

Referring to FIGS. 17 and 18, each of the semiconductor memory devices may include a first structure ST1, a doped semiconductor structure DPS, and a second structure ST2. The first structure ST1 may include a bit line BL, a gate stack structure, and the cell plug CP′ described with reference to FIGS. 16A and 16B.

The gate stack structure GST may include a plurality of conductive layers 113A, 113B, and 113C extending in the first direction DR1 and the second direction DR2. The plurality of conductive layers 113A, 113B, and 113C may be stacked spaced apart from each other in the third direction DR3. The gate stack structure GST may further include a plurality of interlayer insulating layers 1111I, 111I2, 111I3, 111I4, and 111I5. The plurality of interlayer insulating layers 1111I, 111I2, 111I3, 111I4, and 111I5 may be alternately disposed one by one with the plurality of conductive layers 113A, 113B, and 113C in the third direction DR3.

The plurality of conductive layers 113A, 113B, and 113C may include at least one of a doped semiconductor layer, a metal layer, and a conductive metal nitride layer. The doped semiconductor layer may include a doped silicon layer. The metal layer may include tungsten, copper, molybdenum, and the like. The conductive metal nitride layer may include titanium nitride, tantalum nitride, and the like. The plurality of conductive layers 113A, 113B, and 113C may include at least one first conductive layer 113A, at least one second conductive layer 113B, and a plurality of third conductive layers 113C. Hereinafter, a structure of the gate stack structure GST will be described based on an embodiment in which the plurality of conductive layers 113A, 113B, and 113C include two first conductive layers 113A and two second conductive layers 113B, but the embodiments of the present disclosure are not limited thereto. A stacked number of first conductive layers 113A and a stacked number of second conductive layers 113B may be variously changed with a range in which the stacked number of first conductive layers 113A and the stacked number of second conductive layers 113B are less than a stacked number of third conductive layers 113C.

The first conductive layer 113A, the second conductive layer 113B, and the third conductive layer 113C may be sequentially disposed to be spaced apart from each other in the third direction DR3. A select line isolation structure SL_I′ may pass through the first conductive layer 113A, to be isolated into a source select line (e.g., SSLb1) of the first group, which is shown in FIG. 3A, 3B or 16A, and a source select line (e.g., SSLb2) of the second group, which is shown in FIG. 3A, 3B or 16A. The second conductive layer 113B may be disposed between the first conductive layer 113A and the plurality of third conductive layers 113C, and form a portion (e.g., WL1) of the plurality of word lines WL1 to WLn shown in FIG. 3A, 3B or 16B. The plurality of third conductive layers 113C may form others (e.g., WL3 to WLn) of the plurality of word lines WL1 to WLn shown in FIG. 3A, 3B or 16B and a drain select line (e.g., DSLa) shown in FIG. 3A, 3B or 16B.

The plurality of interlayer insulating layers 1111I, 111I2, 111I3, 111I4, and 111I5 may include an insulating material such as a silicon oxide layer or a silicon oxynitride layer. The plurality of interlayer insulating layers 111I1, 111I2, 111I3, 111I4, and 111I5 may include a first interlayer insulating layer 111I1, a second interlayer insulating layer 111I2, a third interlayer insulating layer 111I3, a fourth interlayer insulating layer 111I4, and a plurality of fifth interlayer insulating layers 111I5. The second interlayer insulating layer 111I2 may be disposed between a first conductive layer 113A and a second conductive layer 113B, which are adjacent to each other in the third direction DR3. The fourth interlayer insulating layer 111I4 may be disposed between a second conductive layer 113B and a third conductive layer 113C, which are adjacent to each other in the third direction DR3. The first interlayer insulating layer 111I1 may be spaced apart from the second interlayer insulating layer 111I2 with the first conductive layer 113A interposed therebetween and be alternately disposed with the first conductive layer 113A in the third direction DR3. The third interlayer insulating layer 111I3 may be disposed between the second conductive layers 113B adjacent to each other in the third direction DR3. The plurality of fifth interlayer insulating layers 111I5 may alternately disposed with the plurality of third conductive layers 113C in the third direction DR3.

The select line isolation structure SL_I′ may extend to pass through the first interlayer insulating layer 111I1. The select line isolation structure SL_I′ may be filled with an insulating material 117′. The select line isolation structure SL_I′ may be formed in a tapered shape which becomes thinner as approaching an end portion thereof. The tapered shape of the select line isolation structure SL_I′ may vary according to a method of forming a trench for the select line isolation structure SL_I′. In an embodiment, the select line isolation structure SL_I′ may have a tapered shape which becomes thinner as a distance from the second conductive layer 113B increases as shown in FIG. 17. In another embodiment, the select line isolation structure SL_I′ may have a tapered shape which becomes thinner as becoming closer to the second conductive layer 113B as shown in FIG. 18.

A slit SI may be filled with various materials. In an embodiment, as shown in FIG. 17, a sidewall insulating layer 145′ may be formed on a sidewall of the slit SI, and a conductive contact structure 161′ may be disposed in a central region of the slit SI. The sidewall insulating layer 145′ may extend to cover sidewalls of the plurality of conductive layers 113A, 113B, and 113C. The conductive contact structure 161′ may include at least one of a doped semiconductor layer, a metal layer, and a conductive metal nitride layer. The conductive contact structure 161′ may be connected to the doped semiconductor structure DPS. In another embodiment, as shown in FIG. 18, the slit SI may be filled with an insulating material 147′. Although not shown in the drawings, in still another embodiment, the slit SI may be filled with different types of materials including an insulating material, a semiconductor material, a metal, and the like. The semiconductor material may include an amorphous semiconductor layer or a polycrystalline semiconductor layer, and include silicon (Si), germanium (Ge), or any mixture thereof. The semiconductor material or the metal in the slit SI may be disposed to be spaced apart from a surface of the slit SI through the insulating material formed along the surface of the slit SI. Accordingly, the semiconductor material or the metal in the slit SI may be insulated from the doped semiconductor structure DPS.

Referring to FIGS. 17 and 18, a channel structure 130′ and a memory layer 120′ of the cell plug CP′ may be disposed in a channel hole H′. The channel hole H′ may extend in the third direction DR3 to pass through the gate stack structure GST. The channel hole H′ may include a first portion H1′, a second portion H2′, and a third portion H3′. The first portion H1′ may pass through the second conductive layer 113B, the second portion H2′ may extend from the first portion H1′ to pass through the first conductive layer 113A, and the third portion H3′ may extend from the first portion H1′ to pass through the plurality of third conductive layers 113C. A boundary between the first portion H1′ and the second portion H2′ may be located at a level between the first conductive layer 113A and the second conductive layer 113B. A boundary between the first portion H1′ and the third portion H3′ may be located at a level between the second conductive layer 113B and the third conductive layer 113C. The first portion H1′ may have a first corner H1′_C1 and a second corner H1′_C2. A width of the first portion H1′ is formed wider than the width of the second portion H2′ at the boundary between the first portion H1′ and the second portion H2′, thus the first corner H1′_C1 may be defined. A width of the first portion H1′ is formed wider than the width of the third portion H3′ at the boundary between the first portion H1′ and the third portion H3′, thus the second corner H1′_C2 may be defined.

According to the above-described structure of the channel hole H′, the first portion H1′ may protrude laterally (i.e., wider in the lateral direction than the second and third portions) toward the gate stack structure GST as compared with the second portion H2′ and the third portion H3′, to define a convex portion protruding toward the gate stack structure GST at a sidewall of the channel hole H′.

The channel structure 130′ of the cell plug CP′ may include a channel layer 131′. The memory layer 120′ of the cell plug CP′ may be disposed between the channel layer 131′ and the gate stack structure GST.

The channel layer 131′ may include a semiconductor material to be used as a channel region of a memory cell string CS. In an embodiment, the channel layer 131′ may include silicon (Si), germanium (Ge), or any mixture thereof.

The channel layer 131′ may include a filling channel portion 131F, a first liner channel portion 131L1, and a second liner channel portion 131L2. The filling channel portion 131F may be disposed inside the second portion H2′ of the channel hole H′. The first liner channel portion 131L1 may be disposed inside the first portion H1′ of the channel hole H′. The second liner channel portion 131L2 may be disposed inside the third portion H3′ of the channel hole H′.

The filling channel portion 131F may extend toward an inner wall of the memory layer 120′ from a central axis AX_C of the channel hole H′. The central axis AX_C may be defined as an axis extending along the center of the channel hole H′ in the third direction DR3. That is, the filling channel portion 131F may completely fill a central region of the second portion H2′ in the channel hole H′. The filling channel portion 131F may have a tapered shape which becomes thinner as becoming closer to the doped semiconductor structure DPS. In accordance with the embodiment shown in FIG. 17, the tapered shape of the filling channel portion 131F may become thinner in a direction identical to the direction in which the tapered shape of the select line isolation structure SL_I′ becomes thinner. In accordance with the embodiment shown in FIG. 18, the tapered shape of the filling channel portion 131F may become thinner in a direction opposite to the direction in which the tapered shape of the select line isolation structure SL_I′ becomes thinner.

The first liner channel portion 131L1 and the second liner channel portion 131L2 may be spaced apart from the central axis AX_C of the channel hole H′. That is, the first liner channel portion 131L1 may be formed to open a central region of the first portion H1′ in the channel hole H′, and the second liner channel portion 131L2 may be formed to open a central region of the third portion H3′ in the channel hole H′.

The channel structure 130′ may further include a core insulating layer 133′ and a doped capping layer 135′. The core insulating layer 133′ may extend to the inside of the third portion H3′ from the inside of the first portion H1′ of the channel hole H′. The core insulating layer 133′ may overlap with the filling channel portion 131F of the channel layer 131′ in the third direction DR3. A portion which is not filled with the core insulating layer 133′ in the third portion H3′ of the channel hole H′ may be filled with the doped capping layer 135′. The doped capping layer 135′ may overlap with the filling channel portion 131F with the core insulating layer 133′ interposed therebetween. The doped capping layer 135′ may be formed of a semiconductor layer including at least one of an n-type impurity and a p-type impurity. In an embodiment, the doped capping layer 135′ may include the n-type impurity as a majority carrier. A portion of the channel layer 131′ adjacent to the doped capping layer 135′ may be doped with the same impurity as the doped capping layer 135′.

The first liner channel portion 131L1 and the second liner channel portion 131L2 of the channel layer 131′ may be interposed between the core insulating layer 133′ and the memory layer 120′. The second liner channel portion 131L2 may extend between the doped capping layer 135′ and the memory layer 120′.

The filling channel portion 131F of the channel layer 131′ may be in contact with the doped semiconductor structure DPS. The doped semiconductor structure DPS may overlap with the gate stack structure GST. As shown in FIG. 17, the doped semiconductor structure DPS may be in contact with a sidewall of the filling channel portion 131F. As shown in FIG. 18, the doped semiconductor structure DPS may be in contact with an end EG of the filling channel portion 131F.

Referring to FIG. 17, the doped semiconductor structure DPS may include a first semiconductor layer 101′, a second semiconductor layer 109′, and a third semiconductor layer 151′. The first semiconductor layer 101′ may include a groove GV. The second semiconductor layer 109′ may be disposed between the first semiconductor layer 101′ and the gate stack structure GST. The third semiconductor layer 151′ may be disposed between the first semiconductor layer 101′ and the second semiconductor layer 109′. Each of the first semiconductor layer 101′, the second semiconductor layer 109′, and the third semiconductor layer 151′ may include a doped region provided as at least one of a common source region and a well region. For example, each of the first semiconductor layer 101′, the second semiconductor layer 109′, and the third semiconductor layer 151′ may include at least one of an n-type impurity and a p-type impurity. In an embodiment, each of the first semiconductor layer 101′, the second semiconductor layer 109′, and the third semiconductor layer 151′ may include a first conductivity type doped region including the n-type impurity as a majority carrier. In another embodiment, each of the second semiconductor layer 109′ and the third semiconductor layer 151′ may include the first conductivity type doped region including the n-type impurity as the majority carrier, and the first semiconductor layer 101′ may include a second conductivity type doped region including the p-type impurity as a majority carrier. The first conductivity type doped region may include the common source region, and the second conductivity type doped region may include the well region. However, embodiments of the present disclosure are not limited thereto, and the doped region of each of the first semiconductor layer 101′, the second semiconductor layer 109′, and the third semiconductor layer 151′ may vary. Each of the first semiconductor layer 101′, the second semiconductor layer 109′, and the third semiconductor layer 151′ may include a semiconductor material such as silicon.

The second portion H2′ of the channel hole H′ and the filling channel portion 131F of the channel layer 131′ may extend to pass through the second semiconductor layer 109′. The filling channel portion 131F may extend to pass through the third semiconductor layer 151′ and be inserted into the groove GV of the first semiconductor layer 101′. The third semiconductor layer 151′ may be in contact with the filling channel portion 131F. The memory layer 120′ may extend to be interposed between the filling channel portion 131F and the second semiconductor layer 109′.

A dummy memory layer 121I′ may be interposed between the filling channel portion 131F and the first semiconductor layer 101′. The dummy memory layer 120I′ may include the same materials as the memory layer 120′. The dummy memory layer 120I′ and the memory layer 120′ may be spaced apart from each other with the third semiconductor layer 151′ interposed therebetween.

The slit SI may extend to pass through the second semiconductor layer 109′. The conductive contact structure 161′ may extend to contact the third semiconductor layer 151′.

According to the structure shown in FIG. 17, the conductive contact structure 161′ and the channel layer 131′ may be electrically connected to each other via the third semiconductor layer 151′.

Referring to FIG. 18, the doped semiconductor structure DPS may include a doped semiconductor layer 191′ in contact with the end EG of the filling channel portion 131F. The doped semiconductor layer 191′ may include a doped region provided as at least one of a common source region and a well region. For example, the doped semiconductor layer 191′ may include at least one of an n-type impurity and a p-type impurity. In an embodiment, the doped semiconductor layer 191′ may include a first conductivity type doped region including the n-type impurity as a majority carrier. In another embodiment, the doped semiconductor layer 191′ may include the first conductivity type doped region including the n-type impurity as the majority carrier and a second conductivity type doped region including the p-type impurity as a majority carrier.

The semiconductor memory device may further include an interposition semiconductor layer 105′ disposed between the doped semiconductor structure DPS and the gate stack structure GST. The interposition semiconductor layer 105′ may include at least one of an n-type impurity and a p-type impurity.

Each of the interposition semiconductor layer 105′ and the doped semiconductor layer 191′ may include a semiconductor material such as silicon. The second portion H2′ of the channel hole H′, the memory layer 120′, and the filling channel portion 131F of the channel layer 131′ may extend to pass through the interposition semiconductor layer 105′.

Referring to FIGS. 17 and 18, the channel structure 130′ may include a portion protruding in the third direction DR3 as compared with the gate stack structure GST. The protruding portion of the channel structure 130′ may be covered by a first insulating layer 141′. The slit SI may extend to pass through the first insulating layer 141′. The bit line BL may be spaced apart from the channel structure 130′ with the first insulating layer 141′ interposed therebetween. The bit line BL may be disposed to contact the first insulating layer 141′, or overlap the first insulating layer 141′ with at least one insulating layer interposed therebetween. In an embodiment, a second insulating layer 165′ may be disposed between the bit line BL and the first insulating layer 141′. Hereinafter, the structure of the semiconductor memory device is described based on an embodiment in which the first insulating layer 141′ and the second insulating layer 165′ are disposed between the bit line BL and the channel structure 130′, but the embodiment of the present disclosure is not limited thereto.

The bit line BL may be electrically connected to a channel layer 131′ of a channel structure 130′ corresponding thereto via at least one bit line contact. In an embodiment, the bit line BL may be electrically connected to the channel layer 131′ corresponding thereto via a first bit line contact 163′ and a second bit line contact 167′. The first bit line contact 163′ may be in contact with the doped capping layer 135′ of the channel structure 130′ while passing through the first insulating layer 141′. The second bit line contact 167′ may be connected to the first bit line contact 163′ and the bit line BL while passing through the second insulating layer 165′.

The second structure ST2 may include a semiconductor substrate 71′, a peripheral circuit structure PS, an insulating structure 79′, and a plurality of interconnections 77A′. The peripheral circuit structure PS may correspond to the peripheral circuit structure described with reference to FIGS. 1A and 1B.

The semiconductor substrate 71′ may include an active region 71A′ partitioned by an isolation layer 72′. The peripheral circuit structure PS may include a transistor. The transistor may include a gate insulating layer 73′, a gate electrode 75′, and source/drain junctions 71J′. The gate insulating layer 73′ and the gate electrode 75′ may be stacked on the active region 71A′ of the semiconductor substrate 71′. The source/drain junctions 71J′ may be formed in the active region 71A′ at both sides of the gate electrode 75′.

The plurality of interconnections 77A′ may include sub-interconnections individually connected to the gate electrode 75′ and the source/drain junctions 71J′. The semiconductor substrate 71′ and the peripheral circuit structure PS may be covered by the insulating structure 79′, and the plurality of interconnections 77A′ may be disposed inside the insulating structure 79′.

Referring to FIG. 17, the second structure ST2 may be disposed adjacent to the doped semiconductor structure DPS. A process of forming the doped semiconductor structure DPS and the first structure ST1 may be performed on the second structure ST2 after the second structure ST2 is formed.

Referring to FIG. 18, the first structure ST1 may further include a first contact 171′ and a first conductive bonding pad 183′, and the second structure ST2 may further include a second contact 77B′ and a second conductive bonding pad 83′.

The first contact 171′ and the first conductive bonding pad 183′ may be disposed inside a third insulating layer 175′. The third insulating layer 175′ may overlap with the second insulating layer 165′ with the bit line BL interposed therebetween and include may include a single-layer insulating layer or multi-layer insulating layers each having at least two layers. The first conductive bonding pad 183′ may be electrically connected to the bit line BL via the first contact 171′.

The second conductive bonding pad 83′ may be disposed inside a fourth insulating layer 81′. The fourth insulating layer 81′ may be disposed between the insulating structure 79′ and the third insulting layer 175′. The second contact 77B′ may be in contact with a sub-interconnection corresponding thereto among the plurality of interconnections 77A′ and extend to contact the second conductive bonding pad 83′. The second conductive bonding pad 83′ may be in contact with the first conductive bonding pad 183′.

The memory cell string CS of the first structure ST1 and the peripheral circuit structure PS of the second structure ST2 may be electrically connected to each other via the first conductive bonding pad 183′ and the second conductive bonding pad 83′. In an embodiment, the first conductive bonding pad 183′ may be connected to the memory cell string CS via the first contact 171′, the bit line BL, and the first and second bit line contacts 163′ and 167′, and the second conductive bonding pad 83′ may be connected to the junction 71j′ constituting the transistor of a page buffer circuit via the second contact 77B′ and the interconnection 77A′. When the first conductive bonding pad 183′ and the second conductive bonding pad 83′ in accordance with these embodiments are in contact with each other, the memory cell string CS may be electrically connected to the peripheral circuit structure PS via the bit line BL, the first contact 171′, the first conductive bonding pad 183′, the second conductive bonding pad 83′, and the interconnection 77A′.

The first structure ST1 and the second structure ST2, which are described above, may be provided through individual processes. A bonding process is performed such that the first conductive bonding pad 183′ and the second conductive bonding pad 83′ are in contact with each other. Thus, the first structure ST1 and the second structure ST2 may be structurally connected to each other. The doped semiconductor structure DPS may be provided after the bonding process.

The first conductive bonding pad 183′ and the second conductive bonding pad 83′ may include copper, a copper alloy, or the same kind of metal. The first conductive bonding pad 183′ and the second conductive bonding pad 83′ may further include a barrier layer such as a metal nitride layer.

Referring to FIGS. 17 and 18, a void (not shown) may be generated inside the third portion H3′ having an aspect ratio relatively larger than an aspect ratio of the first portion H1′ of the channel hole H′. The filling channel portion 131F of the channel layer 131′ may block a void which may remain inside the third portion H3′ from being exposed to the outside. Accordingly, a leakage current which may be caused as the void is exposed to the outside may be reduced, and a failure in a manufacturing process, which may be caused as the void is exposed to the outside may be reduced. Thus, in the embodiments of the present disclosure, the stability of the semiconductor memory device in the manufacturing process and the operational reliability of the semiconductor memory device may be improved through the filling channel portion 131F.

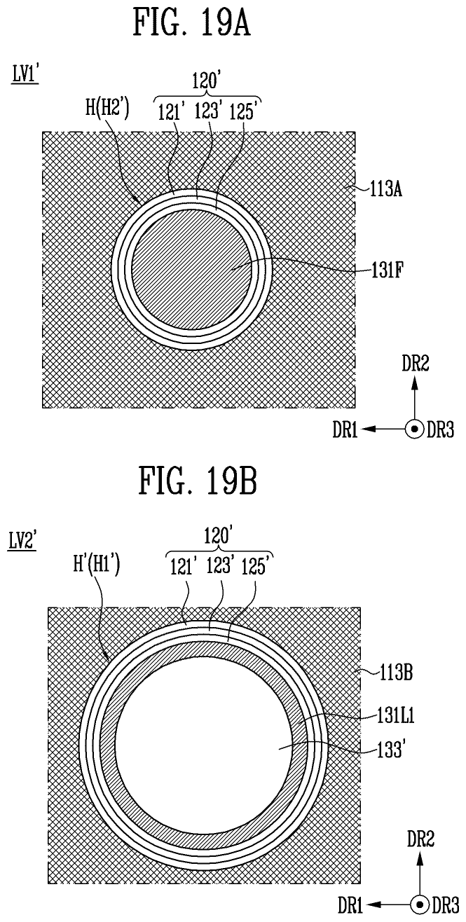

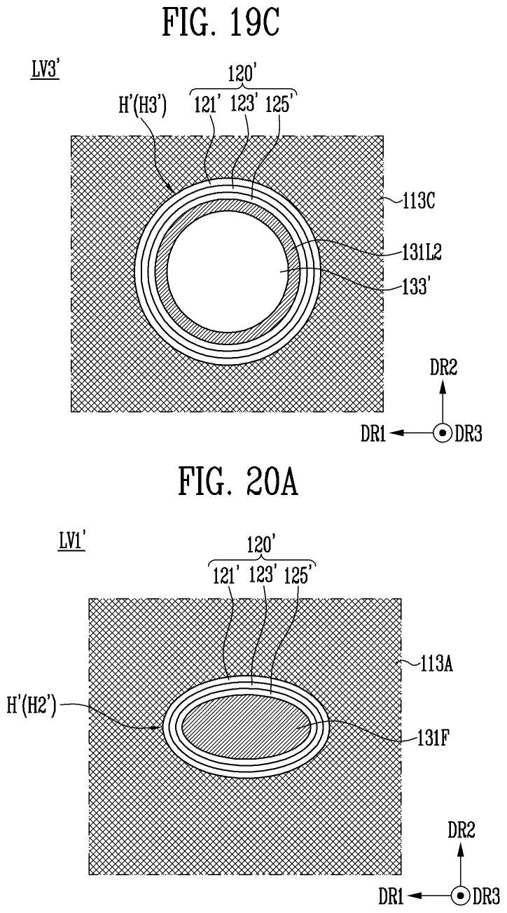

FIGS. 19A, 19B, and 19C are plan views illustrating a cell plug in accordance with an embodiment of the present disclosure. FIG. 19A illustrates a cross-section of the cell plug CP′ at a first level LV1′ shown in FIG. 17 or 18, FIG. 19B illustrates a cross-section of the cell plug CP′ at a second level LV2′ shown in FIG. 17 or 18, and FIG. 19C illustrates a cross-section of the cell plug CP′ at a third level LV3′ shown in FIG. 17 or 18. Hereinafter, overlapping descriptions of portions identical to those shown in FIGS. 6A to 6C may be simplified or omitted.

Referring to FIGS. 17, 18, and 19A to 19C, the first level LV1′ may be a level at which the first conductive layer 113A is disposed, the second level LV2′ may be a level at which the second conductive layer 113B is disposed, and the third level LV3′ may be a level at which the third conductive layer 113C is disposed.

Referring to FIGS. 19A to 19C, each of the first portion H1′, the second portion H2′, and the third portion H3′ of the channel hole H′ may include a circular cross-sectional structure. A cross-sectional structure of the filling channel portion 131F may have a shape corresponding to the second portion H2′, a cross-sectional structure of the first liner channel portion 131L1 may have a shape corresponding to the first portion H1′, and a cross-sectional structure of the second liner channel portion 131L2 may have a shape corresponding to the third portion H3′. In an embodiment, the cross-sectional structure of the filling channel portion 131F may have a circular shape, and the cross-sectional structure of each of the first liner channel portion 131L1 and the second liner channel portion 131L2 may have a ring shape.

Each of the first liner channel portion 131L1 and the second liner channel portion 131L2 may surround a sidewall of the core insulating layer 133′.

The memory layer 120′ may include a blocking insulating layer 121′, a data storage layer 123′, and a tunnel insulating layer 125′ which are formed of the same materials as described with reference to FIGS. 6A to 6C. Each of the blocking insulating layer 121′, the data storage layer 123′, and the tunnel insulating layer 125′ may extend along an inner wall of the channel hole H′. The blocking insulating layer 121′ may be disposed between the inner wall of the channel hole H′ and the data storage layer 123′, and the data storage layer 123′ may be disposed between the blocking insulating layer 121′ and the tunnel insulating layer 125′.

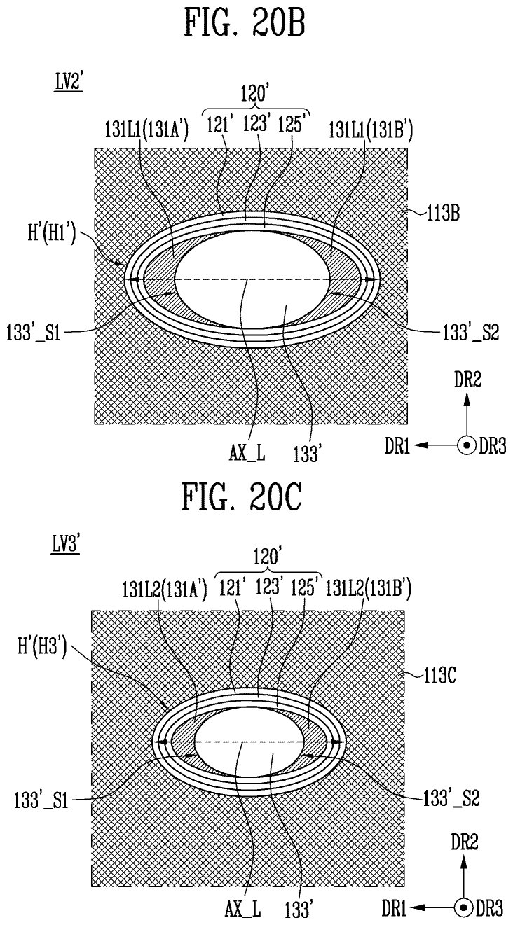

FIGS. 20A, 20B, and 20C are plan views illustrating a cell plug in accordance with an embodiment of the present disclosure. FIG. 20A illustrates a cross-section of the cell plug CP′ at the first level LV1′ shown in FIG. 17 or 18, FIG. 20B illustrates a cross-section of the cell plug CP′ at the second level LV2′ shown in FIG. 17 or 18, and FIG. 20C illustrates a cross-section of the cell plug CP′ at the third level LV3′ shown in FIG. 17 or 18. Hereinafter, overlapping descriptions of portions identical to those shown in FIGS. 19A to 19C may be simplified or omitted.

Referring to FIGS. 19A to 19C, each of the first portion H1′, the second portion H2′, and the third portion H3′ of the channel hole H′ may include an elliptical cross-sectional structure. A cross-sectional structure of the filling channel portion 131F may have an elliptical shape corresponding to the second portion H2′. A cross-sectional structure of each of the first liner channel portion 131L1 and the second liner channel portion 131L2 may have a crescent moon shape having a width which becomes narrower as approaching an end portion thereof.

The core insulating layer 133′ may include a first sidewall 133′_S1 and a second sidewall 133′_S2, which face in directions opposite to each other. The first sidewall 133′_S1 and the second sidewall 133′_S2 may be aligned on a major axis AX_L defined by the elliptical cross-sectional structure of the channel hole H′. Each of the first sidewall 133′_S1 and the second sidewall 133′_S2 may extend in the third direction DR3 along the first portion H1′ and the second portion H2′ of the channel hole H′.

The first liner channel portion 131L1 and the second liner channel portion 131L2, which extend along the first sidewall 133′_S1 of the core insulating layer 133′, may be connected to each other to form a first channel pattern 131A′. The first liner channel portion 131L1 and the second liner channel portion 131L2, which extend along the second sidewall 133′_S2 of the core insulating layer 133′, may be connected to each other to form a second channel pattern 131B′. The core insulating layer 133′ may be in contact with the memory layer 120′ between the first channel pattern 131A′ and the second channel pattern 131B′. The doped capping layer 135′ shown in FIG. 17 or 18 may be structurally isolated into a first doped capping pattern in contact with the first channel pattern 131A′ and a second doped capping pattern in contact with the second channel pattern 131B′.

The filling channel portion 131F may include a connection portion connecting the first channel pattern 131A′ and the second channel pattern 131B′ to each other. The first channel pattern 131A′ and the second channel pattern 131B′ may be connected to different bit lines to be used as channel regions of different memory cell strings, respectively.

The memory layer 120′ may include a blocking insulating layer 121′, a data storage layer 123′, and a tunnel insulating layer 125′, which are formed with the same materials as described with reference to FIGS. 6A to 6C.

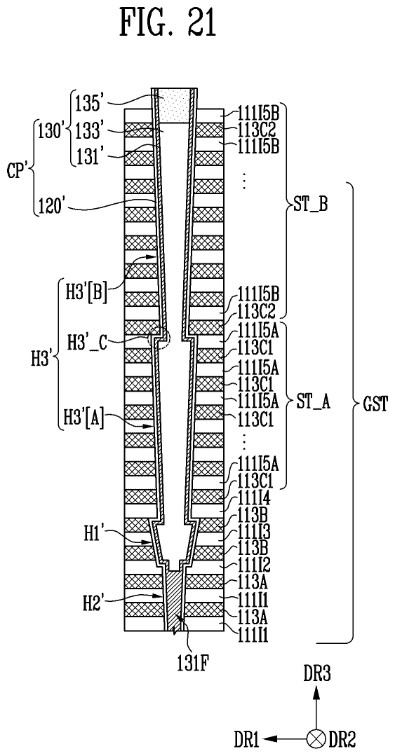

FIG. 21 is a sectional view of a semiconductor memory device in accordance with an embodiment of the present disclosure. A gate stack structure GST and a cell plug CP′, which are shown in FIG. 21, may substitute for the gate stack structure GST and the cell plug CP′, which are shown in FIG. 17 or 18. Hereinafter, overlapping descriptions of portions identical to those shown in FIGS. 17 and 18 may be simplified or omitted.

Referring to FIG. 21, the gate stack structure GST may include a plurality of conductive layers 113A, 113B, 113C1, and 113C2 extending in the first direction DR1 and the second direction DR2. The plurality of conductive layers 113A, 113B, 113C1, and 113C2 may be stacked spaced apart from each other in the third direction DR3. The gate stack structure GST may further include a plurality of interlayer insulating layers 111I1, 111I2, 111I3, 111I4, 111I5A, and 111I5B. The plurality of interlayer insulating layers 111I1, 111I2, 111I3, 111I4, 111I5A, and 111I5B may be alternately disposed one by one with the plurality of conductive layers 113A, 113B, 113C1, and 113C2 in the third direction DR3.

The plurality of conductive layers 113A, 113B, 113C1, and 113C2 may include at least one first conductive layer 113A, at least one second conductive layer 113B, and a plurality of third conductive layers 113C1 and 113C2 as described with reference to FIGS. 17 and 18. The plurality of interlayer insulating layers 111I1, 111I2, 111I3, 111I4, 111I5A, and 111I5B may include a first interlayer insulating layer 111I1, a second interlayer insulating layer 111I2, a third interlayer insulating layer 111I3, a fourth interlayer insulating layer 111I4, and a plurality of fifth interlayer insulating layers 111I5A and 111I5B as described with reference to FIGS. 17 and 18.

The plurality of third conductive layers 113C1 and 113C2 and the plurality of fifth interlayer insulating layers 111I5A and 111I5B may be divided into multiple sub-stack structures stacked in the third direction DR3. In an embodiment, the plurality of third conductive layers 113C1 and 113C2 and the plurality of fifth interlayer insulating layers 111I5A and 111I5B may be divided into a first sub-stack structure ST_A and a second sub-stack structure ST_B. Hereinafter, an embodiment of the present disclosure will be representatively described based on an embodiment in which the plurality of third conductive layers 113C1 and 113C2 and the plurality of fifth interlayer insulating layers 111I5A and 111I5B are divided into two sub-stack structures.

The plurality of third conductive layers 113C1 and 113C2 may be divided into a first sub-group of third conductive layers 113C1 forming the first sub-stack structure ST_A and a second sub-group of third conductive layers 113C2 forming the second sub-stack structure ST_B. The plurality of fifth interlayer insulating layers 111I5A and 111I5B may be divided into a first sub-group of fifth interlayer insulating layers 111I5A forming the first sub-stack structure ST_A and a second sub-group of fifth interlayer insulating layers 111I5B forming the second sub-stack structure ST_B.

A channel hole H′ may include the first portion H1′ and the second portion H2′, which are described with reference to FIGS. 17 and 18. The channel hole H′ may include a third portion H3′ extending from the first portion H1′ to pass through the plurality of third conductive layers 113C1 and 113C2 and the plurality of fifth interlayer insulating layers 111I5A and 111I5B. The third portion H3′ may be formed in a connection structure of penetration portions respectively passing through the sub-stack structures. In an embodiment, the third portion H3′ may be formed in a connection structure of a first penetration portion H3′[A] passing through the first sub-stack structure ST_A and a second penetration portion H3′[B] passing through the second sub-stack structure ST_B. A corner H3′_C of the third portion H3′ may be defined due to a width difference between the first penetration portion H3′[A] and the second penetration portion H3′[B] at a level at which the first penetration portion H3′[A] and the second penetration portion H3′[B] are connected to each other. The corner H3′_C of the third portion H3′ may be defined between the third conductive layer 113C1 of the first sub-group and the third conductive layer 113C2 of the second sub-group, which are adjacent in the third direction DR3.

A memory layer 120′ and a channel structure 130′ may be disposed in the channel hole H′ having the above-described structure. The channel structure 130′ may include a channel layer 131′, a core insulating layer 133′, and a doped capping layer 135′. The channel layer 131′ may include a filling channel portion 131F filling a central region of the first portion H1′ in the channel hole H′.

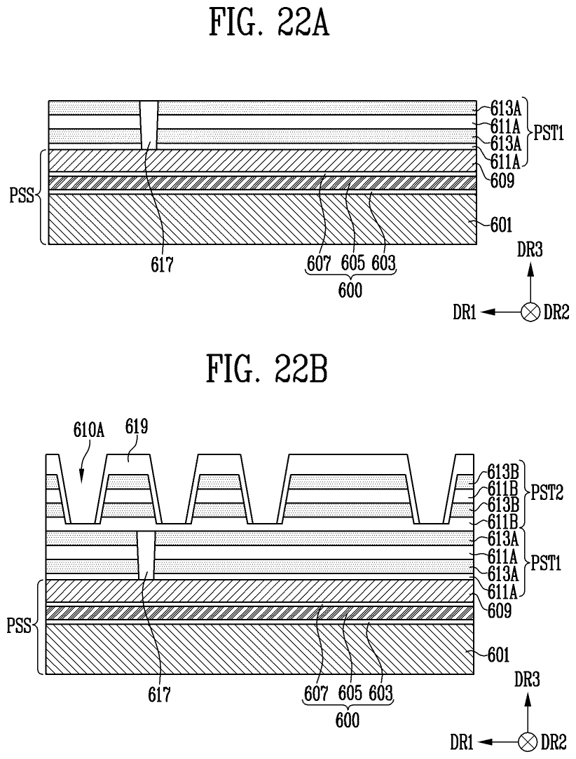

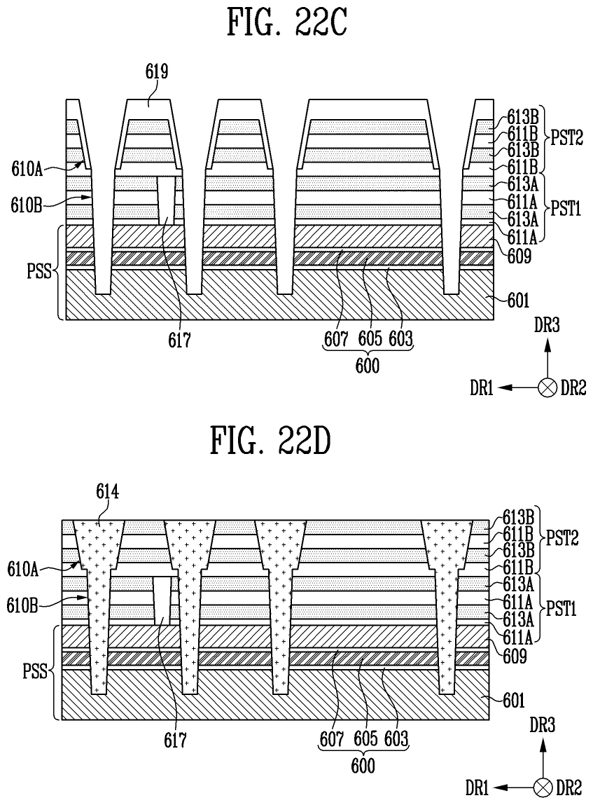

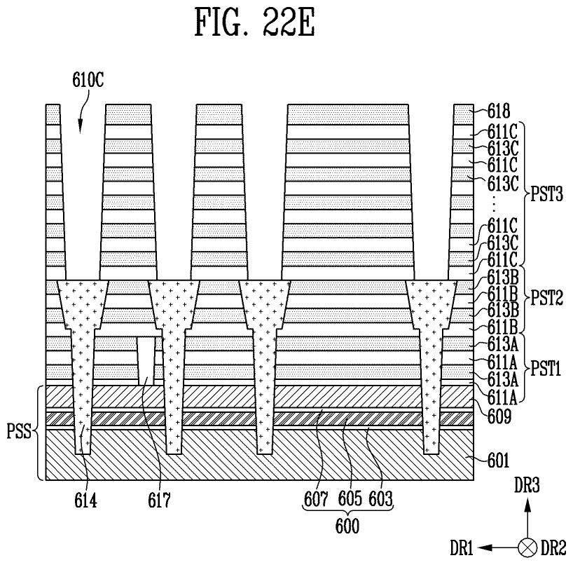

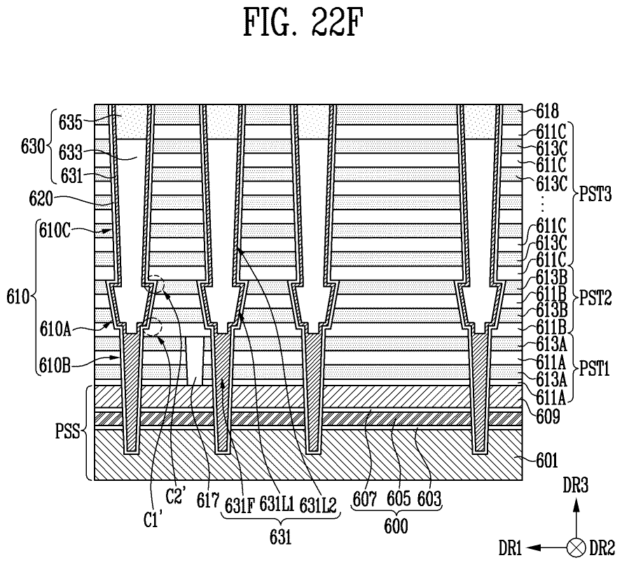

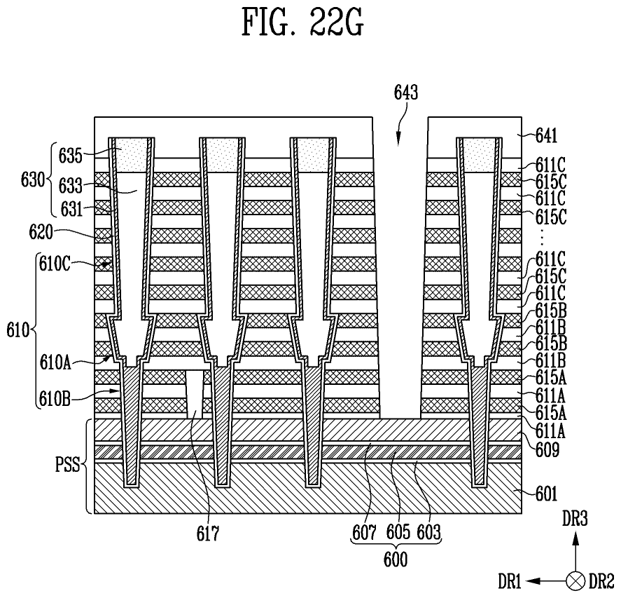

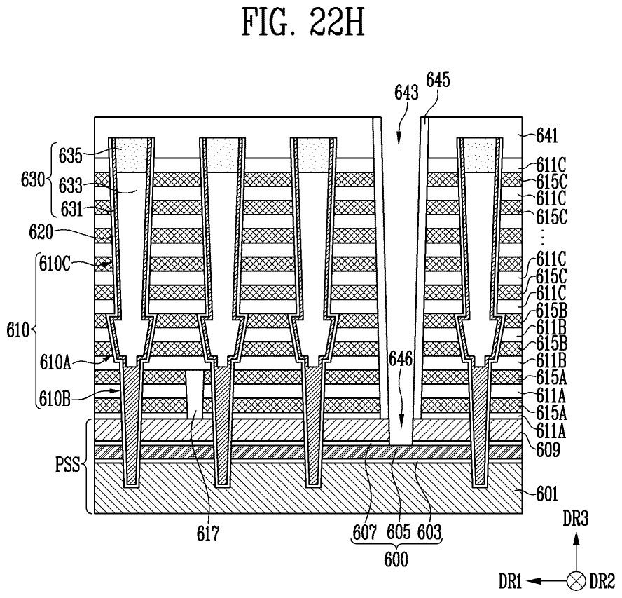

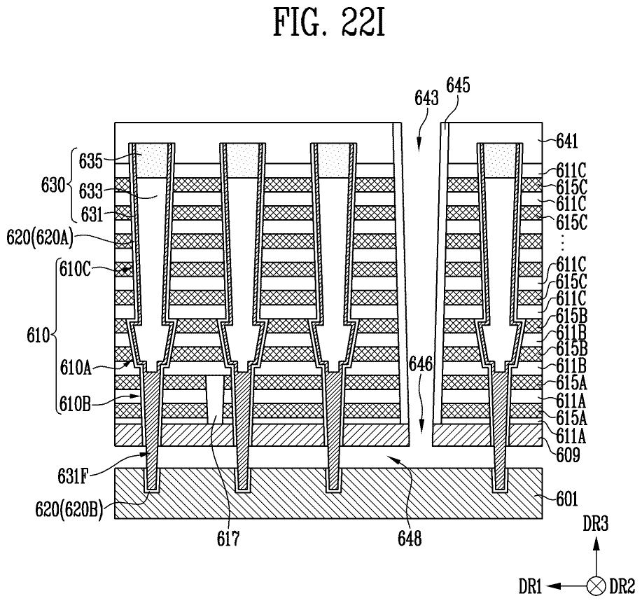

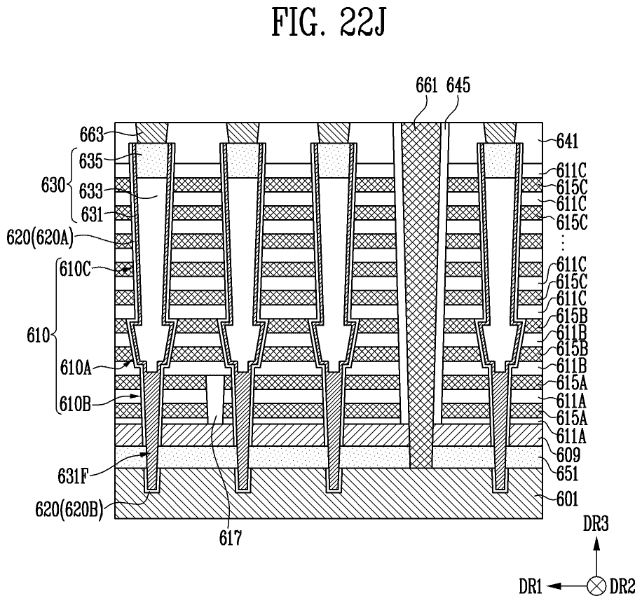

FIGS. 22A to 22J are sectional views illustrating a manufacturing method of a semiconductor memory device in accordance with an embodiment of the present disclosure.

Referring to FIG. 22A, a preliminary semiconductor structure PSS may be formed. The preliminary semiconductor structure PSS may have a surface extending in the first direction DR1 and the second direction DR2. Hereinafter, the third direction DR3 may be a direction in which an axis intersecting the surface of the preliminary semiconductor structure PSS faces. The preliminary semiconductor structure PSS may be formed as a multi-layer. In an embodiment, the preliminary semiconductor structure PSS may include a first semiconductor layer 601, a sacrificial stack structure 600, and a second semiconductor layer 609.

The first semiconductor layer 601 may be formed on a lower structure including the second structure ST2 shown in FIG. 17. The first semiconductor layer 601 may include at least one of an n-type impurity and a p-type impurity. In an embodiment, the first semiconductor layer 601 may include a doped silicon layer.

The sacrificial stack structure 600 may be formed on the first semiconductor layer 601. The sacrificial stack structure 600 may include at least one material layer having an etch selectivity with respect to the first semiconductor layer 601. In an embodiment, the sacrificial stack structure 600 may be formed in a single-layer structure including a sacrificial layer 605. In another embodiment, the sacrificial stack structure 600 may be formed in a multi-layer structure including a first protective layer 603, the sacrificial layer 605 on the first protective layer 603, and a second protective layer 607 on the sacrificial layer 605. The sacrificial layer 605 may include a material having an etch selectivity with respect to the first semiconductor layer 601. In an embodiment, the sacrificial layer 605 may include a nitride layer or an undoped silicon layer. Each of the first protective layer 603 and the second protective layer 607 may include at least one of an oxide layer and a nitride layer by considering an etch selectivity thereof. In an embodiment, each of the first protective layer 603 and the second protective layer 607 may be formed as a single layer of an oxide layer or be formed as a double layer or a triple layer, which is formed with a combination of the oxide layer and the nitride layer. The first protective layer 603 and the second protective layer 607 may be formed in the same structure or be formed in different structures. In an embodiment, the first protective layer 603 may be formed in a double-layer structure of the oxide layer and the nitride layer, and the second protective layer 607 may be formed in a single-layer structure of the oxide layer.

The second semiconductor layer 609 may be formed on the sacrificial stack structure 600. The second semiconductor layer 609 may include at least one of an n-type impurity and a p-type impurity. The second semiconductor layer 609 may include a material layer having an etch selectivity with respect to the sacrificial stack structure 600. In an embodiment, the second semiconductor layer 609 may include doped silicon.

Subsequently, a first preliminary stack structure PST1 may be formed on the preliminary semiconductor structure PSS. The first preliminary stack structure PST1 may be formed by alternately disposing a first material layer 611A and a second material layer 613A in the third direction DR3.

The second material layer 613A may be formed of a material having an etch selectivity with respect to the first material layer 611A. In an embodiment, the first material layer 611A may include an insulating material such as a silicon oxide layer or a silicon nitride layer, and the second material layer 613A may include a sacrificial insulating material such as a silicon nitride layer. The sacrificial insulating material may be replaced with a conductive material including at least one of a doped semiconductor layer, a metal layer, and a conductive metal nitride layer in a subsequent process. In another embodiment, the first material layer 611A may include a sacrificial material such as an undoped silicon layer, and the second material layer 613A may include a conductive material such as a doped silicon layer. The sacrificial material may be replaced with an insulating material including a silicon oxide layer, a silicon oxynitride layer, and the like in a subsequent process.

Unlike as described above, the first material layer 611A may be formed of an insulating material, and the second material layer 613A may be formed of a conductive material. In an embodiment, the first material layer 611A may include a silicon oxide layer, a silicon oxynitride layer, and the like, and the second material layer 613A may include at least one of a doped semiconductor layer, a metal layer, and a conductive metal nitride layer.

After the first preliminary stack structure PST1 is formed, a select line isolation insulating layer 617 may be formed. The select line isolation insulating layer 617 may passe through the first preliminary stack structure PST1. The select line isolation insulating layer 617 may fill a trench formed through an etching process. The etching process for forming the trench may be performed toward the second semiconductor layer 609 from a surface of the first preliminary stack structure PST1. Through this etching process, the trench may have a tapered shape which becomes thinner in a direction in which a distance to the second semiconductor layer 609 decreases. Similarly to the trench, the select line isolation insulating layer 617 may have a tapered shape which becomes thinner in a direction in which a distance to the second semiconductor layer 609 decreases. The trench and the select line isolation insulating layer 617 may be formed with the same layout as the select line isolation structure SL_I′ shown in FIG. 16A.

Referring to FIG. 22B, a second preliminary stack structure PST2 may be formed on the first preliminary stack structure PST1. The second preliminary stack structure PST2 may be formed by alternately disposing a third material layer 611B and a fourth material layer 613B in the third direction DR3. The third material layer 611B may include the same material as the first material layer 611A, and the fourth material layer 613B may include the same material as the second material layer 613A.

Subsequently, a first opening 610A may be formed to pass through the second preliminary stack structure PST2. A bottom surface of the first opening 610A may be located at a level between the second material layer 613A and the fourth material layer 613B, which are adjacent to each other in the third direction DR3.

After that, a spacer layer 619 may be formed to cover a sidewall of the first opening 610A. The spacer layer 619 may include a material having an etch selectivity with respect to the first material layer 611A, the second material layer 613A, the third material layer 611B, and the fourth material layer 613B. In an embodiment, the spacer layer 619 may include a carbon layer, a carbon doping layer, a high dielectric layer doped with a metal, a metal oxide layer, and the like. For example, the spacer layer 619 may be formed of an aluminum oxide (Al₂O₃) or a silicon carbon nitride (SiCN). A portion of the first opening 610A and a portion of the spacer layer 619 may overlap with a portion of the select line isolation insulating layer 617. A thickness of the spacer layer 619 may be controlled such that a central portion of the first opening 610A opened by the spacer layer 619 does not overlap with the select line isolation insulating layer 617.

Referring to FIG. 22C, through an etching process using the spacer layer 619 shown in FIG. 22B as an etch barrier, the first material layer 611A and the second material layer 613A of the first preliminary stack structure PST1 may be etched through the first opening 610A, and the second semiconductor layer 609 and the sacrificial stack structure 600 may be etched through the first opening 610A. Accordingly, a second opening 610B may be formed. The second opening 610B may be connected to the first opening 610A and be formed with a width narrower than the width of the first opening 610A. The second opening 610B may extend to the inside of the first semiconductor layer 601 while passing through the first preliminary stack structure PST1, the second semiconductor layer 609, and the sacrificial stack structure 600. After the second opening 610B is formed, the spacer layer 619 may be removed.

Referring to FIG. 22D, a sacrificial structure 614 may be formed to fill the first opening 610A and the second opening 610B. The sacrificial structure 614 may include a material having an etch selectivity with respect to the preliminary semiconductor structure PSS. In an embodiment, the sacrificial structure 614 may include a metal such as tungsten. The sacrificial structure 614 may further include a barrier layer. The barrier layer may be formed along an interface between the metal and the preliminary semiconductor structure PSS. The barrier layer may include a metal nitride layer such as a titanium nitride layer.

Referring to FIG. 22E, a third preliminary stack structure PST3 may be formed on the second preliminary stack structure PST2. The third preliminary stack structure PST3 may be formed by alternately disposing a plurality of fifth material layers 611C and a plurality of sixth material layers 613C one by one in the third direction DR3. The plurality of fifth material layers 611C may include the same material as the first material layer 611A, and the plurality of sixth material layers 613C may include the same material as the second material layer 613A.

Subsequently, a mask layer 618 may be formed on the third preliminary stack structure PST3. After that, a third opening 610C passing through the third preliminary stack structure PST3 may be formed through an etching process using the mask layer 618 as an etch barrier. The third opening 610C may expose the sacrificial structure 614. The third opening 610C shown in FIG. 22E may correspond to the third portion H3′ of the channel hole H′ shown in FIG. 17 or 18.

The process for forming the third opening 610C is not limited to the above-described embodiment. Although not shown in the drawing, in another embodiment, in order to form a third opening corresponding to the third portion H3′ of the channel hole H′ shown in FIG. 21, the process for forming the third opening may include a process of forming a lower third preliminary stack structure, a process of forming a lower portion of the third opening passing through the lower third preliminary stack structure, a process of filling the lower portion of the third opening with a sacrificial pillar, a process of forming an upper third preliminary stack structure on the lower third preliminary stack structure, a process of forming an upper portion of the third opening passing through the upper third preliminary stack structure, and a process of removing the sacrificial pillar through the upper portion of the third opening.

As described above, after the third opening 610C is formed in various manners, the sacrificial structure 614 may be removed through the third opening 610C. Accordingly, the first opening 610A, the second opening 610B, and the third opening 610C may be connected to each other, to define a channel hole 610 as shown in FIG. 22F, and the preliminary semiconductor structure PSS, the first material layer 611A, the second material layer 613A, the third material layer 611B, the fourth material layer 613B, the plurality of fifth material layers 611C, and the plurality of sixth material layers 613C may be exposed along a surface of the channel hole 610.

Referring to FIG. 22F, the channel hole 610 may include a first corner region C1′ and a second corner region C2′. The first corner region C1′ may be defined as a width of the first opening 610A and is formed wider than the width of the second opening 610B in a region adjacent to an interface between the first preliminary stack structure PST1 and the second preliminary stack structure PST2. The second corner region C2′ may be defined as a width of the third opening 610C and is formed narrower than the width of the second opening 610B in a region adjacent to an interface between the second preliminary stack structure PST2 and the third preliminary stack structure PST3.

A memory layer 620 may be formed along the surface of the channel hole 610. The memory layer 620 may include the blocking insulating layer 121′, the data storage layer 123′, and the tunnel insulating layer 125′, which are shown in FIGS. 19A to 19C or FIGS. 20A to 20C.

Subsequently, a channel structure 630 including a channel layer 631 may be formed on the memory layer 620. The channel layer 631 may include silicon (Si), germanium (Ge), or any mixture thereof. The channel layer 631 may include a filling channel portion 631F, a first liner channel portion 631L1, and a second liner channel portion 631L. The filling channel portion 631F may fill a central region of the second opening 610B. The first liner channel portion 631L1 may be disposed in the first opening 610A, and the second liner channel portion 631L2 may be disposed in the third opening 610C. A structure of each of the first liner channel portion 631L1 and the second liner channel portion 631L2 may vary. In an embodiment, a cross-sectional structure of each of the first liner channel portion 631L1 and the second liner channel portion 631L2 may be formed in a ring shape as described with reference to FIGS. 19B and 19C. In another embodiment, the cross-sectional structure of each of the first liner channel portion 631L1 and the second liner channel portion 631L2 may be formed in a crescent moon shape having a width which becomes narrower as approaching an end portion thereof as described with reference to FIGS. 20B and 20C.

The channel structure 630 may further include a core insulating layer 633 and a doped capping layer 635. The doped capping layer 635 may be formed of a semiconductor layer including at least one of an n-type impurity and a p-type impurity. In an embodiment, the doped capping layer 635 may include the n-type impurity as a majority carrier. The core insulating layer 633 and the doped capping layer 635 may be disposed in a central region of the first opening 610A and a central region of the third opening 610C, which are opened by the first liner channel portion 631L1 and the second liner channel portion 631L2. In an embodiment, when each of the first liner channel portion 631L1 and the second liner channel portion 631L2 includes a ring-shaped cross-sectional structure as described with reference to FIGS. 19B and 19C, the doped capping layer 635 may be formed to fill the central region of the third opening 610C at an upper end of the third opening 610C. In another embodiment, when each of the first liner channel portion 631L1 and the second liner channel portion 631L2 includes a crescent-moon-shaped cross-sectional structure as described with reference to FIGS. 20B and 20C, an isolation insulating structure (not shown) isolating the doped capping layer 635 into a first doped capping pattern and a second doped capping pattern may be further formed in the third opening 610C.

After the channel structure 630 is formed, the mask layer 618 may be removed.

Referring to FIG. 22G, a first insulating layer 641 may be formed to cover the channel structure 630 and the third preliminary stack structure PST3, which are shown in FIG. 22F. Subsequently, a slit 643 may be formed to pass through the first insulating layer 641, and the first preliminary stack structure PST1, the second preliminary stack structure PST2, and the third preliminary stack structure PST3, which are shown in FIG. 22F.

A subsequent process continued after the above described process may vary according to properties of the first material layer 611A, the second material layer 613A, the third material layer 611B, the fourth material layer 613B, the plurality of fifth material layers 611C, and the plurality of sixth material layers 613C, which are shown in FIG. 22F. Hereinafter, the subsequent process will be described based on an embodiment in which the first material layer 611A, the third material layer 611B, and the plurality of fifth material layers 611C, which are shown in FIG. 22F, include an insulating material, and the second material layer 613A, the fourth material layer 613B, and the plurality of sixth material layers 613C, which are shown in FIG. 22F, include a sacrificial insulating material having an etch selectivity with respect to the insulating material.

The second material layer 613A, the fourth material layer 613B, and the plurality of sixth material layers 613C, which are shown in FIG. 22F, may be replaced with a plurality of conductive layers 615A, 615B, and 615C through the slit 643. The plurality of conductive layers 615A, 615B, and 615C may include a first conductive layer 615A, a second conductive layer 615B, and a plurality of third conductive layers 615C. The first conductive layer 615A may be isolated into source select lines by the select line isolation insulating layer 617 and the slit 643. The second conductive layer 615B may be isolated into word lines by the slit 643. Some of the plurality of third conductive layers 615C may be isolated into word lines by the slit 643, and the others of the plurality of third conductive layers 615C may be isolated into drain select lines by the slit 643.

Referring to FIG. 22H, a sidewall insulating layer 645 may be formed on a sidewall of the slit 643. The sidewall insulating layer 645 may be formed to expose the bottom of the slit 643.

Subsequently, the second semiconductor layer 609 may be etched through the slit 643, thereby forming a slit extension portion 646. The slit extension portion 646 may pass through the second semiconductor layer 609 and pass through the second protective layer 607 of the sacrificial stack structure 600. The sacrificial layer 605 of the sacrificial stack structure 600 may be exposed through the slit extension portion 646.

Referring to FIG. 22I, the sacrificial layer 605 of the sacrificial stack structure 600 shown in FIG. 22H may be removed through the slit extension portion 646. Accordingly, a portion of the memory layer 620 shown in FIG. 22H may be exposed between the first semiconductor layer 601 and the second semiconductor layer 609. After that, the exposed portion of the memory layer 620 may be removed through the slit extension portion 646. The first protective layer 603 and the second protective layer 607 of the sacrificial stack structure 600 shown in FIG. 22H may be removed.

Through the above-described process, a horizontal space 648 may be opened. The first semiconductor layer 601 and the second semiconductor layer 609 may be exposed by the horizontal space 648. The filling channel portion 631F of the channel layer 631 may be exposed between the first semiconductor layer 601 and the second semiconductor layer 609 by the horizontal space 648. The memory layer 620 may be isolated into a first memory layer 620A and a second memory layer 620B by the horizontal space 648. The first memory layer 620A may be used as a data storage region of a memory cell string, and the second memory layer 620B may remain as a dummy memory layer.

While an etching process for opening the horizontal space 648 is performed, the filling channel portion 631F may reduce or prevent a phenomenon in which an etching material from the horizontal space 648 infiltrates into the core insulating layer 633. Accordingly, although a void remains inside the core insulating layer 633, in an embodiment of the present disclosure, a phenomenon in which the above-described etching material infiltrates into the void may be reduced or prevented, and a process failure occurring when the etching material infiltrates into the void may be reduced or prevented.

Referring to FIG. 22J, the horizontal space 648 shown in FIG. 22I may be filled with a third semiconductor layer 651. The third semiconductor layer 651 may surround a sidewall of the filling channel portion 631F between the first semiconductor layer 601 and the second semiconductor layer 609 and be in contact with the sidewall of the filling channel portion 361F.

The third semiconductor layer 651 may include at least one of an n-type impurity and a p-type impurity. In an embodiment, the third semiconductor layer 651 may include the n-type impurity as a majority carrier and be a silicon layer.

Because the core insulating layer 633 is blocked by the filling channel portion 631F, a failure in which the third semiconductor layer 651 infiltrates into the void inside the core insulating layer 633 may be reduced or prevented. Thus, a leakage current which may be generated when the third semiconductor layer 651 infiltrates into the void inside the core insulating layer 633 may be reduced or prevented.

After that, the slit extension portion 646 and the slit 643, which are shown in FIG. 22I, may be filled with an insulating material, a semiconductor material, or a conductive material. In an embodiment, a conductive material may be formed in the slit extension portion 646 and the slit 643 which are shown in FIG. 22I, thereby providing a conductive contact structure 661. Subsequently, a subsequent process such as a process of forming a first bit line contact 663 may be performed, thereby providing the semiconductor memory device shown in FIG. 17.

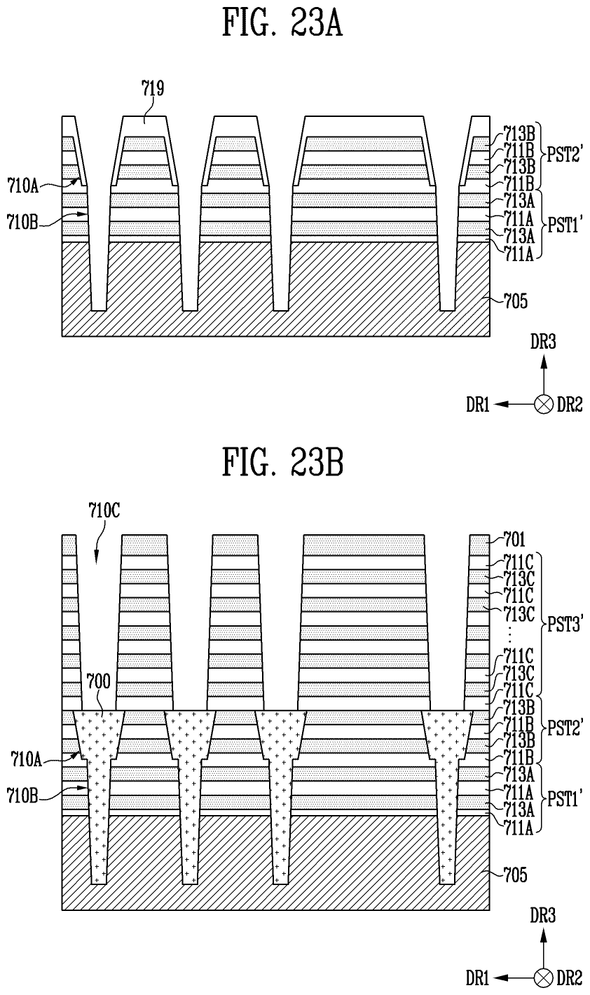

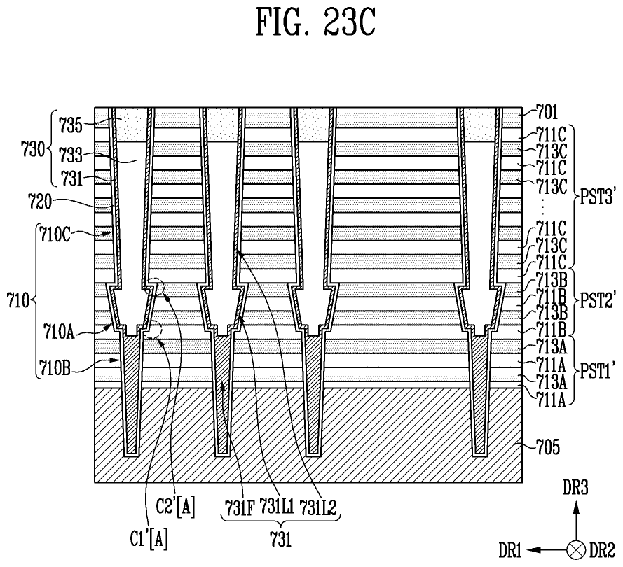

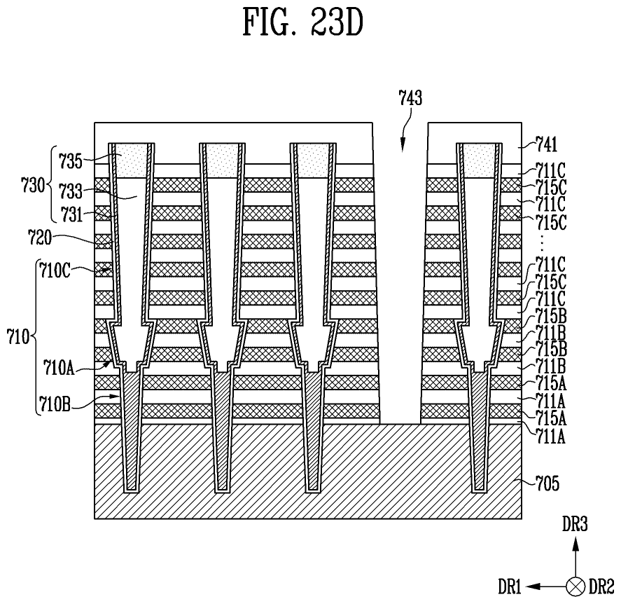

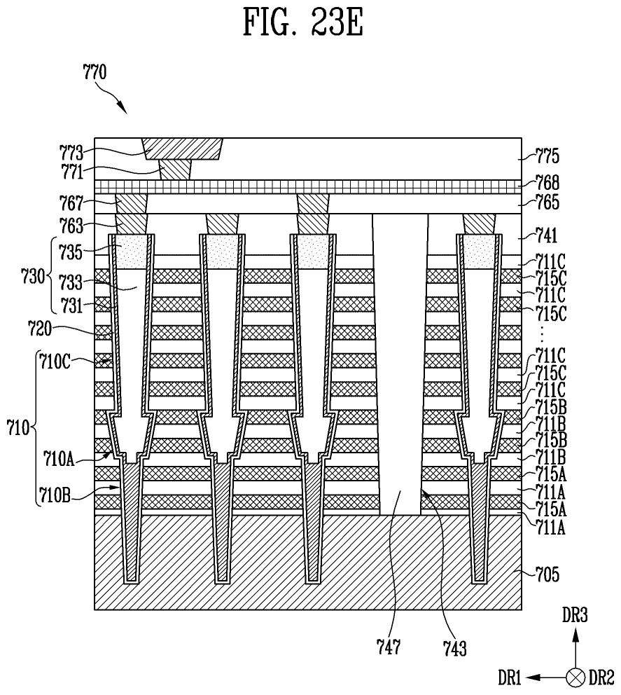

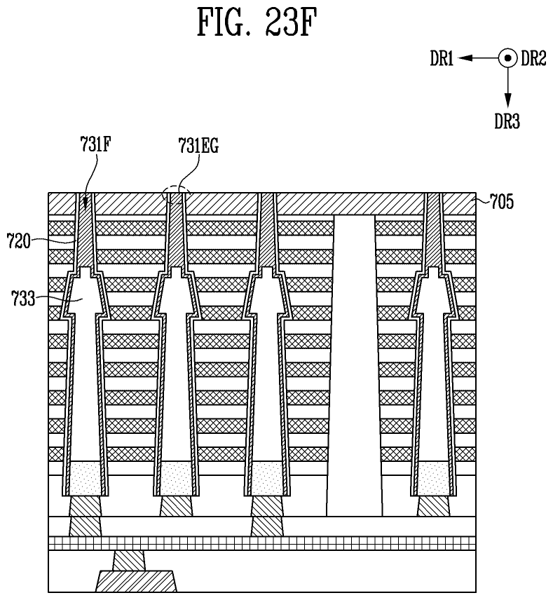

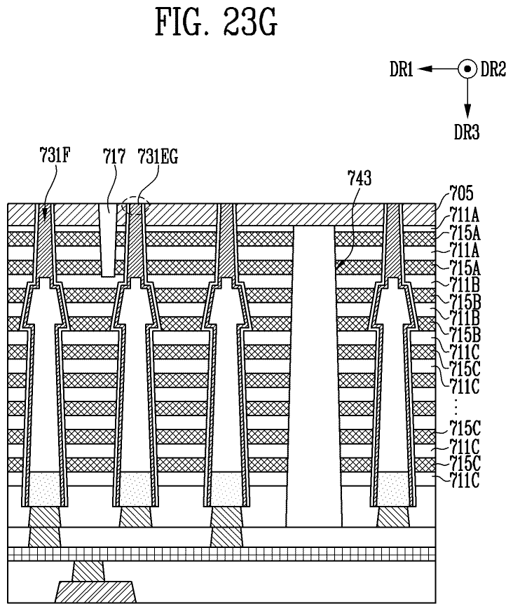

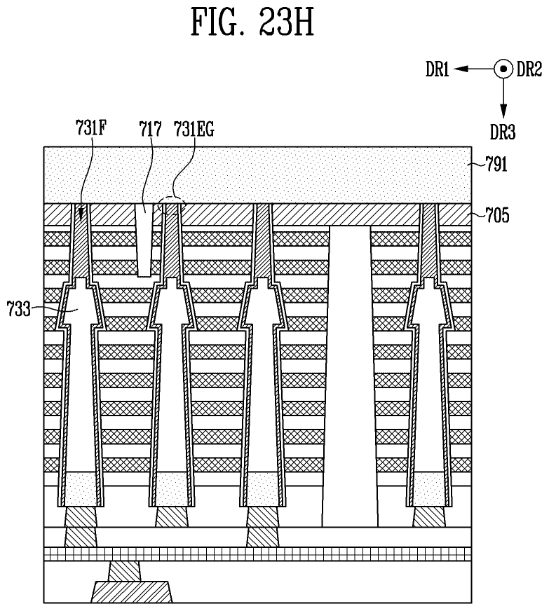

FIGS. 23A to 23H are sectional views illustrating a manufacturing method of a semiconductor memory device in accordance with an embodiment of the present disclosure.

Referring to FIG. 23A, a first preliminary stack structure PST1′ and a second preliminary stack structure PST2′ may be sequentially formed on a semiconductor layer 705. The semiconductor layer 705 may include an upper surface and a back surface, which extend in the first direction DR1 and the second direction DR2. The first preliminary stack structure PST1′ and the second preliminary stack structure PST2′ may be stacked on the upper surface of the semiconductor layer 705 in the third direction DR3 in which the upper surface faces.

The semiconductor layer 705 may include a silicon wafer. The semiconductor layer 705 may include an amorphous semiconductor, a polycrystalline semiconductor, or any mixture thereof. The semiconductor layer 705 may include at least one of an undoped region and a doped region.

The first preliminary stack structure PST1′ may be formed by alternately disposing a first material layer 711A and a second material layer 713A in the third direction DR3. The first material layer 711A may be formed of the same material as the first material layer 611A described with reference to FIG. 22A, and the second material layer 713A may be formed of the same material as the second material layer 613A described with reference to FIG. 22A.

The second preliminary stack structure PST2′ may be formed on the first preliminary stack structure PST1′ by alternately disposing a third material layer 711B and a fourth material layer 713B in the third direction DR3. The third material layer 711B may include the same material as the first material layer 711A, and the fourth material layer 713B may include the same material as the second material layer 713A.

Subsequently, a first opening 710A may be formed to pass through the second preliminary stack structure PST2′. After that, a spacer layer 719 may be formed to cover a sidewall of the first opening 710A. The spacer layer 719 may include a material having an etch selectivity with respect to the first material layer 711A, the second material layer 713A, the third material layer 711B, and the fourth material layer 713B. In an embodiment, the spacer layer 719 may include a carbon layer, a carbon doping layer, a high dielectric layer doped with a metal, a metal oxide layer, and the like. For example, the spacer layer 719 may be formed of an aluminum oxide (Al₂O₃) or a silicon carbon nitride (SiCN).

Through an etching process using the spacer layer 719 as an etch barrier, the first material layer 711A and the second material layer 713A of the first preliminary stack structure PST1′ may be etched through the first opening 710A, and a portion of the semiconductor layer 705 may be etched through the first opening 710A. Accordingly, a second opening 710B may be formed. The second opening 710B may be connected to the first opening 710A and be formed with a width narrower than the width of the first opening 710A. The second opening 710B may extend to the inside the semiconductor layer 705 while passing through the first preliminary stack structure PST1′. After the second opening 710B is formed, the spacer layer 719 may be removed.

Referring to FIG. 23B, as described with reference to FIG. 22D, the first opening 710A and the second opening 710B may be filled with a sacrificial structure 700. Subsequently, as described with reference to FIG. 22E, a plurality of fifth material layers 711C and a plurality of sixth material layers 713C may be alternately disposed one by one in the third direction DR3 on the second preliminary stack structure PST2′, thereby forming a third preliminary stack structure PST3′. The plurality of fifth material layers 711C may include the same material as the first material layer 711A, and the plurality of sixth material layers 713C may include the same material as the second material layer 713A.

Subsequently, a mask layer 701 may be formed on the third preliminary stack structure PST3′. After that, as described with reference to FIG. 22E, a third opening 710C passing through the third preliminary stack structure PST3′ may be formed through an etching process using the mask layer 701 as an etch barrier. After the third opening 710C is formed, the sacrificial structure 700 may be removed. Accordingly, the first opening 710A, the second opening 710B, and the third opening 710C may be connected to each other, to define a channel hole 710 as shown in FIG. 23C.

Referring to FIG. 23C, as described with reference to FIG. 22F, the channel hole 710 may include a first corner region C1′[A] and a second corner region C2′[A] due to width differences between the first opening 710A, the second opening 710B, and the third opening 710C.

Subsequently, as described with reference to FIG. 22F, a memory layer 720 may be formed and a channel structure 730 may be formed. The channel structure 730 may include a channel layer 731, a core insulating layer 733, and a doped capping layer 735. As described with reference to FIG. 22F, the channel layer 731 may include a filling channel portion 731F in the second opening 710B, a first liner channel portion 731L1 in the first opening 710A, and a second liner channel portion 731L2 in the third opening 710C.

The mask layer 701 may be removed after the channel structure 730 is formed.

Referring to FIG. 23D, as described with reference to FIG. 22G, a process of forming a first insulating layer 741, a process of forming a slit 743, and a process of forming a plurality of conductive layers 715A, 715B, and 715C may be performed. The plurality of conductive layers 715A, 715B, and 715C may include at least one first conductive layer 715A adjacent to the semiconductor layer 705, at least one second conductive layer 715B disposed to be spaced apart from the at least one first conductive layer 715A in the third direction DR3, and a plurality of third conductive layers 715C.

Referring to FIG. 23E, the slit 743 may be filled with an insulating material 747 or be filled with the sidewall insulating layer 645 and the conductive contact structure 661, which are shown in FIG. 22J. Subsequently, a first bit line contact 763 may be formed. The first bit line contact 763 may be in contact with the channel structure 730 while passing through the first insulating layer 741.

After that, a second insulating layer 765 may be formed to cover the first bit line contact 763 and the first insulating layer 741. Subsequently, a second bit line contact 767 and a bit line 768 may be formed. The second bit line contact 767 may contact the first bit line contact 763 while passing through the second insulating layer 765 and the bit line 768 may contact the second bit line contact 767.

Subsequently, a third insulating layer 775 may be formed on the bit line 768. A first contact 771 and a first conductive bonding pad 773 may be buried in the third insulating layer 775.

A first structure 770 may be formed through the processes described with reference to FIGS. 23A to 23E.

Although not shown in the drawing, the second structure ST2 described with reference to FIG. 18 may be provided through a process separate from a process of forming the first structure 770.

FIGS. 23F to 23H are sectional views illustrating an embodiment of processes continued after the first structure 770 shown in FIG. 23E is bonded to a second structure (not shown) provided separately from the first structure 770.

Referring to FIG. 23F, a portion of the semiconductor layer 705 may be removed from the back surface of the semiconductor layer 705 shown in FIG. 23E. In an embodiment, the portion of the semiconductor layer 705 may be removed through a planarization process such as chemical mechanical polishing. The portion of the memory layer 720 may be removed, and an end 731EG of the filling channel portion 731F may be exposed.

In accordance with an embodiment of the present disclosure, while the planarization process is performed, it is difficult for an etching material to infiltrate into the core insulating layer 733 due to the filling channel portion 731F. Accordingly, in the embodiment of the present disclosure, although a void remains inside the core insulating layer 733, a phenomenon in which the above-described etching material infiltrates into the void may be reduced or prevented, and a process failure occurring as the etching material infiltrates into the void may be reduced or prevented.

After the planarization process, the semiconductor layer 705 may remain to constitute an interposition semiconductor layer. However, embodiments of the present disclosure are not limited thereto, and the semiconductor layer 705 may be completely removed through the planarization process.

Referring to FIG. 23G, a trench passing through the semiconductor layer 705, the first material layer 711A, and the first conductive layer 715A may be formed through an etching process, and the trench may be filled with a select line isolation insulating layer 717. The etching process for forming the trench may be performed toward the second conductive layer 715B from the surface of the semiconductor layer 705. The trench may have a tapered shape which becomes thinner as becoming closer to the second conductive layer 715B through this etching process. Similarly to the trench, the select line isolation insulating layer 717 may have a tapered shape which becomes thinner as becoming closer to the second conductive layer 715B.

The select line isolation insulating layer 717 may be formed with the same layout as the select line isolation structure SL_I′ shown in FIG. 16A. The first conductive layer 715A may be isolated into source select lines by the select line isolation insulating layer 717 and the slit 743. The second conductive layer 715B may be isolated into word lines by the slit 743. Some of the plurality of third conductive layers 715C may be isolated into word lines by the slit 743, and the others of the plurality of third conductive layers 715C may be isolated into drain select lines by the slit 743.

Referring to FIG. 23H, a doped semiconductor layer 791 may be formed to contact with the end 731EG of the filling channel portion 731F. The doped semiconductor layer 791 may include at least one of an n-type impurity and a p-type impurity. The doped semiconductor layer 791 may include a semiconductor material such as silicon. Because the core insulating layer 733 is blocked by the filling channel portion 731F, a failure in which the doped semiconductor layer 791 infiltrates into a void inside the core insulating layer 733 may be reduced or prevented. Thus, a leakage current which may be generated when the doped semiconductor layer 791 infiltrates into the void inside the core insulating layer 733 may be reduced or prevented. The doped semiconductor layer 791 and the semiconductor layer 705 may be reformed through an annealing process such as laser anneal.

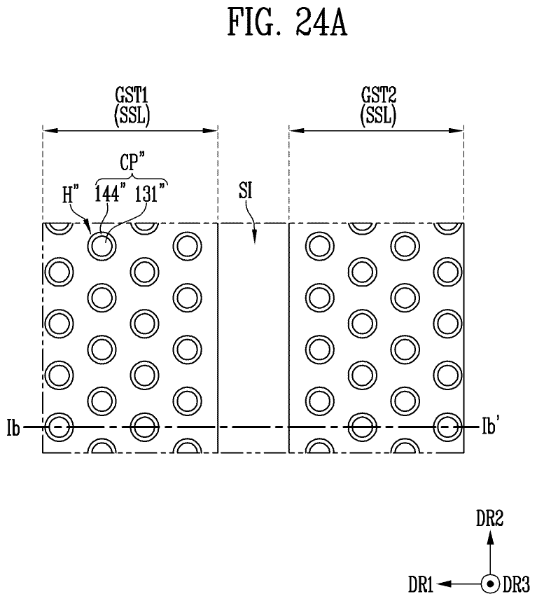

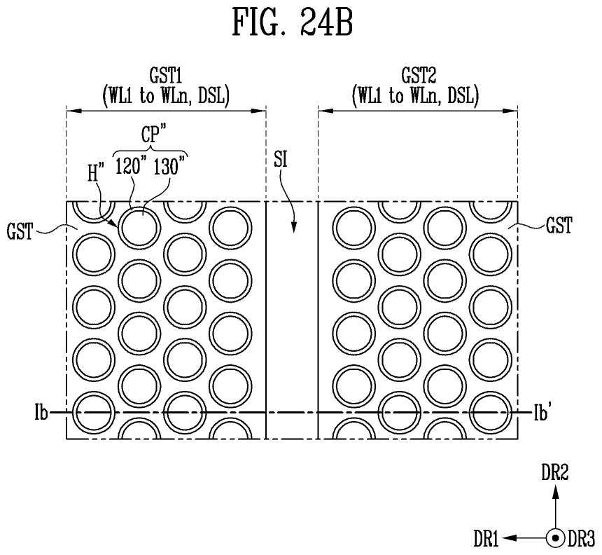

FIGS. 24A and 24B are plan views illustrating a gate stack structure of a semiconductor memory device in accordance with an embodiment of the present disclosure. FIGS. 24A and 24B illustrate a portion of a first gate stack structure GST1 and a portion of a second gate stack structure GST2, which are adjacent to a slit SI. FIG. 24A illustrates a layout of a source select line SSL between the slit SI and the select line isolation structure SL_I or SL_I′ shown in each of FIGS. 2A and 3A. FIG. 24B illustrates a layout of a plurality of word lines WL1 to WLn and a drain select line DSL between the slit SI and the select line isolation structure SL_I or SL_I′ shown in each of FIGS. 2A and 3A.

Referring to FIGS. 24A and 24B, the semiconductor memory device may include a plurality of cell plugs CP″ surrounded by a gate stack structure GST1 or GST2. The memory cell string CS described with reference to FIGS. 2B and 3B may be defined along each cell plug CP″.

The gate stack structure GST1 or GST2 may include a plurality of conductive layers used as the source select line SSL, the plurality of word lines WL1 to WLn, and the drain select line DSL. The plurality of conductive layers may extend in the first direction DR1 and the second direction DR2 and be stacked spaced apart from each other in the third direction DR3.

The gate stack structure GST1 or GST2 may include a plurality of channel holes H″ extending in the third direction DR3. The plurality of cell plugs CP″ may be disposed in the plurality of channel holes H″. An external diameter in each of each cell plug CP″ and each channel hole H″ may be changed according to a position thereof in the third direction DR3. In an embodiment, an external diameter of each of the cell plug CP″ and the channel hole H″ at a first level at which the source select line SSL is disposed may be formed narrower than an external diameter of each of the cell plug CP″ and the channel hole H″ at a second level at which a first word line WL1 is disposed.

The cell plug CP″ may include a gate insulating layer 144″, a filling channel pattern 131″, a memory layer 120″, and a channel structure 130″. The filling channel pattern 131″ may pass through the source select line SSL, and the gate insulating layer 144″ may be interposed between the filling channel pattern 131″ and the source select line SSL. The channel structure 130″ may pass through the plurality of word lines WL1 to WLn and the drain select line DSL, and the memory layer 120″ may be interposed between the channel structure 130″ and the gate stack structure GST.

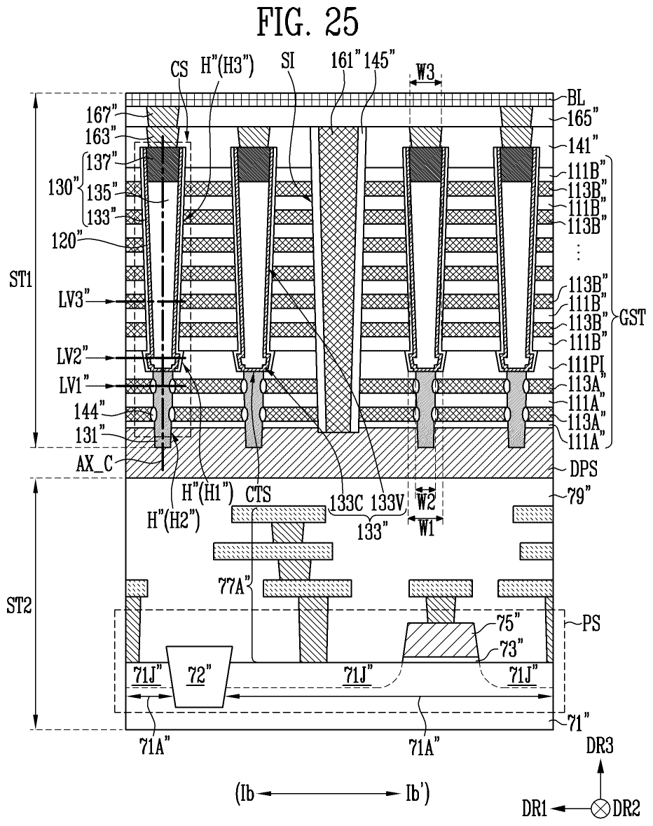

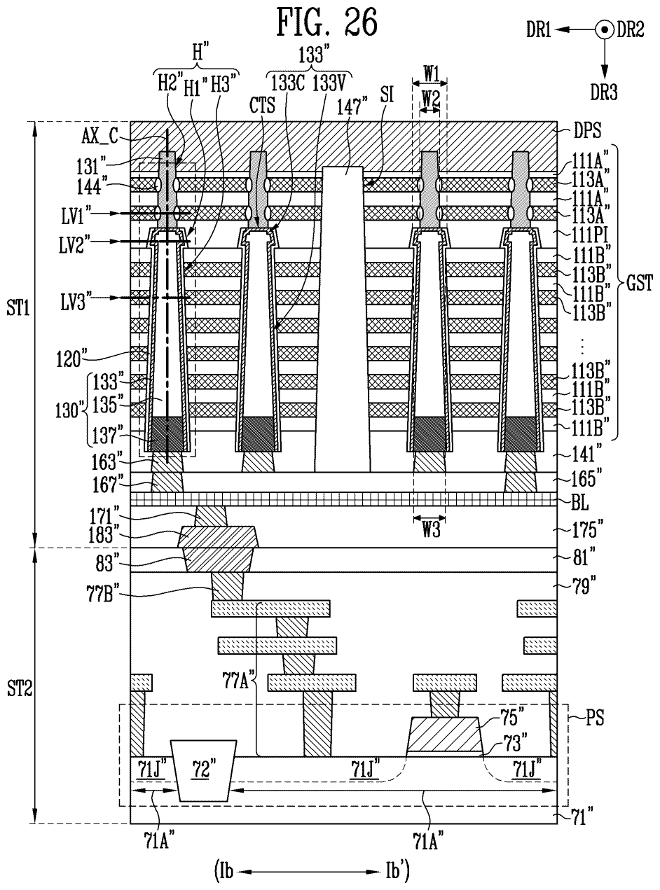

FIGS. 25 and 26 are sectional views of semiconductor memory devices in accordance with embodiments of the present disclosure. A sectional view illustrated in each of FIGS. 25 and 26 may correspond to a sectional view of the semiconductor memory device taken along line Ib-Ib′ shown in each of FIGS. 24A and 24B.

Referring to FIGS. 25 and 26, each of the semiconductor memory devices may include a first structure ST1, a doped semiconductor structure DPS, and a second structure ST2. The first structure ST1 may include a bit line BL, a gate stack structure GST, and the cell plug CP″ described with reference to FIGS. 24A and 24B.

The gate stack structure GST may include a plurality of conductive layers 113A″ and 113B″ extending in the first direction DR1 and the second direction DR2. The plurality of conductive layers 113A″ and 113B″ may be stacked spaced apart from each other in the third direction DR3. The gate stack structure GST may further include a plurality of interlayer insulating layers 111A″, 111PI, and 111B″. The plurality of interlayer insulating layers 111A″, 111PI, and 111B″ may be alternately disposed with the plurality of conductive layers 113A″ and 113B″ in the third direction DR3.

The plurality of conductive layers 113A″ and 113B″ may include at least one of a doped semiconductor layer, a metal layer, and a conductive metal nitride layer. The doped semiconductor layer may include a doped silicon layer. The metal layer may include tungsten, copper, molybdenum, and the like. The conductive metal nitride layer may include titanium nitride, tantalum nitride, and the like. The plurality of conductive layers 113A″ and 113B″ may include at least one first conductive layer 113A″ and a plurality of second conductive layers 113B″. Hereinafter, a structure of the gate stack structure GST will be described based on an embodiment in which the plurality of conductive layers 113A″ and 113B″ include two first conductive layers 113A″, but the embodiments of the present disclosure are not limited thereto. A stacked number of first conductive layers 113A″ may be variously changed with a range in which the stacked number of first conductive layers 113A″ is less than a stacked number of second conductive layers 113B″.

The second conductive layer 113B″ may be disposed to be spaced apart from the first conductive layer 113A″ in the third direction DR3. The first conductive layer 113A″ may include the source select line SSL shown in FIG. 24A. The plurality of second conductive layers 113B″ may include the plurality of word lines WL1 to WLn shown in FIG. 24B and the drain select line (e.g., DSL) shown in FIG. 24B.

The plurality of interlayer insulating layers 111A″, 111PI, and 111B″ may include an insulating material such as a silicon oxide layer or a silicon oxynitride layer. The plurality of interlayer insulating layers 111A″, 111PI, and 111B″ may include a first interlayer insulating layer 111A″, a pad interlayer insulating layer 111PI, and a plurality of second interlayer insulating layers 111B″. The pad interlayer insulating layer 111PI may be disposed between the first conductive layer 113A″ and the second conductive layer 113B″, which are adjacent to each other in the third direction DR3. The first interlayer insulating layer 111A″ may be alternately disposed with the first conductive layer 113A″ in the third direction DR3 between the pad interlayer insulating layer 111PI and the doped semiconductor structure DPS. The plurality of second interlayer insulating layers 111B″ may be alternately disposed with the plurality of second conductive layers 113B″ in the third direction DR3 between the pad interlayer insulating layer 111PI and the bit line BL. The first conductive layer 113A″ may be disposed adjacent to the pad interlayer insulating layer 111P, and one of the plurality of second interlayer insulating layers 111B″ may be interposed between the pad interlayer insulating layer 111PI and the second conductive layer 113B″. However, the embodiments of the present disclosure are not limited thereto.

Although not shown in the drawings, in another embodiment, an interlayer insulating layer may be additionally interposed between the pad interlayer insulating layer 111PI and the first conductive layer 113A″. Although not shown in the drawings, in still another embodiment, the second conductive layer 113B″ may be disposed adjacent to the pad interlayer insulating layer 111PI without interposition of any second interlayer insulating layer.

A slit SI may be filled with various materials. In an embodiment, as shown in FIG. 25, a sidewall insulating layer 145″ may be formed on a sidewall of the slit SI, and a conductive contact structure 161″ may be disposed in a central region of the slit SI. The sidewall insulating layer 145″ may extend to cover sidewalls of the plurality of conductive layers 113A″ and 113B″. The conductive contact structure 161″ may include at least one of a doped semiconductor layer, a metal layer, and a conductive metal nitride layer. The conductive contact structure 161″ may be connected to the doped semiconductor structure DPS. In another embodiment, as shown in FIG. 26, the slit SI may be filled with an insulating material 147″. Although not shown in the drawings, in still another embodiment, the slit SI may be filled with different types of materials including an insulating material, a semiconductor material, a metal, and the like. The semiconductor material may include an amorphous semiconductor layer or a polycrystalline semiconductor layer, and include silicon (Si), germanium (Ge), or any mixture thereof. The semiconductor material or the metal in the slit SI may be disposed to be spaced apart from a surface of the slit SI through the insulating material formed along the surface of the slit SI. Accordingly, the semiconductor material or the metal in the slit SI may be insulated from the doped semiconductor structure DPS.

Referring to FIGS. 25 and 26, a gate insulating layer 144″, a filling channel pattern 131″, a channel structure 130″, and a memory layer 120″ may be disposed in a channel hole H″. The channel hole H″ may extend in the third direction DR3 to pass through the gate stack structure GST. The channel hole H″ may include a first portion H1″, a second portion H2″, and a third portion H3″. The first portion H1″ may be disposed inside the pad interlayer insulating layer 111PI. The second portion H2″ may extend from the first portion H1″ to pass through the first conductive layer 113A″ and the first interlayer insulating layer 111A″. The third portion H3″ may extend from the first portion H1″ to pass through the plurality of second conductive layers 113B″ and the plurality of second interlayer insulating layers 111B″. A boundary between the first portion H1″ and the second portion H2″ and a boundary between the first portion H1″ and the third portion H3″ may be located at a level between a first surface of the pad interlayer insulating layer 111PI facing the first conductive layer 113A″ and a second surface of the pad interlayer insulating layer 111PI facing the second conductive layer 113B″. The first portion H1″ may protrude laterally (i.e., wider in the lateral direction than the second and third portions) toward the gate stack structure GST as compared with the second portion H2″ and the third portion H3″. Accordingly, a convex portion protruding toward the gate stack structure GST may be defined at a sidewall of the channel hole H″.

The filling channel pattern 131″ may be disposed inside the second portion H2″ of the channel hole H″. The filling channel pattern 131″ may extend toward a sidewall of the second portion H2″ of the channel hole H″ from a central axis AX_C of the channel hole H″. The central axis AX_C may be defined as an axis extending along the center of the channel hole H″. The filling channel pattern 131″ may completely fill a central region of the second portion H2″ in the channel hole H″. The gate insulating layer 144″ may be interposed between the first conductive layer 113A″ and the filling channel pattern 131″. The gate insulating layer 144″ may include oxide such as a silicon oxide layer. The gate insulating layer 144″ may be cut by at least one interlayer insulating layer (e.g., 111A″ and 111PI) adjacent to the first conductive layer 113A″ among the plurality of interlayer insulating layers 111A″, 111PI, and 111B″.

The channel structure 130″ may include a liner channel pattern 133″. The liner channel pattern 133″ may include a connection portion 133C and a vertical portion 133V. The connection portion 133C may be disposed inside the first portion H1″ of the channel hole H″, and the vertical portion 133V may extend to the inside of the third portion H3″ of the channel hole H″ from the connection portion 133C. The connection portion 133C may form a contact surface CTS with the filling channel pattern 131″. The memory layer 120″ may be disposed between the liner channel pattern 133″ and the gate stack structure GST.

The filling channel pattern 131″ and the liner channel pattern 133″ may include a semiconductor material to be used as a channel region of a memory cell string CS. In an embodiment, the filling channel pattern 131″ and the liner channel pattern 133″ may include silicon (Si), germanium (Ge), or any mixture thereof. The filling channel pattern 131″ and the liner channel pattern 133″ may be provided through different processes and have different grain structures. In an embodiment, the filling channel pattern 131″ may be formed in a single crystalline structure, and the liner channel pattern 133″ may be formed in a polycrystalline structure. However, the embodiments of the present disclosure are not limited thereto. In another embodiment, the filling channel pattern 131″ may be formed in a polycrystalline structure in which a grain size of the filling channel pattern 131″ is greater than a grain size of the liner channel pattern 133″.

The liner channel pattern 133″ may be spaced apart from the central axis AX_C of the channel hole H″. The liner channel pattern 133″ may be formed to open a central region of the first portion H1″ and a central region of the third portion H3″ in the channel hole H″. A width of the channel hole H″ may be controlled such that the filling channel pattern 131″ easily fills the central region of the second portion H2″ and the liner channel pattern 133″ easily opens the central region of the first portion H1″ and the central region of the third portion H3″. In an embodiment, each of a minimum width W1 of the first portion H1″ and a minimum width W3 of the third portion H3″ may be defined greater than two times a maximum width W2 of the second portion H2″ in the channel hole H″.

The channel structure 130″ may further include a core insulating layer 135″ and a doped capping layer 137″. The core insulating layer 135″ may extend to the inside of the third portion H3″ from the inside of the first portion H1″ of the channel hole H″. The core insulating layer 135″ may overlap with the filling channel pattern 131″ in the third direction DR3. A portion of the third portion H3″ of the channel hole H″, which is not filled with the core insulating layer 135″, may be filled with the doped capping layer 137″. The doped capping layer 137″ may overlap with the filling channel pattern 131″ with the core insulating layer 135″ interposed therebetween. The doped capping layer 137″ may be formed of a semiconductor layer including at least one of an n-type impurity and a p-type impurity. In an embodiment, the doped capping layer 137″ may include the n-type impurity as a majority carrier. A portion of the liner channel pattern 133″ adjacent to the doped capping layer 137″ may be doped with the same impurity as the doped capping layer 137″.

The connection portion 133C of the liner channel pattern 133″ may extend between the core insulating layer 135″ and the filling channel pattern 131″, to form the contact surface CTS with the filling channel pattern 131″. The gate insulating layer 144″ may be formed by oxidizing a portion of a channel layer filling the second portion H2″ of the channel hole H″. Because of characteristics of manufacturing processes of the semiconductor memory devices in accordance with the embodiments of the present disclosure, a portion of the contact surface CTS may overlap with the gate insulating layer 144″ in the third direction DR3.

The connection portion 133C and the vertical portion 133V of the liner channel pattern 133″ may be interposed between the core insulating layer 135″ and the memory layer 120″. The vertical portion 133V of the liner channel pattern 133″ may extend between the doped capping layer 137″ and the memory layer 120″.

The filling channel pattern 131″ may contact the doped semiconductor structure DPS. The doped semiconductor structure DPS may overlap with the gate stack structure GST. The doped semiconductor structure DPS may include at least one semiconductor layer such as silicon. The doped semiconductor structure DPS may include a doped region including at least one of a common source region and a well region. For example, the doped semiconductor structure DPS may include at least one of an n-type impurity and a p-type impurity. In an embodiment, the doped semiconductor structure DPS may include a first conductivity type doped region including the n-type impurity as a majority carrier. In another embodiment, the doped semiconductor structure DPS may include a first semiconductor layer including the n-type impurity as a majority carrier and a second semiconductor layer including the p-type impurity as a majority carrier. The first semiconductor layer including the n-type impurity as the majority carrier may include the common source region, and the second semiconductor layer including the p-type impurity as the majority carrier may include the well region. The second portion H2″ of the channel hole H″ and the filling channel pattern 131″ may extend to the inside of the doped semiconductor structure DPS.

The conductive contact structure 161″ shown in FIG. 25 may be in contact with the doped semiconductor structure DPS. According to the structure shown in FIG. 25, the conductive contact structure 161″ and the filling channel pattern 131″ may be electrically connected to each other via the doped semiconductor structure DPS.

Referring to FIGS. 25 and 26, the channel structure 130″ may include a portion protruding in the third direction DR3 as compared with the gate stack structure GST. The protruding portion of the channel structure 130″ may be covered by a first insulating layer 141″. The slit SI may extend to pass through the first insulating layer 141″. The bit line BL may be spaced apart from the channel structure 130″ with the first insulating layer 141″ interposed therebetween. The bit line BL may be disposed to contact the first insulating layer 141″ or overlap with the first insulating layer 141″ with at least one insulating layer interposed therebetween. In an embodiment, a second insulating layer 165″ may be disposed between the bit line BL and the first insulating layer 141″. Hereinafter, a structure of each of the semiconductor memory devices will be described based on an embodiment in which the first insulating layer 141″ and the second insulating layer 165″ are disposed between the bit line BL and the channel structure 130″, but the embodiments of the present disclosure are not limited thereto.

The bit line BL may be electrically connected to a liner channel pattern 133″ corresponding thereto via at least one bit line contact. In an embodiment, the bit line BL may be electrically connected to the liner channel pattern 133″ corresponding thereto via a first bit line contact 163″ and a second bit line contact 167″. The first bit line contact 163″ may be in contact with the doped capping layer 137″ of the channel structure 130″ while passing through the first insulating layer 141″. The second bit line contact 167″ may be connected to the first bit line contact 163″ and the bit line BL while passing through the second insulating layer 165″.

The second structure ST2 may include a semiconductor substrate 71″, a peripheral circuit structure PS, an insulating structure 79″, and a plurality of interconnections 77A″. The peripheral circuit structure PS may correspond to the peripheral circuit structure described with reference to FIGS. 1A and 1B.

The semiconductor substrate 71″ may include an active region 71A″ partitioned by an isolation layer 72″. The peripheral circuit structure PS may include a transistor. The transistor may include a gate insulating layer 73″, a gate electrode 75″, and source/drain junctions 71J″. The gate insulating layer 73″ and the gate electrode 75″ may be stacked on the active region 71A″ of the semiconductor substrate 71″. The source/drain junctions 71J″ may be formed in the active region 71A″ at both sides of the gate electrode 75″.

The plurality of interconnections 77A″ may include sub-interconnections individually connected to the gate electrode 75″ and the source/drain junctions 71J″. The semiconductor substrate 71″ and the peripheral circuit structure PS may be covered by the insulating structure 79″, and the plurality of interconnections 77A″ may be disposed inside the insulating structure 79″.

Referring to FIG. 25, the second structure ST2 may be disposed adjacent to a side of the doped semiconductor structure DPS. A process of forming the doped semiconductor structure DPS and the first structure ST1 may be performed on the second structure ST2 after the second structure ST2 is formed.

Referring to FIG. 26, the first structure ST1 may further include a first contact 171″ and a first conductive bonding pad 183″, and the second structure ST2 may further include a second contact 77B″ and a second conductive bonding pad 83″.

The first contact 171″ and the first conductive bonding pad 183″ may be disposed inside a third insulating layer 175″. The third insulating layer 175″ may overlap with the second insulating layer 165″ with the bit line BL interposed therebetween and include a single-layer insulating layer or multi-layer insulating layers each having at least two layers. The first conductive bonding pad 183″ may be electrically connected to the bit line BL via the first contact 171″.

The second conductive bonding pad 83″ may be disposed inside a fourth insulating layer 81″. The fourth insulating layer 81″ may be disposed between the insulating structure 79″ and the third insulting layer 175″. The second contact 77B″ may be in contact with a sub-interconnection corresponding thereto among the plurality of interconnections 77A″ and extend to contact the second conductive bonding pad 83″. The second conductive bonding pad 83″ may contact the first conductive bonding pad 183″.

The memory cell string CS of the first structure ST1 and the peripheral circuit structure PS of the second structure ST2 may be electrically connected to each other via the first conductive bonding pad 183″ and the second conductive bonding pad 83″. In an embodiment, the first conductive bonding pad 183″ may be connected to the memory cell string CS via the first contact 171″, the bit line BL, and the first and second bit line contacts 163″ and 167″, and the second conductive bonding pad 83′″ may be connected to the junction 71j″ constituting the transistor of a page buffer circuit via the second contact 77B″ and the interconnection 77A″. When the first conductive bonding pad 183″ and the second conductive bonding pad 83″ in accordance with these embodiments are in contact with each other, the memory cell string CS may be electrically connected to the peripheral circuit structure PS via the bit line BL, the first contact 171″, the first conductive bonding pad 183″, the second conductive bonding pad 83″, and the interconnection 77A″.

The first structure ST1 and the second structure ST2, which are described above, may be provided through individual processes. A bonding process may then be performed to bond the first conductive bonding pad 183″ and the second conductive bonding pad 83″ which are in contact with each other. Thus, the first structure ST1 and the second structure ST2 may be structurally connected to each other.

The first conductive bonding pad 183″ and the second conductive bonding pad 83″ may include copper, a copper alloy, or the same type of metal. The first conductive bonding pad 183″ and the second conductive bonding pad 83″ may further include a barrier layer such as a metal nitride layer.

Referring to FIGS. 25 and 26, the second portion H2″ of the channel hole H″ is formed with a narrow width as compared with the first portion H1″ and the third portion H3″ of the channel hole H″, so that the second portion H2″ may be easily filled with the filling channel pattern 131″, using deposition. In addition, the first portion H1″ of the channel hole H″ is formed with a wide width as compared with the third portion H3″ and the second portion H2″ of the channel hole H″, so that a height of the filling channel pattern 131″ may be easily controlled at a level at which the boundary between the first portion H1″ and the second portion H2″ is disposed. Accordingly, although selective epitaxial growth (SEG) performed at a high temperature as compared with the deposition is not used, the filling channel pattern 131″ may be formed with a uniform height in the second portion H2″ of the channel hole H″. Thus, when the filling channel pattern 131″ is formed on the peripheral circuit structure PS, the filling channel pattern 131″ is formed using the deposition instead of the SEG, so that characteristic degradation of the peripheral circuit structure PS due to a high temperature process may be reduced. In addition, a channel resistance is decreased through the filling channel pattern 131″, so that a channel current of the memory cell string CS may be increased. In accordance with the embodiments of the present disclosure, because the characteristic degradation of the peripheral circuit structure PS may be reduced, and the channel current of the memory cell string CS may be increased, the operational reliability of each of the semiconductor memory devices may be improved.

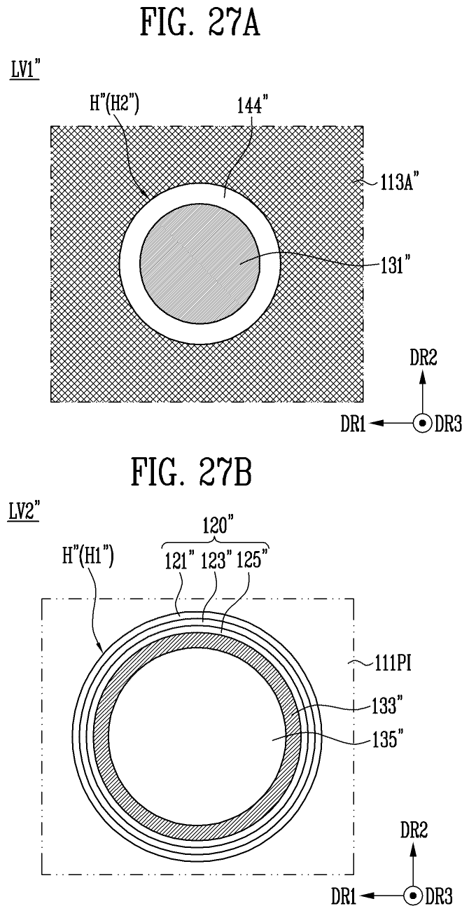

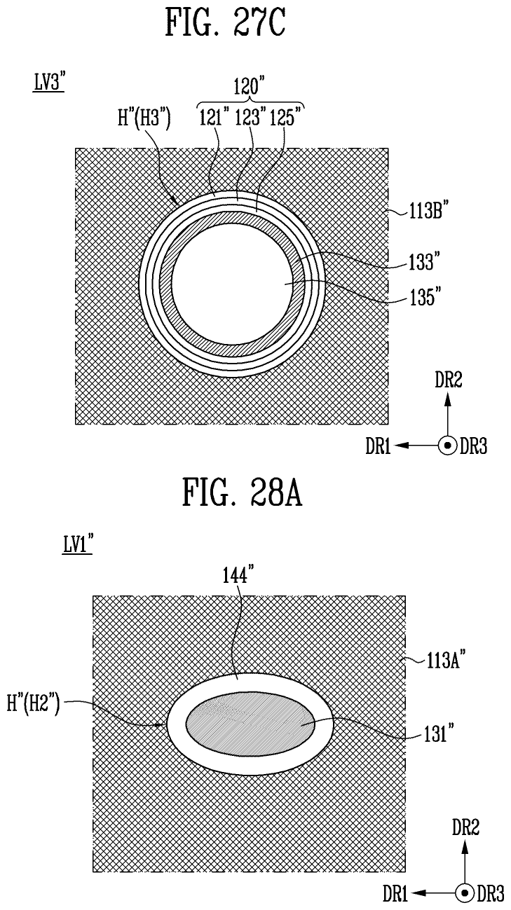

FIGS. 27A, 27B, and 27C are plan views illustrating a cell plug in accordance with an embodiment of the present disclosure. Hereinafter, overlapping descriptions of portions identical to those shown in FIGS. 6A to 6C may be simplified or omitted.

FIG. 27A illustrates a cross-section of the cell plug at a first level LV1″ shown in FIG. 25 or 26. FIG. 27B illustrates a cross-section of the cell plug at a second level LV2″ shown in FIG. 25 or 26. FIG. 27C illustrates a cross-section of the cell plug at a third level LV3″ shown in FIG. 25 or 26.

Referring to FIGS. 25, 26, and 27A to 27C, the first level LV1″ may be a level at which the first conductive layer 113A″ is disposed, the second level LV2″ may be a level at which the pad interlayer insulating layer 111PI is disposed, and the third level LV3″ may be a level at which the second conductive layer 113B″ is disposed.

Referring to FIGS. 27A to 27C, each of the first portion H1″, the second portion H2″, and the third portion H3″ of the channel hole H″ may include a circular cross-sectional structure. A cross-sectional structure of the filling channel pattern 131″ may have a shape corresponding to the second portion H2″. A cross-sectional structure of the liner channel pattern 133″ may have a shape corresponding to the first portion H1″ at the second level LV2″ and have a shape corresponding to the third portion H3″ at the third level LV3″. In an embodiment, the filling channel pattern 131″ may include a circular cross-sectional structure. The liner channel pattern 133″ may include a ring-shaped cross-sectional structure at each of the second level LV2″ and the third level LV3″.

The gate insulating layer 114″ may have a ring shape surrounding a sidewall of the filling channel pattern 131″ at the first level LV1″. A cross-sectional structure of the gate insulating layer 114″ may have a circular shape.

The liner channel pattern 133″ may surround a sidewall of the core insulating layer 135″.

The memory layer 120″ may include a blocking insulating layer 121″, a data storage layer 123″, and a tunnel insulating layer 125″, which are formed of the same materials as described with reference to FIGS. 6A to 6C. Each of the blocking insulating layer 121″, the data storage layer 123″, and the tunnel insulating layer 125″ may extend along a sidewall of each of the first portion H1″ and the third portion H3″ of the channel hole H″. The blocking insulating layer 121″ may be disposed between the sidewall of each of the first portion H1″ and the third portion H3″ and the data storage layer 123″, and the data storage layer 123″ may be disposed between the blocking insulating layer 121″ and the tunnel insulating layer 125″.

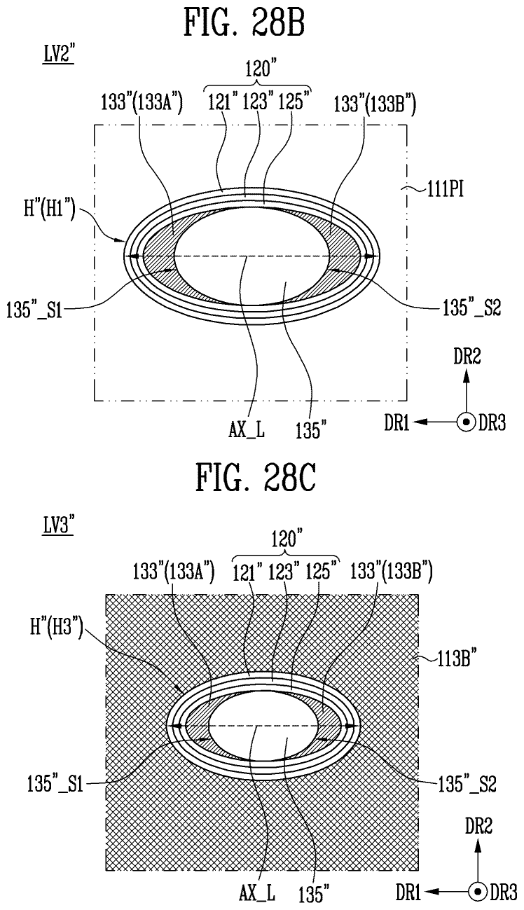

FIGS. 28A, 28B, and 28C are plan views illustrating a cell plug in accordance with an embodiment of the present disclosure. FIG. 28A illustrates a cross-section of the cell plug at the first level LV1″ shown in FIG. 25 or 26, FIG. 28B illustrates a cross-section of the cell plug at the second level LV2″ shown in FIG. 25 or 26, and FIG. 28C illustrates a cross-section of the cell plug at the third level LV3″ shown in FIG. 25 or 26. Hereinafter, overlapping descriptions of portions identical to those shown in FIGS. 27A to 27C may be simplified or omitted.

Referring to FIGS. 28A to 28C, each of the first portion H1″, the second portion H2″, and the third portion H3″ of the channel hole H″ may include an elliptical cross-sectional structure. A cross-sectional structure of the filling channel pattern 131″ may include an elliptical cross-sectional structure corresponding to the second portion H2″. The liner channel pattern 133″ may include a crescent-moon-shaped cross-sectional structure having a width which becomes narrower as approaching an end portion thereof at each of the second level LV2″ and the third level LV3″.

The gate insulating layer 114″ may have a ring shape and surround a sidewall of the filling channel pattern 131″ at the first level LV1″. A cross-sectional structure of the gate insulating layer 114″ may have an elliptical shape.

The core insulating layer 135″ may include a first sidewall 135″_S1 and a second sidewall 135″_S2, which face in directions opposite to each other. The first sidewall 135″_S1 and the second sidewall 135″_S2 may be aligned on a major axis AX_L defined by the elliptical cross-sectional structure of the channel hole H″. Each of the first sidewall 135″_S1 and the second sidewall 135″_S2 may extend in the third direction DR3 along the first portion H1″ and the second portion H2″ of the channel hole H″.

The liner channel pattern 133″ may include a first vertical channel portion 133A″ extending along the first sidewall 135″_S1 of the core insulating layer 135″ and a second vertical channel portion 133B″ extending to the second sidewall 135″_S2 of the core insulating layer 135″. The first vertical channel portion 133A″ and the second vertical channel portion 133B″ may be connected to the filling channel pattern 131″ via the connection portion 130C of the liner channel pattern 133″ shown in FIG. 25 or 26.

The core insulating layer 135″ may contact the memory layer 120″ between the first vertical channel portion 133A″ and the second vertical channel portion 133B″. The doped capping layer 137″ shown in FIG. 25 or 26 may be isolated into a first doped capping pattern in contact with the first vertical channel portion 133A″ and a second doped capping pattern in contact with the second vertical channel portion 133B″.

The first vertical channel portion 133A″ and the second vertical channel portion 133B″ may be connected to different bit lines to be used as channel regions of different memory cell strings.

The memory layer 120″ may include the blocking insulating layer 121″, the data storage layer 123″, and the tunnel insulating layer 125″, which are formed of the same materials as described with reference to FIGS. 6A to 6C.

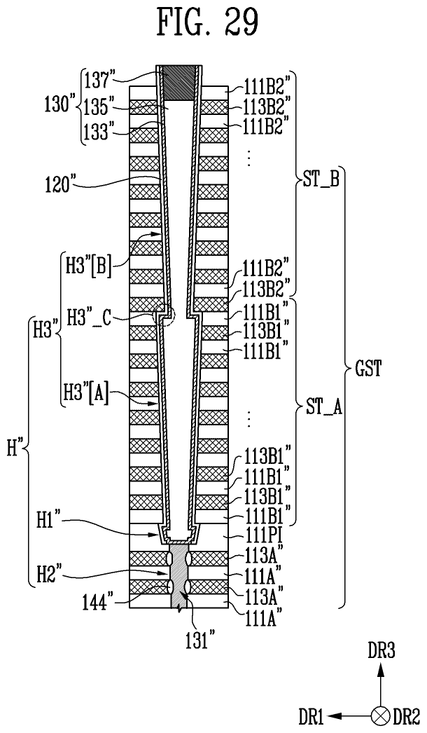

FIG. 29 is a sectional view illustrating a semiconductor memory device in accordance with embodiments of the present disclosure. A gate stack structure GST and a channel hole H″, which are shown in FIG. 29, may substitute for the gate stack structure GST and the channel hole H″, which are shown in FIG. 25 or 26. Hereinafter, overlapping descriptions of portions identical to those shown in FIGS. 25 and 26 may be simplified or omitted.

Referring to FIG. 29, the gate stack structure GST may include a plurality of conductive layers 113A″, 113B1″, and 113B2″ extending in the first direction DR1 and the second direction DR2. The plurality of conductive layers 113A″, 113B1″, and 113B2″ may be stacked spaced apart from each other in the third direction DR3. The gate stack structure GST may further include a plurality of interlayer insulating layers 111A″, 111PI, 111B1″, and 111B2″. The plurality of interlayer insulating layers 111A″, 111PI, 111B1″, and 111B2″ may alternately disposed with the plurality of conductive layers 113A″, 113B1″, and 113B2″ in the third direction DR3.

The plurality of conductive layers 113A″, 113B1″, and 113B2″ may include at least one first conductive layer 113A″ and a plurality of second conductive layers 113B1″ and 113B2″ as described with reference to FIGS. 25 and 26. The plurality of interlayer insulating layers 111A″, 111PI, 111B1″, and 111B2″ may include a first interlayer insulating layer 111A″, a pad interlayer insulating layer 111PI, and a plurality of second interlayer insulating layers 111B1″ and 111B2″ as described with reference to FIGS. 25 and 26.

The plurality of second conductive layers 113B1″ and 113B2″ and the plurality of second interlayer insulating layers 111B1″ and 111B2″ may be divided into multiple sub-stack structures stacked in the third direction DR3. In an embodiment, the plurality of second conductive layers 113B1″ and 113B2″ and the plurality of second interlayer insulating layers 111B1″ and 111B2″ may be divided into a first sub-stack structure ST_A and a second sub-stack structure ST_B. Hereinafter, an embodiment of the present disclosure will be representatively described based on an embodiment in which the plurality of second conductive layers 113B1″ and 113B2″ and the plurality of second interlayer insulating layers 111B1″ and 111B2″ are divided into two sub-stack structures.

The plurality of second conductive layers 113B1″ and 113B2″ may be divided into a first sub-group of second conductive layers 113B1″ forming the first sub-stack structure ST_A and a second sub-group of second conductive layers 113B2″ forming the second sub-stack structure ST_B. The plurality of second interlayer insulating layers 111B1″ and 111B2″ may be divided into a first sub-group of second interlayer insulating layers 111B1″ forming the first sub-stack structure ST_A and a second sub-group of second interlayer insulating layers 111B2″ forming the second sub-stack structure ST_B.

The channel hole H″ may include the first portion H1″ and the second portion H2″, which are described with reference to FIGS. 25 and 26. The channel hole H″ may include a third portion H3″ extending from the first portion H1″ to pass through the plurality of second conductive layers 113B1″ and 113B2″ and the plurality of second interlayer insulating layers 111B1″ and 111B2″. The third portion H3″ may be formed in a connection structure of penetration portions respectively passing through the sub-stack structures. In an embodiment, the third portion H3″ may be formed in a connection structure of a first penetration portion H3″ [A] passing through the first sub-stack structure ST_A and a second penetration portion H3″ [B] passing through the second sub-stack structure ST_B. A corner H3″_C of the third portion H3″ may be defined due to a width difference between the first penetration portion H3″ [A] and the second penetration portion H3″ [B] at a level at which the first penetration portion H3″ [A] and the second penetration portion H3″ [B] are connected to each other. The corner H3″_C of the third portion H3″ may be defined between the second conductive layer 113B1″ of the first sub-group and the second conductive layer 113B2″ of the second sub-group, which are adjacent to each other in the third direction DR3.

A gate insulating layer 144″, a filling channel pattern 131″, a memory layer 120″, and a channel structure 130″ may be disposed in the channel hole H″ having the above-described structure. The channel structure 130″ may include a liner channel pattern 133″, a core insulating layer 135″, and a doped capping layer 137″.

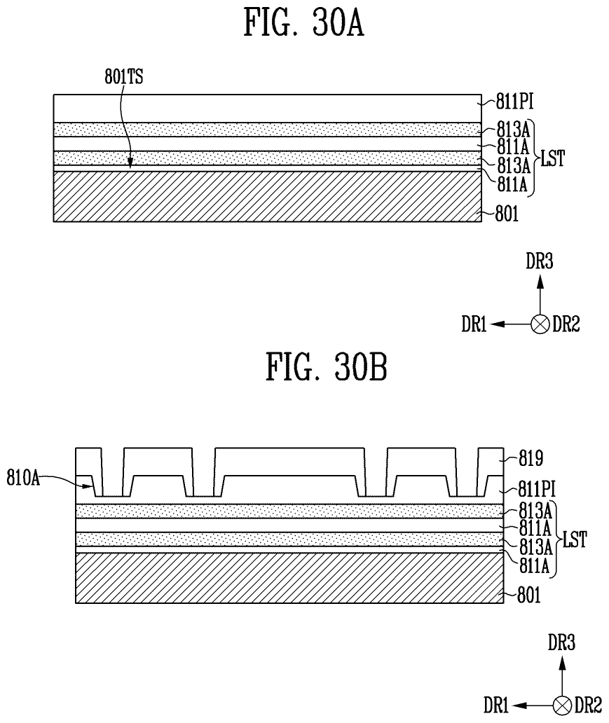

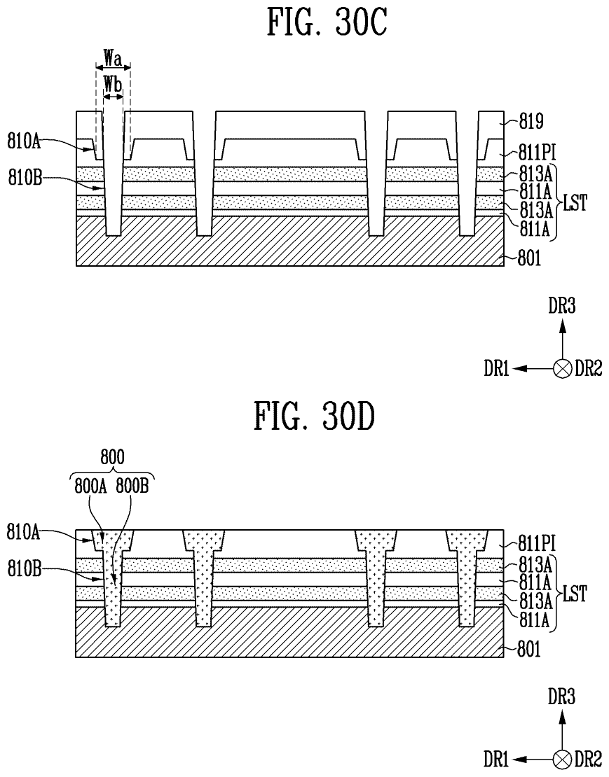

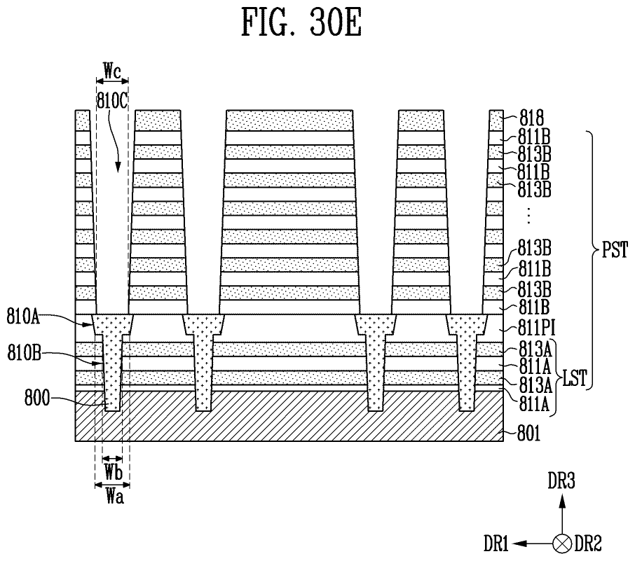

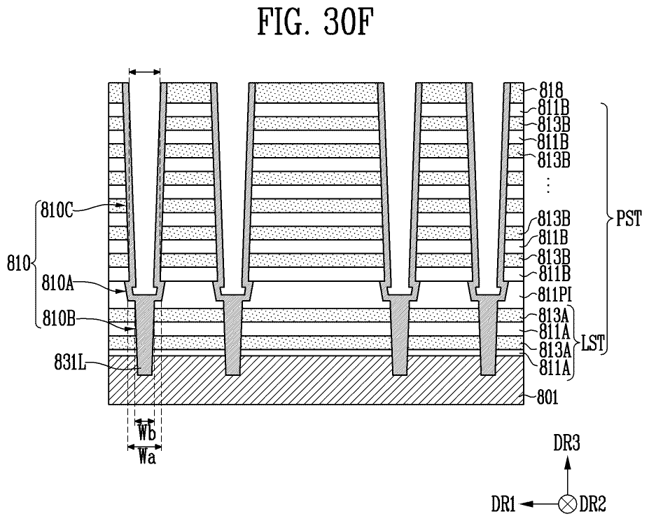

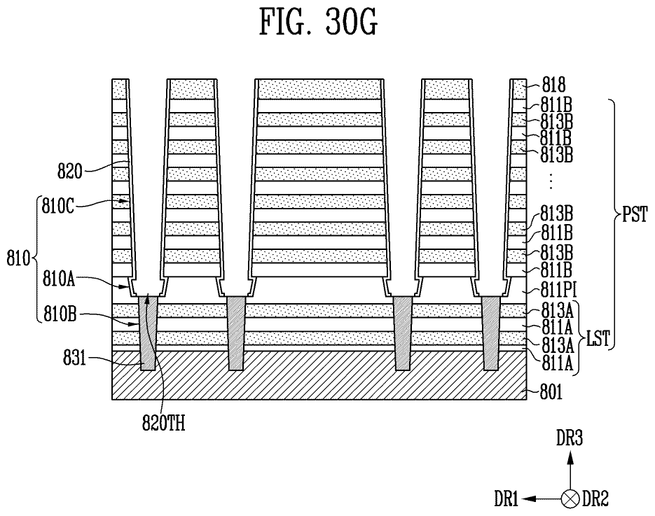

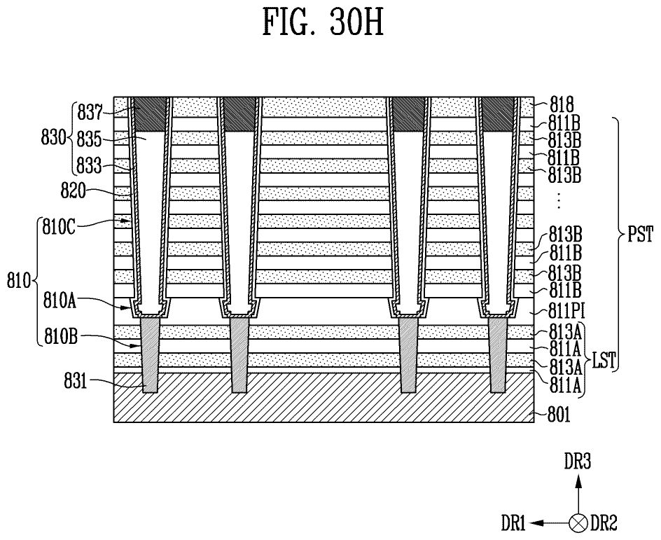

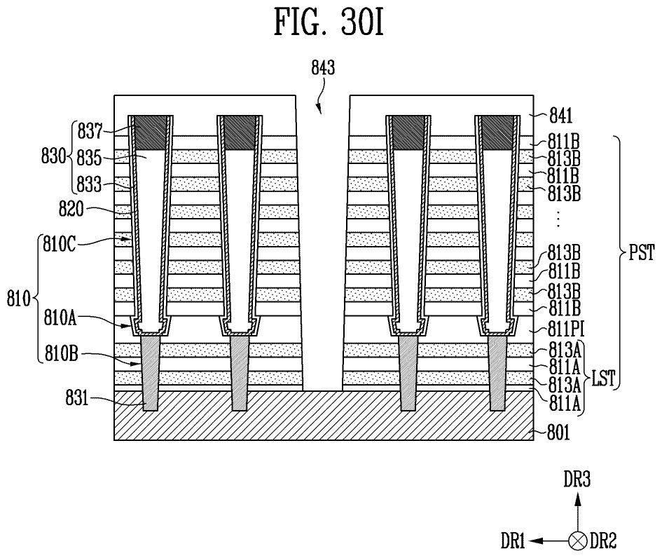

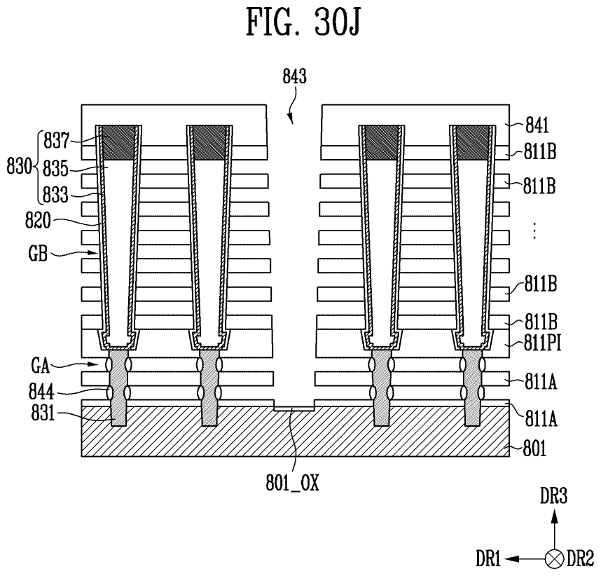

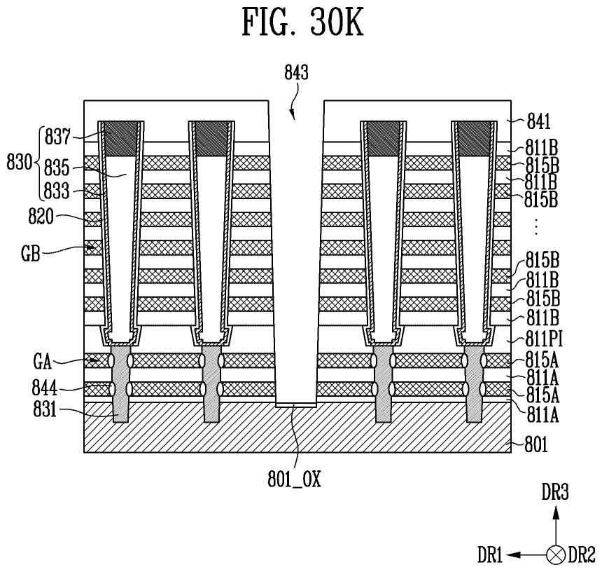

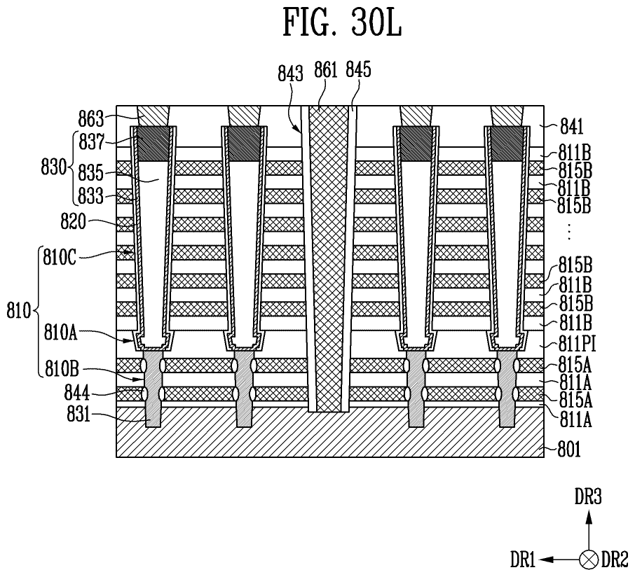

FIGS. 30A to 30L are sectional views illustrating a manufacturing method of a semiconductor memory device in accordance with an embodiment of the present disclosure.

Referring to FIG. 30A, a lower stack structure LST may be formed on a doped semiconductor structure 801. The doped semiconductor structure 801 may extend in the first direction DR1 and the second direction DR2 and include an upper surface 801TS facing in the third direction DR3. The doped semiconductor structure 801 may include at least one semiconductor layer such as a silicon layer. The doped semiconductor structure 801 may include at least one of a first conductivity doped region including an n-type impurity as a majority carrier and a second conductivity type doped region including a p-type impurity as a majority carrier. The first conductivity type doped region may include a common source region, and the second conductivity type doped region may include a well region. In an embodiment, the doped semiconductor structure 801 may include an n-type doped silicon layer.

The doped semiconductor structure 801 may be formed on the second structure ST2 shown in FIG. 25 or be formed on a semiconductor wafer excluding the second structure ST2.

The lower stack structure LST may be formed by alternately disposing at least one first material layer 811A and at least one second material layer 813A in the third direction DR3 on the upper surface 801TS of the doped semiconductor structure 801. A first material layer 811A may be disposed in a lowermost layer of the lower stack structure LST, and a first material layer 811A or a second material layer 813A may be disposed in an uppermost layer of the lower stack structure LST. Hereinafter, the embodiment of the present disclosure will be described based on an embodiment in which the second material layer 813A is disposed in the uppermost layer of the lower stack structure LST.

The second material layer 813A may be formed of a material having an etch selectivity with respect to the first material layer 811A. In an embodiment, the first material layer 811A may include an insulating material such as a silicon oxide layer or a silicon nitride layer, and the second material layer 813A may include a sacrificial insulating material such as a silicon nitride layer. The sacrificial insulating material may be replaced with a conductive material including at least one of a doped semiconductor layer, a metal layer, and a conductive metal nitride layer in a subsequent process.

After that, a third material layer 811PI may be formed on the lower stack structure LST. The third material layer 811PI may be formed of the same material as the first material layer 811A. The third material layer 811PI may include the pad interlayer insulating layer described with reference to FIGS. 25 and 26.

Referring to FIG. 30B, a portion of the third material layer 811PI may be etched, thereby forming a first opening 810A inside the third material layer 811PI. A bottom surface of the first opening 810A may be located at a level at which the bottom surface is spaced apart from the second material layer 813A adjacent to the third material layer 811PI.

After that, a spacer layer 819 may be formed along a surface of the first opening 810A. The spacer layer 819 may be etched through an etching process such as etch-back, thereby exposing the bottom surface of the first opening 810A. The remaining spacer layer 819 may cover a sidewall of the first opening 810A, and a central region of the first opening 810A may be exposed without being filled with the spacer layer 819.

The spacer layer 819 may include a material having an etch selectivity with respect to the first material layer 811A, the second material layer 813A, and a third material layer 811PI. In an embodiment, the spacer layer 819 may include a carbon layer, a carbon doping layer, a high dielectric layer doped with a metal, a metal oxide layer, and the like. For example, the spacer layer 819 may be formed of an aluminum oxide (Al₂O₃) or a silicon carbon nitride (SiCN).

Referring to FIG. 30C, the third material layer 811PI and the lower stack structure LST may be etched through an etching process using the spacer layer 819 as an etch barrier. Accordingly, a second opening 810B may be formed. The etching process for forming the second opening 810B may be performed through the central region of the first opening 810A exposed by the spacer layer 819. The second opening 810B may extend from the first opening 810A to pass through the lower stack structure LST.

In the etching process for forming the second opening 810B, a portion of the doped semiconductor structure 801 may be etched. Accordingly, the second opening 810B may extend to the inside of the doped semiconductor structure 801.

A maximum width Wb of the second opening 810B may be controlled by controlling a deposition thickness of the spacer layer 819. The maximum width Wb of the second opening 810B may be controlled to be less than a half of a minimum width Wa of the first opening 810A. After the second opening 810B is formed, the spacer layer 819 may be removed such that the sidewall of the first opening 810A is exposed.

Referring to FIG. 30D, a sacrificial structure 800 may be formed in the first opening 810A and the second opening 810B. The sacrificial structure 800 may be formed by filling the first opening 810A and the second opening 810B with a material having an etch selectivity with respect to the doped semiconductor structure 801, the first material layer 811A, the second material layer 813A, and the third material layer 811PI. In an embodiment, the sacrificial structure 800 may include a metal such as tungsten. The sacrificial structure 800 may further include a barrier layer. The barrier layer may be interposed between each of the doped semiconductor structure 801, the first material layer 811A, the second material layer 813A, and the third material layer 811PI and the metal of the sacrificial structure 800. The barrier layer may include a metal nitride layer such as a titanium nitride layer.

The sacrificial structure 800 may include a first portion 800A and a second portion 800B, which respectively correspond to the first opening 810A and the second opening 810B. The first portion 800A of the sacrificial structure 800 may be formed to fill the first opening 810A inside the third material layer 811PI. The second portion 800B of the sacrificial structure 800 may extend from the first portion 800A and be formed to fill the second opening 810B passing through the lower stack structure LST. The second portion 800B may be formed with a narrow width as compared with the first portion 800A.

Referring to FIG. 30E, a plurality of fourth material layers 811B and a plurality of fifth material layers 813B may be alternately stacked one by one on the third material layer 811PI to cover the sacrificial structure 800. The plurality of fourth material layers 811B may include the same material as the first material layer 811A, and the plurality of fifth material layers 813B may include the same material as the second material layer 813A. Accordingly, a preliminary stack structure PST may be formed. The preliminary stack structure PST may include the lower stack structure LST, the third material layer 811PI, the plurality of fourth material layers 811B, and the plurality of fifth material layers 813B.

Subsequently, a mask layer 818 may be formed on the preliminary stack structure PST. After that, the plurality of fourth material layers 811B and the plurality of fifth material layers 813B of the preliminary stack structure PST may be etched through an etching process using the mask layer 818 as an etch barrier. Accordingly, a third opening 810C may be formed to pass through the plurality of fourth material layers 811B and the plurality of fifth material layers 813B. A minimum width Wc of the third opening 810C may be defined to be greater than two times of the maximum width Wb of the second opening 810B.

The third opening 810C may expose the sacrificial structure 800. The third opening 810C shown in FIG. 30E may correspond to the third portion H3″ of the channel hole H″ shown in FIG. 25 or 26.

A process for forming the third opening 810C is not limited to the above-described embodiment. Although not shown in the drawing, in another embodiment, in order to form a third opening corresponding to the third portion H3″ of the channel hole H″ shown in FIG. 29, the process for forming the third opening 810C may include a process of forming a first sub-stack structure by stacking a first group of a plurality of fourth material layers 811B and a plurality of fifth material layers 813B, a process of forming a lower portion of the third opening passing through the first sub-stack structure, a process of filling the lower portion of the third opening with a sacrificial pillar, a process of forming a second sub-stack structure by stacking a second group of a plurality of fourth material layers 811B and a plurality of fifth material layers 813B, a process of forming an upper portion of the third opening passing through the second sub-stack structure, and a process of removing the sacrificial pillar through the upper portion of the third opening.

After the third opening 810C is formed in various manners as described above, the sacrificial structure 800 may be removed through the third opening 810C. Accordingly, as shown in FIG. 30F, a channel hole 810 may be defined. The channel hole 810 may include the first opening 810A, the second opening 810B and the third opening 810C. The second and third openings 810B and 810C may extend in directions opposite to each other from the first opening 810A. The first opening 810A may protrude laterally as compared with the second opening 810B and the third opening 810C.

Referring to FIG. 30F, a channel layer 831L may be formed in the channel hole 810 such that the second opening 810B is filled therewith. A thickness of the channel layer 831L may be controlled such that a central region of each of the first opening 810A and the third opening 810C, each of which has a wide width as compared with the second opening 810B, may be opened.

The channel layer 831L may include silicon (Si), germanium (Ge), or any mixture thereof. In an embodiment, when the channel layer 831L is formed in a state in which the second structure ST2 shown in FIG. 25 or 26 is excluded, the channel layer 831L may be formed using selective epitaxial growth (SEG). In another embodiment, when a process of forming the channel layer 83IL is performed on the second structure ST2 shown in FIG. 25, the channel layer 831L may be formed using deposition. Because the deposition may be performed at a low temperature as compared with the SEG, thermal stress applied to the peripheral circuit structure PS shown in FIG. 25 may be reduced even when a deposition process of the channel layer 831L is performed in a state in which the second structure ST2 shown in FIG. 25 is formed.

Because the maximum width Wb of the second opening 810B is formed smaller than a half of each of the minimum width Wa of the first opening 810A and the minimum width Wc of the third opening 810C, the second opening 810B may be easily filled with the channel layer 831L even when the channel layer 831L is formed using the deposition. As the first opening 810A is formed wider than the second opening 810B and the third opening 810C, the first opening 810A protrudes laterally as compared with the second opening 810B and the third opening 810C, so that a phenomenon in which a void is generated in the second opening 810B may be reduced.

Referring to FIG. 30G, an etching process such as etch-back may be performed such that a portion of the channel layer (831L shown in FIG. 30F) disposed in the first opening 810A and the third opening 810C may be removed. The remaining channel layer may form a filling channel pattern 831 while filling the second opening 810B. The filling channel pattern 831 may contact the doped semiconductor structure 801, and extend to the inside of the doped semiconductor structure 801.

In accordance with an embodiment of the present disclosure, a portion of the channel layer (831L shown in FIG. 30F) disposed in the first opening 810A and the third opening 810C may be removed in a state in which the central region is opened in each of the first opening 810A and the third opening 810C, each of which has a wide width as compared with the second opening 810B. Accordingly, the channel layer may be easily removed in the first opening 810A and the third opening 810C, and the height of the remaining channel layer may be easily controlled to become target height.

The filling channel pattern 831 may have a cross-sectional structure corresponding to the second opening 810B. In an embodiment, each of the filling channel pattern 831 and the second opening 810B may have a circular cross-sectional structure. In another embodiment, each of the filling channel pattern 831 and the second opening 810B may have an elliptical cross-sectional structure.

Subsequently, a memory layer 820 may be formed along the sidewall of the first opening 810A and a sidewall of the third opening 810C. The filling channel pattern 831 may be exposed by a penetration hole 820TH passing through the memory layer 820.

The memory layer 820 may include the blocking insulating layer 121″, the data storage layer 123″, and the tunnel insulating layer 125″, which are shown in FIGS. 27B and 27C or are shown in FIGS. 28B and 28C. The memory layer 820 may have a cross-sectional structure corresponding to the first opening 810A and the third opening 810C. In an embodiment, the memory layer 820 may have a circular cross-sectional structure as shown in FIGS. 27B and 27C. In another embodiment, the memory layer 820 may have an elliptical cross-sectional structure as shown in FIGS. 28B and 28C.

Referring to FIG. 30H, a channel structure 830 including a liner channel pattern 833 may be formed. The liner channel pattern 833 may include silicon (Si), germanium (Ge), or any mixture thereof. The liner channel pattern 833 may contact the filling channel pattern 831. The liner channel pattern 833 may extend along an inner wall of the memory layer 820.

The liner channel pattern 833 may have a cross-sectional structure corresponding to the first opening 810A and the third opening 810C. In an embodiment, the liner channel pattern 833 may have a circular cross-sectional structure as shown in FIGS. 27B and 27C. In another embodiment, the liner channel pattern 833 may have a crescent-moon-shaped cross-sectional structure having a width which becomes thinner as approaching an end portion thereof as shown in FIGS. 28B and 28C.

The channel structure 830 may further include a core insulating layer 835 and a doped capping layer 837. The doped capping layer 837 may be formed of a semiconductor layer including at least one of an n-type impurity and a p-type impurity. In an embodiment, the doped capping layer 837 may include the n-type impurity as a majority carrier. The core insulating layer 835 and the doped capping layer 837 may be disposed in a central region of the first opening 810A and a central region of the third opening 810C, which are opened by the liner channel pattern 833. In an embodiment, when the liner channel pattern 833 includes a ring-shaped cross-sectional structure as described with reference to FIGS. 27B and 27C, the doped capping layer 837 may be formed to fill the central region of the third opening 810C at an upper end of the third opening 810C. In another embodiment, when the liner channel pattern 833 include a crescent-moon-shaped cross-sectional structure as shown in FIGS. 28B and 28C, an isolation insulating structure (not shown) which isolates the doped capping layer 837 into a first doped capping pattern and a second doped capping pattern may be further formed in the third opening 810C.

After the channel structure 830 is formed, the mask layer 818 may be removed.

Referring to FIG. 30I, a first insulating layer 841 may be formed to cover the channel structure 830 and the preliminary stack structure PST. Subsequently, a slit 843 may be formed to pass through the first insulating layer 841 and the preliminary stack structure PST.

Referring to FIG. 30J, the second material layer 813A and the plurality of fifth material layers 813B, which are shown in FIG. 30I, may be selectively removed through the slit 843. Accordingly, a first gate region GA may be opened in a region in which the second material layer 813A is removed, and a plurality of second gate regions GB may be opened in regions in which the plurality of fifth material layers 813B are removed.

An outer wall of the filling channel pattern 831 may be exposed by the first gate region GA. Subsequently, the exposed outer wall of the filling channel pattern 831 may be oxidized through the first gate region GA. Accordingly, a gate insulating layer 844 may be formed to surround the outer wall of the filling channel pattern 831.

The liner channel pattern 833 may be protected from an oxidation process through the memory layer 820. A portion of the doped semiconductor structure 801 may be oxidized through the slit 843. As a result, a semiconductor oxide layer 801_OX may be formed along a bottom surface of the slit 843.

Referring to FIG. 30K, a plurality of conductive layers 815A and 815B may be formed in the first gate region GA and the plurality of second gate regions GB through the slit 843. A plurality of conductive layers 815A may include a first conductive layer 815A inside the first gate region GA and a second conductive layer 815B inside each second gate region GB.

The first conductive layer 815A may surround the filling channel pattern 831 with the gate insulating layer 844 interposed therebetween. The second conductive layer 815B may surround the channel structure 830 with the memory layer 820 interposed therebetween.

Referring to FIG. 30L, a sidewall insulating layer 845 may be formed on a sidewall of the slit 843. The sidewall insulating layer 845 may be formed to expose the bottom of the slit 843. The semiconductor oxide layer 801_OX shown in FIG. 30K may be removed before the sidewall insulating layer 845 is formed but may be removed while a portion of the sidewall insulating layer 845 is etched to expose the bottom of the slit 843.

Subsequently, a conductive contact structure 861 connected to the doped semiconductor structure 801 may be formed by filling the slit 843 with a conductive material. The conductive contact structure 861 may be formed of various conductive materials. In another embodiment, the slit 843 may be filled with the insulating material 147″ shown in FIG. 26. In still another embodiment, the slit 843 may be filled with different types of materials including an insulating material, a semiconductor material, a metal, and the like. The semiconductor material may include an amorphous semiconductor layer or a polycrystalline semiconductor layer, and include silicon (Si), germanium (Ge), or any mixture thereof.

Subsequently, a subsequent process such as a process of forming a first bit line contact 863 may be performed, thereby providing the semiconductor memory device shown in FIG. 25 or providing the first structure ST1 shown in FIG. 26.

In an embodiment, separately from that the first structure ST1 is provided using the processes described with reference to FIGS. 30A to 30L, processes for providing the second structure ST2 shown in FIG. 26 may be performed, and a bonding process for bonding the first structure ST1 and the second structure ST2 to each other may be additionally performed. The semiconductor memory device shown in FIG. 26 may be provided using these processes.

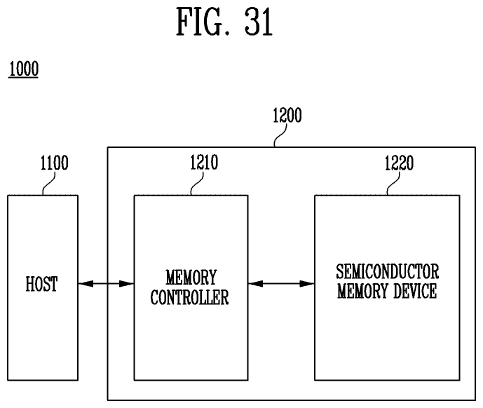

FIG. 31 is a block diagram illustrating an electronic system including a semiconductor memory device in accordance with embodiments of the present disclosure.

Referring to FIG. 31, the electronic system 1000 may be a computing system, a medical device, a communication device, a wearable device, a memory system, or the like. The electronic system 1000 may include a host 1100 and a storage device 1200.

The host 1100 may store data in the storage device 1200 or read data stored in the storage device 1200, based on an interface. The interface may include at least one of a Double Data Rate (DDR) interface, a Universal Serial Bus (USB) interface, a Multi-Media Card (MMC) interface, an embedded MMC (eMMC) interface, a Peripheral Component Interconnection (PCI) interface, a PCI-Express (PCI-E) interface, an Advanced Technology Attachment (ATA) interface, a Serial ATA (SATA) interface, a Parallel ATA (PATA) interface, a Small Computer System Interface (SCSI), an Enhanced Small Disk Interface (ESDI), an Integrated Drive Electronics (IDE) interface, a firewire interface, a Universal Flash Storage (UFS) interface, and a Non-Volatile Memory express (NVMe) interface.

The storage device 1200 may include a memory controller 1210 and a semiconductor memory device 1220. In an embodiment, the storage device 1200 may be a storage medium such as a Solid State Drive (SSD) or a Universal Serial Bus (USB) memory.

The memory controller 1210 may store data in the semiconductor memory device 1220 or read data stored in the semiconductor memory device 1220 under the control of the host 1100.

The semiconductor memory device 1220 may include one memory chip or a plurality of memory chips. The semiconductor memory device 1220 may store data or output stored data under the control of the memory controller 1210.

The semiconductor memory device 1220 may be a nonvolatile memory device. The semiconductor memory device 1220 may include at least one of the semiconductor memory devices described with reference to FIGS. 4, 5, 8, 9A, 9B, 17, 18, 21, 25, 26, and 29. The semiconductor memory device 1220 may include at least one of the cell plug described with reference to FIGS. 6A to 6C, the cell plug described with reference to FIGS. 7A to 7C, the cell plug described with referenced to FIGS. 19A to 19C, the cell plug described with reference to FIGS. 20A to 20C, the cell plug described with reference to FIGS. 27A to 27C, and the cell plug described with reference to FIGS. 28A to 28C.

In accordance with embodiments of the present disclosure, a failure of manufacturing processes and a leakage current in an operation, which are caused as a void is exposed to the outside, may be reduced. As a result, the stability in manufacturing processes of the semiconductor memory device and the operational reliability of the semiconductor memory device may be improved. Furthermore, the embodiments may be combined to form additional embodiments.

What is claimed is:

1. A semiconductor memory device comprising:
a first structure including a cell array structure and a first conductive bonding pad electrically connected to the cell array structure;
a doped semiconductor structure including a first surface facing the first structure and a second surface facing opposite to the first surface; and
a second structure including a second conductive bonding pad being in contact with the first conductive bonding pad and a peripheral circuit electrically connected to the second conductive bonding pad,
wherein the cell array structure comprising:
a gate stack structure including conductive layers stacked over the first surface of the doped semiconductor structure;
a channel layer including a first portion extending along a sidewall of the gate stack structure, a second portion extending to the inside of the doped semiconductor structure from the first portion, and a third portion extending toward the second surface of the doped semiconductor structure from the second portion, the second portion of the channel layer includes a first corner adjacent to the gate stack structure and a second corner between the second surface of the doped semiconductor structure and the first corner; and
a memory layer disposed between the first portion of the channel layer and the sidewall of the gate stack structure.

2. The semiconductor memory device of claim 1, wherein the first structure disposed between the doped semiconductor structure and the second structure.

3. The semiconductor memory device of claim 1, wherein the gate stack structure disposed between the doped semiconductor and the second structure.

4. The semiconductor memory device of claim 1, wherein the second portion of the channel layer protrudes further laterally than the first and third portions of the channel layer.

5. The semiconductor memory device of claim 1, wherein a sidewall of the third portion of the channel layer is in contact with the doped semiconductor structure.

6. The semiconductor memory device of claim 1, wherein the doped semiconductor structure includes a first sidewall being in contact with the third portion of the channel layer and a second sidewall spaced apart from the third portion of the channel layer, and
wherein the first and second sidewalls of the doped semiconductor structure are aligned in a stacking direction of the conductive layers of the gate stack structure.

7. The semiconductor memory device of claim 6, further comprising an interposition layer disposed between the second sidewall the doped semiconductor structure and the third portion of the channel layer,
wherein the interposition layer includes the same material layers as the memory layer.

8. The semiconductor memory device of claim 1, wherein the conductive layers of the gate stack structure are spaced apart from each other and stacked along the first portion of the channel layer.

9. A semiconductor memory device comprising:
a first structure including a cell array structure and a first conductive bonding pad electrically connected to the cell array structure;
a doped semiconductor structure including a first surface facing the first structure and a second surface facing opposite to the first surface; and
a second structure including a second conductive bonding pad being in contact with the first conductive bonding pad and a peripheral circuit electrically connected to the second conductive bonding pad,
wherein the cell array structure comprising:
a gate stack structure including conductive layers stacked over the first surface of the doped semiconductor structure;
a channel structure disposed to penetrate the gate stack structure and including a channel layer, the channel layer including a first portion extending along a sidewall of the channel structure, a second portion extending to the inside of the doped semiconductor structure from the first portion, and a third portion extending toward the second surface of the doped semiconductor structure from the second portion, the channel layer including a first corner adjacent to the gate stack structure and a second corner adjacent to the third portion; and
a memory layer disposed between the first portion of the channel layer and the sidewall of the gate stack structure.

10. The semiconductor memory device of claim 9, wherein the first structure disposed between the doped semiconductor structure and the second structure.

11. The semiconductor memory device of claim 9, wherein the gate stack structure disposed between the doped semiconductor and the second structure.

12. The semiconductor memory device of claim 9, wherein the second portion of the channel layer protrudes further laterally than the first and third portions of the channel layer.

13. The semiconductor memory device of claim 9, wherein a sidewall of the third portion of the channel layer is in contact with the doped semiconductor structure.

14. The semiconductor memory device of claim 13, wherein the doped semiconductor structure includes a first doped semiconductor layer being in contact with a contact portion of the sidewall of the third portion of the channel layer and a second doped semiconductor layer spaced apart from the contact portion of the sidewall of the third portion of the channel layer.

15. The semiconductor memory device of claim 14, further comprising an interposition layer disposed between the doped semiconductor structure and the sidewall of the third portion of the channel layer,
wherein the interposition layer includes the same material layers as the memory layer.

16. The semiconductor memory device of claim 14, wherein each of the first and second portion of the channel layer includes a ring-shaped cross section, and
wherein the third portion of the channel layer includes a circular cross section.

17. The semiconductor memory device of claim 9, wherein the second corner is disposed between the third portion and the second portion of the channel layer.

18. The semiconductor memory device of claim 9, wherein the second portion of the channel layer includes the first corner and the second corner.

19. The semiconductor memory device of claim 18, wherein the second portion of the channel layer extends from the first corner to the second corner to form a convex sidewall that connects the first portion and the third portion of the channel layer.

20. The semiconductor memory device of claim 9,
wherein the channel structure and the memory layer are formed in a channel hole, and
wherein the channel hole includes a gate penetration portion in which the first portion of the channel layer is disposed, a middle portion in which the second portion of the channel layer is disposed, and an end portion in which the third portion of the channel layer is disposed.

21. The semiconductor memory device of claim 20, wherein the middle portion of the channel hole has a width greater than that of the gate penetration portion of the channel hole, with the difference in width defining a corner.

22. The semiconductor memory device of claim 20, wherein the middle portion of the channel hole has a width greater than that of the end portion of the channel hole, with the difference in width defining a corner.
